(19) United States
(12) Patent Application Publication
(10) Pub. No.: US 2024/0251670 A1
(43) Pub. Date: Jul. 25, 2024

(54) ORGANIC LIGHT-EMITTING DEVICE AND METHOD FOR MAKING SAME

(71) Applicant: KYULUX, INC., Fukuoka-shi, Fukuoka (JP)

(72) Inventor: Hayato KAKIZOE, Fukuoka-shi, Fukuoka (JP)

(21) Appl. No.: 18/557,103

(22) PCT Filed: Mar. 30, 2022
(86) PCT No.: PCT/JP2022/015884

§ 371 Date: Oct. 25, 2023

(30) Foreign Application Priority Data
Apr. 26, 2021 (JP) 2021-073740

(51) Int. Cl. H10K 85/60; H10K 50/12; H10K 101/20

(52) U.S. Cl. CPC H10K 85/654; H10K 85/626; H10K 85/6572; H10K 85/658; H10K 50/12; H10K 2101/20

(57) ABSTRACT

An organic light emitting device having a light emitting layer that contains a first organic compound (1) and a second organic compound (2) of a delayed fluorescent material, and a barrier layer containing a triplet-regulating compound (Q) in contact with the light emitting layer, and satisfying the following formulae has a long emission lifetime and is stable. E_{S1} represents a lowest excited singlet energy, and E_{T1} represents a lowest excited triplet energy. E_{S1}(1)>E_{S1}(Q)>E_{S1}(2) E_{T1}(1)>E_{T1}(2)>E_{T1}(Q)

### TECHNICAL FIELD

The present invention relates to an organic light emitting device using a delayed fluorescent material.

### BACKGROUND ART

Studies for enhancing the light emission efficiency of light emitting devices such as organic electroluminescent devices (organic EL devices) are being made actively. In particular, various kinds of efforts have been made for increasing light emission efficiency by newly developing and combining an electron transporting material, a hole transporting material, a host material and a light emitting material to constitute an organic electroluminescent device. Among them, there are seen some studies relating to an organic electroluminescent device that utilizes a delayed fluorescent material.

A delayed fluorescent material is a material which, in an excited state, after having undergone reverse intersystem crossing from an excited triplet state to an excited singlet state, emits fluorescence when returning back from the excited singlet state to a ground state thereof. Fluorescence through the route is observed later than fluorescence from the excited singlet state directly occurring from the ground state (ordinary fluorescence), and is therefore referred to as delayed fluorescence. Here, for example, in the case where a light emitting compound is excited through carrier injection thereinto, the occurring probability of the excited singlet state to the excited triplet state is statistically 25%/75%, and therefore improvement of light emission efficiency by the fluorescence alone from the directly occurring excited singlet state is limited. On the other hand, in a delayed fluorescent material, not only the excited singlet state thereof but also the excited triplet state can be utilized for fluorescence emission through the route via the above-mentioned reverse intersystem crossing, and therefore as compared with an ordinary fluorescent material, a delayed fluorescent material can realize a higher emission efficiency.

As such a delayed fluorescent material, there has been proposed a benzene derivative having a heteroaryl group such as a carbazolyl group or a diphenylamino group and at least two cyano groups, and it has been confirmed an organic EL device using the benzene derivative in the light emitting layer can realize a high light emission efficiency (see PTL 1).

NPL 1 reports that a carbazolyldicyanobenzene derivative (4CzTPN) is a thermal activation-type delayed fluorescent material, and that an organic electroluminescent device using the carbazolyldicyanobenzene derivative attained a high internal EL quantum efficiency.

### CITATION LIST

### Patent Literature

PTL 1: JP2014-43541A

### Non-Patent Literature

NPL 1: H. Uoyama, et al., Nature 492, 234 (2012)

### SUMMARY OF INVENTION

### Technical Problem

As described above, PTL 1 and NPL 1 report that an organic electroluminescent device using a delayed fluorescent material attained a high emission efficiency. On the other hand, for providing a highly-practicable organic electroluminescent device, it is absolutely necessary to prolong a lifetime. However, it is not easy to secure a sufficient lifetime.

Given the situation, the present inventors have promoted assiduous studies for the purpose of improving the lifetime of an organic light emitting device utilizing a delayed fluorescent material.

### Solution to Problem

As a result of assiduous studies for attaining the above-mentioned object, the present inventors have found that, by using a host material, a delayed fluorescent material and a triplet-regulating compound satisfying specific requirements, in the light emitting layer and its adjacent layer, an organic light emitting device having a long emission lifetime and being stable can be realized. The present invention has been proposed based on such findings, and specifically has the following constitution.

[1] An organic light emitting device having a light emitting layer that contains a first organic compound and a second organic compound, and a barrier layer containing a triplet-regulating compound in contact with the light emitting layer, in which:
the second organic compound is a delayed fluorescent material,
the first organic compound, the second organic compound and the triplet-regulating compound satisfy the following requirements (a) and (b):

$$Requirement ( a ) \qquad {E}_{S 1} ( 1 ) > {E}_{S 1} ( Q ) > {E}_{S 1} ( 2 )$$

$$Requirement ( b ) \qquad {E}_{T 1} ( 1 ) > {E}_{T 1} ( 2 ) > {E}_{T 1} ( Q )$$

where:
E_{S1}(1) represents the lowest excited singlet energy of the first organic compound,
E_{S1}(2) represents the lowest excited singlet energy of the second organic compound,
E_{S1}(Q) represents the lowest excited singlet energy of the triplet-regulating compound,
E_{T1}(1) represents the lowest excited triplet energy at 77K of the first organic compound,
E_{T1}(2) represents the lowest excited triplet energy at 77K of the second organic compound,
E_{T1}(Q) represents the lowest excited triplet energy at 77K of the triplet-regulating compound.
   [2] The organic light emitting device according to [1], in which the light emitting layer further contains a third organic compound, satisfying the following requirements (a1) and (b1):

$$Requirement ( a 1 ) \qquad {E}_{S 1} ( 1 ) > {E}_{S 1} ( Q ) > {E}_{S 1} ( 2 ) > {E}_{S 1} ( 3 )$$

$$Requirement ( b 1 ) \qquad {E}_{T 1} ( 1 ) > {E}_{T 1} ( 2 ) > {E}_{T 1} ( 3 ) > {E}_{T 1} ( Q )$$

where:
E_{S1}(3) represents the lowest excited singlet energy of the third organic compound,
E_{T1}(3) represents the lowest excited triplet energy at 77K of the third organic compound.
   [3] The organic light emitting device according to [1] or [2], in which the concentration of the triplet-regulating compound in the barrier layer is more than 50%.
   [4] The organic light emitting device according to any one of [1] to [3], in which the triplet-regulating compound has a structure represented by the following general formula (15):

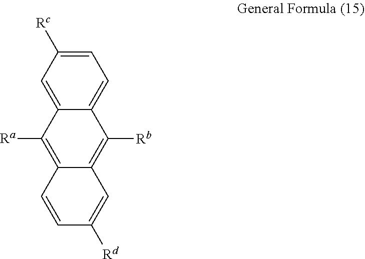

where R^{a} and R^{b} each independently represent a substituted or unsubstituted aryl group, R^{c} and R^{d} each independently represent a hydrogen atom, a deuterium atom, a substituted or unsubstituted alkyl group, a substituted or unsubstituted alkoxy group, a substituted or unsubstituted aryl group, a substituted or unsubstituted aryloxy group, a substituted or unsubstituted amino group, a halogen atom, a cyano group, or a substituted or unsubstituted silyl group.
[5] The organic light emitting device according to any one of [1] to [4] having the light emitting layer between an anode and a cathode, in which the barrier layer is an electron barrier layer formed between the anode and the light emitting layer.
[6] The organic light emitting device according to any one of [1] to [5] having the light emitting layer between an anode and a cathode, in which the barrier layer is a hole barrier layer formed between the cathode and the light emitting layer.
[7] The organic light emitting device according to any one of [1] to [6], in which the second organic compound is such that the energy difference ΔEₛₜ between the lowest excited singlet state and the lowest excited triplet state at 77K is 0.3 eV or less.
[8] The organic light emitting device according to any one of [2] to [7], in which the light emitting layer contains the third organic compound such that the energy difference ΔEₛₜ between the lowest excited singlet state and the lowest excited triplet state at 77K is 0.3 eV or less.
[9] The organic light emitting device according to any one of [1] to [8], in which the light emitting layer is formed of a compound alone composed of atoms selected from the group consisting of a carbon atom, a hydrogen atom, a deuterium atom, a nitrogen atom, a boron atom, an oxygen atom and a sulfur atom.

The organic light emitting device according to any one of [1] to [9], in which the first organic compound, the second organic compound and the triplet-regulating compound each are independently a compound formed of atoms selected from the group consisting of a carbon atom, a hydrogen atom, a deuterium atom and a nitrogen atom.

The organic light emitting device according to any one of [1] to [10], in which the triplet-regulating compound is a compound composed of a carbon atom and a hydrogen atom alone.

The organic light emitting device according to any one of [1] to [11], in which the second organic compound contains a cyanobenzene structure.

A method for producing an organic light emitting device, including:
forming a light emitting layer containing a first organic compound and a second organic compound of a delayed fluorescent material, and forming a barrier layer containing a triplet-regulating compound so as to be in contact with the light emitting layer, or including:
forming a barrier layer containing a triplet-regulating compound, and forming a light emitting layer containing a first organic compound and a second organic compound of a delayed fluorescent material so as to be in contact with the barrier layer, in which:
the first organic compound, the second organic compound and the triplet-regulating compound satisfy the following requirements (a) and (b).

$${E}_{S 1} ( 1 ) > {E}_{S 1} ( Q ) > {E}_{S 1} ( 2 ) \qquad Requirement ( a )$$

$${E}_{T 1} ( 1 ) > {E}_{T 1} ( 2 ) > {E}_{T 1} ( Q ) \qquad Requirement ( b )$$

where:
E_{S1}(1) represents the lowest excited singlet energy of the first organic compound,
E_{S1}(2) represents the lowest excited singlet energy of the second organic compound,
E_{S1}(Q) represents the lowest excited singlet energy of the triplet-regulating compound,
E_{T1}(1) represents the lowest excited triplet energy at 77K of the first organic compound,
E_{T1}(2) represents the lowest excited triplet energy at 77K of the second organic compound,
E_{T1}(Q) represents the lowest excited triplet energy at 77K of the triplet-regulating compound.

The method for producing an organic light emitting device according to [13], in which the light emitting layer further contains a third organic compound, satisfying the following requirements (a1) and (b1):

$${E}_{S 1} ( 1 ) > {E}_{S 1} ( Q ) > {E}_{S 1} ( 2 ) > {E}_{S 1} ( 3 ) \qquad Requirement ( a1 )$$

$${E}_{T 1} ( 1 ) > {E}_{T 1} ( 2 ) > {E}_{T 1} ( 3 ) > {E}_{T 1} ( Q ) \qquad Requirement ( b1 )$$

where:
E_{S1} (1) represents the lowest excited singlet energy of the first organic compound.
E_{S1}(2) represents the lowest excited singlet energy of the second organic compound,
E_{S1}(3) represents the lowest excited singlet energy of the third organic compound,
E_{S1}(Q) represents the lowest excited singlet energy of the triplet-regulating compound,
E_{T1}(1) represents the lowest excited triplet energy at 77K of the first organic compound,
E_{T1}(2) represents the lowest excited triplet energy at 77K of the second organic compound,
E_{T1}(3) represents the lowest excited triplet energy at 77K of the third organic compound.
E_{T1}(Q) represents the lowest excited triplet energy at 77K of the triplet-regulating compound.

A design method for a light emitting composition, including the following steps:
[Step 1] evaluating the light emission efficiency and the lifetime of a composition containing a first organic compound, a second organic compound of a delayed fluorescent material and a triplet-regulating compound, and satisfying the above-mentioned requirements (a) and (b),
[Step 2] carrying out at least once evaluating the light emission efficiency and the lifetime of a composition prepared by replacing at least one of the first organic compound, the second organic compound of a delayed fluorescent material and the triplet-regulating compound within the range satisfying the above-mentioned requirements (a) and (b),
[Step 3] displaying the evaluation results.

A design method for a light emitting composition, including the following steps:
[Step 1] evaluating the light emission efficiency and the lifetime of a composition containing a first organic compound, a second organic compound of a delayed fluorescent material and a triplet-regulating compound, and satisfying the above-mentioned requirements (a) and (b),
[Step 2] carrying out at least once evaluating the light emission efficiency and the lifetime of a composition prepared by replacing at least one of the first organic compound, the second organic compound of a delayed fluorescent material and the triplet-regulating compound within the range satisfying the above-mentioned requirements (a1) and (b1),
[Step 3] displaying the evaluation results.

A program of carrying out the method of [15] or [16].

### Advantageous Effects of Invention

The organic light emitting device of the present invention can realize long-life light emission. According to the design method and the program of the present invention, a light emitting composition for an organic light emitting device capable of realizing long-life light emission can be designed.

### BRIEF DESCRIPTION OF DRAWINGS

FIG. 1 This is a schematic cross-sectional view showing an example of a layer configuration of an organic electroluminescent device.

FIG. 2 This is a flow chart showing a process for carrying out a production method for an organic light emitting device.

FIG. 3 This is a flow chart showing an example of a procedure of a program.

### DESCRIPTION OF EMBODIMENTS

The contents of the present invention will be described in detail below. The constitutional elements may be described below with reference to representative embodiments and specific examples of the invention, but the invention is not limited to the embodiments and the examples. In the present description, a numerical range expressed as “to” means a range that includes the numerical values described before and after “to” as the lower limit and the upper limit. In the present description, the phrase “consisting of” means that the phrase “consisting of” is composed of only the components described before the phrase “consisting of” and does not contain any others. The isotope species of the hydrogen atom existing in the molecule of the compound used in the present invention is not specifically limited, and for example, all hydrogen atoms in the molecule can be ¹H, or a part or all can be ²H (deuterium D).

### (Characteristics of Organic Light Emitting Device)

The organic light emitting device of the present invention contains a first organic compound, a second organic compound and a triplet-regulating compound. Of these, the second organic compound is a delayed fluorescent material. With that, these organic compounds satisfy the following requirements (a) and (b).

$${E}_{S 1} ( 1 ) > {E}_{S 1} ( Q ) > {E}_{S 1} ( 2 ) \qquad Requirement ( a )$$

$${E}_{T 1} ( 1 ) > {E}_{T 1} ( 2 ) > {E}_{T 1} ( Q ) \qquad Requirement ( b )$$

In a preferred embodiment of the present invention, the organic light emitting device of the present invention contains a first organic compound, a second organic compound, a third organic compound and a triplet-regulating compound. Of these, the second organic compound is a delayed fluorescent material. With that, these organic compounds satisfy the following requirements (a1) and (b1).

$${E}_{S 1} ( 1 ) > {E}_{S 1} ( Q ) > {E}_{S 1} ( 2 ) > {E}_{S 1} ( 3 ) \qquad Requirement ( a1 )$$

$${E}_{T 1} ( 1 ) > {E}_{T 1} ( 2 ) > {E}_{T 1} ( 3 ) > {E}_{T 1} ( Q ) \qquad Requirement ( b1 )$$

In the present invention, E_{S1}(1) represents the lowest excited singlet energy of the first organic compound, E_{S1}(2) represents the lowest excited singlet energy of the second organic compound, E_{S1}(3) represents the lowest excited singlet energy of the third organic compound, E_{S1}(Q) represents the lowest excited singlet energy of the triplet-regulating compound. In the present invention, eV is employed as the unit.

E_{T1}(1) represents the lowest excited triplet energy at 77K (Kelvin) of the first organic compound, E_{T1}(2) represents the lowest excited triplet energy at 77K of the second organic compound, E_{T1}(3) represents the lowest excited triplet energy at 77K of the third organic compound. E_{T1}(Q) represents the lowest excited triplet energy at 77K of the triplet-regulating compound. In the present invention, eV is employed as the unit.

When the requirement (a) and the requirement (b) are satisfied at the same time, the lowest excited singlet energy E_{S1}(2) and the lowest excited triplet energy E_{T1}(2) of the second organic compound are both between the lowest excited singlet energy E_{S1}(Q) and the lowest excited triplet energy E_{T1}(Q) of the triplet-regulating compound. When the requirement (a1) and the requirement (b1) are satisfied at the same time, the lowest excited single energy E_{S1}(2) and the lowest excited triplet energy E_{T1}(2) of the second organic compound, and the lowest excited singlet energy E_{S1}(3) and the lowest excited triplet energy E_{T1}(3) of the third organic compound are all between the lowest excited singlet energy E_{S1}(Q) and the lowest excited triplet energy E_{T1}(Q) of the triplet-regulating compound. Consequently, of the triplet-regulating compound, the difference between the lowest excited singlet energy and the lowest excited triplet energy at 77K, ΔE_{T1}(Q) is larger than that of the second organic compound and the third organic compound. Preferably, ΔE_{T1}(Q) of the triplet-regulating compound is 0.5 eV or more, more preferably 0.6 eV or more, even more preferably 0.7 eV or more. ΔE_{T1}(Q) of the triplet-regulating compound can be within a range of 1.5 eV or less, or can be within a range of 1.2 eV or less, or can be within a range of 0.9 eV.

The lowest excited singlet energy difference between the triplet-regulating compound and the second organic compound, E_{S1}(Q)−E_{S1}(2) is preferably 0.05 eV or more, more preferably 0.10 eV or more, and can be 0.15 eV or more. E_{S1}(Q)−E_{S1}(2) can be, for example, within a range of 0.7 eV or less, or can be within a range of 0.5 eV or less, or can be within a range of 0.3 eV or less.

The lowest excited triplet energy difference between the third organic compound and the triplet-regulating compound, E_{T1}(3)−E_{T1}(Q) is preferably 0.10 eV or more, more preferably 0.30 eV or more, and can be 0.45 eV or more. E_{T1}(3)−E_{T1}(Q) can be, for example, within a range of 0.9 eV or less, or can be within a range of 0.7 eV or less, or can be within a range of 0.5 eV or less.

The lowest excited singlet energy difference between the first organic compound and the second organic compound, E_{S1}(1)−E_{S1}(2) can be within a range of 0.3 eV or more, or can be within a range of 0.5 eV or more, or can be within a range of 0.7 eV or more. Also it can be within a range of 1.6 eV or less, or can be within a range of 1.3 eV or less, or can be within a range of 0.9 eV or less.

The lowest excited singlet energy difference between the first organic compound and the triplet-regulating organic compound, E_{S1}(1)−E_{S1}(Q) can be within a range of 0.2 eV or more, or can be within a range of 0.4 eV or more, or can be within a range of 0.6 eV or more. Also it can be within a range of 1.5 eV or less, or can be within a range of 1.2 eV or less, or can be within a range of 0.8 eV or less.

The lowest excited triplet energy of the first organic compound E_{T1}(1) can be larger than the lowest excited singlet energy E_{S1}(Q) of the triplet-regulating compound. For example, E_{T1}(1)−E_{S1}(Q) can be within a range of 0.05 eV or more, or can be within a range of 0.10 eV or more, or can be within a range of 0.15 eV or more. Also it can be within a range of 0.7 eV or less, or can be within a range of 0.5 eV or less, or can be within a range of 0.3 eV or less.

When the light emitting layer of the organic light emitting device of the present invention contains the first organic compound, the second organic compound and the third organic compound, the content of each compound preferably satisfies the following requirement (c).

$$Conc ( 1 ) > Conc ( 2 ) > Conc ( 3 ) \qquad Requirement ( c )$$

Conc(1) represents the concentration of the organic compound in the light emitting layer, Conc(2) represents the concentration of the second organic compound in the light emitting layer, Conc(3) represents the concentration of the third organic compound in the light emitting layer. In the present invention, % by weight is employed as the unit.

Preferably, Conc(1) in the organic light emitting device of the present invention is 30% by weight or more, or can be within a range of 50% by weight or more, or can be within a range of 65% by weight or more, and also can be within a range of 99% by weight or less, or can be within a range of 85% by weight or less, or can be within a range of 75% by weight or less.

Preferably, Conc(2) in the organic light emitting device of the present invention is preferably 10% by weight or more, or can be within a range of 20% by weight or more, or can be within a range of 30% by weight or more, and also can be within a range of 45% by weight or less, or can be within a range or 40% by weight or less, or can be within a range of 35% by weight or less.

When the light emitting layer of the organic light emitting device of the present invention contains the third organic compound, Conc(3) is preferably 5% by weight or less, more preferably 3% by weight or less. Conc(3) can be within a range of 1% by weight or less, or can be within a range of 0.5% by weight or less. Also it can be within a range of 0.01% by weight or more, or can be within a range of 0.1% by weight or more, or can be within a range of 0.3% by weight or more. Further, preferably, the following requirement (d) is satisfied.

Conc(2)/Conc(3)>5 Requirement (d)

Conc(2)/Conc(3) can be within a range of 10 or more, or can be within a range of 30 or more, or can be within a range of 50 or more, and can be within a range of 500 or less, or can be within a range of 300 or less, or can be within a range of 100 or less.

The organic light emitting device of the present invention contains a triplet-regulating compound in the barrier layer laminated on the light emitting layer. The triplet-regulating compound-containing barrier layer can be laminated on the light emitting layer, or the light emitting layer can be laminated on the triplet-regulating compound-containing barrier layer. The device can have a configuration where the triplet-regulating compound-containing barrier layer formed on both surfaces of the light emitting layer, that is, the device can have a configuration of a barrier layer, a light emitting layer and a barrier layer laminated in that order. At that time, the thickness and the constituent components of each barrier layer formed on both surfaces of the light emitting layer can be the same. The barrier layers formed on both surfaces of the light emitting layer can differ from each other in at least one of the thickness or the constituent components.

In the case where the organic light emitting device of the present invention has a structure that has a light emitting layer-containing organic layer between the anode and the cathode, the triplet-regulating compound-containing barrier layer can be an electron barrier layer formed so as to be in contact with (laminated on) the anode side of the light emitting layer, or can be a hole barrier layer formed so as to be in contact with (laminated on) the cathode side of the light emitting layer. Both a triplet-regulating compound-containing electron barrier layer and a triplet-regulating compound-containing hole barrier layer can be formed in the device.

The barrier layer can be composed of a triplet-regulating compound alone, or can contain both a triplet-regulating compound and any other compound than a triplet-regulating compound. In the latter case, the concentration of the triplet-regulating compound is preferably 50% by weight or more, more preferably 80% by weight or more, and can be, for example, 95% by weight or more, or 99% by weight or more.

The thickness of the barrier layer is preferably 1 nm or more, more preferably 3 nm or more, can be, for example 5 nm or more. The thickness of the barrier layer is preferably 20 nm or less, more preferably 10 nm or less, and can be, for example, 7 nm or less.

### (First Organic Compound)

The first organic compound is an organic compound of which the lowest excited singlet energy and the lowest excited triplet energy are larger than the second organic compound and the triplet-regulating compound. When the light emitting layer contains the third organic compound, the lowest excited singlet energy and the lowest excited triplet energy of the first organic compound are larger than those of the third organic compound. The first organic compound has a function as a host material for transporting carriers and a function of confining the energy of the second organic compound and the third organic compound in the first organic compound. With that, the energy formed by recombination of holes and electrons in the molecule can be efficiently converted into light emission.

Preferably, the first organic compound is an organic compound having a hole transporting capability and an electron transporting capability, capable of preventing prolongation of the wavelength of light emission, and having a high glass transition temperature. In a preferred embodiment of the present invention, the first organic compound is selected from compounds not emitting delayed fluorescence.

Preferred compounds usable as the first organic compound are shown below.

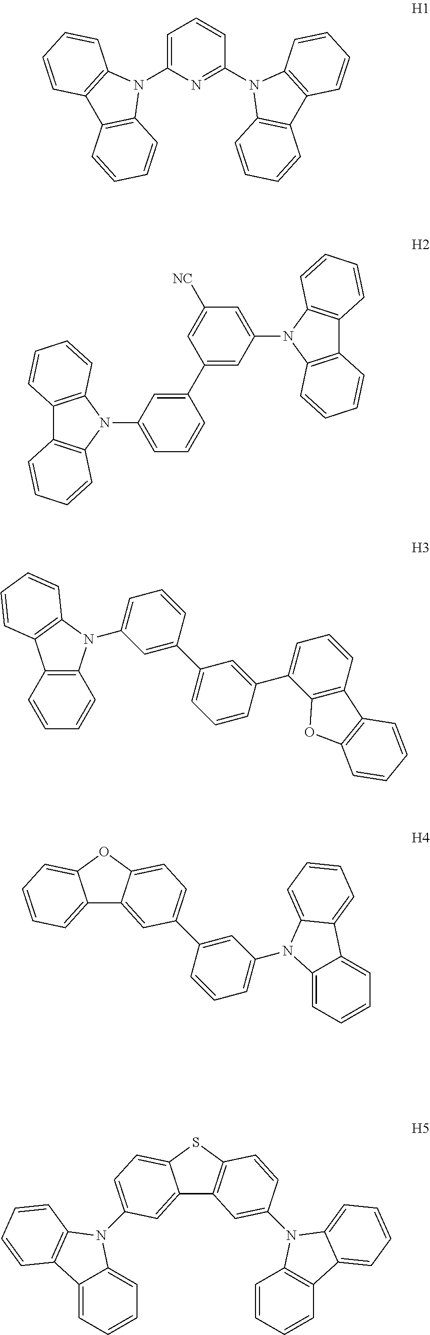 [SMILES: c1cc(-n2c3ccccc3c3ccccc32)nc(-n2c3ccccc3c3ccccc32)c1 ; N#Cc1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2oc2ccccc23)c1 ; c1cc(-c2ccc3oc4ccccc4c3c2)cc(-n2c3ccccc3c3ccccc32)c1 ; c1ccc2c(c1)c1ccccc1n2-c1ccc2sc3ccc(-n4c5ccccc5c5ccccc54)cc3c2c1]

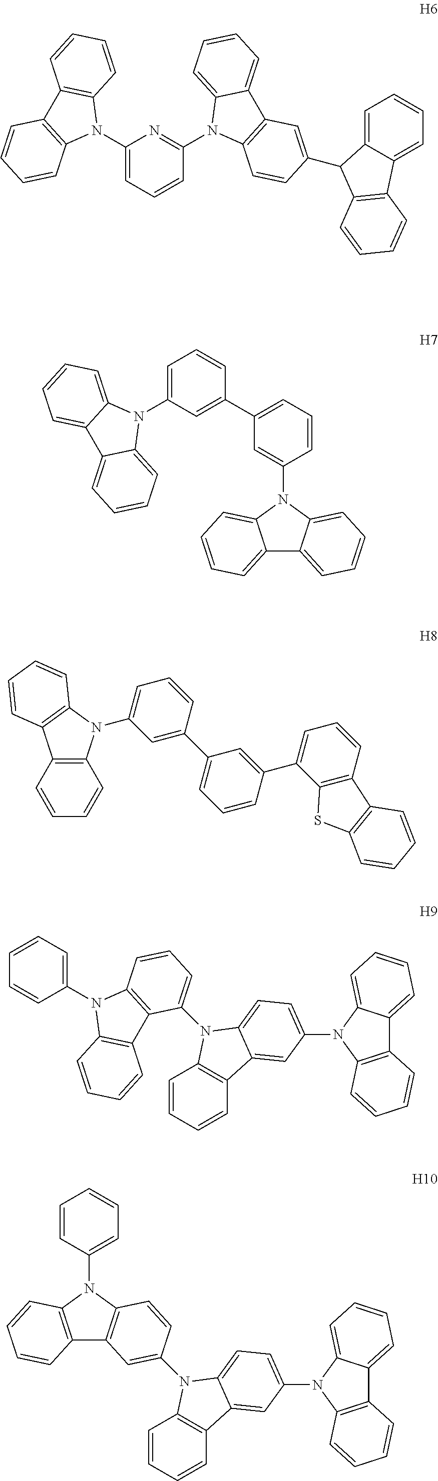 [SMILES: c1cc(-n2c3ccccc3c3ccccc32)nc(-n2c3ccccc3c3cc(C4c5ccccc5-c5ccccc54)ccc32)c1 ; c1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2sc2ccccc23)c1 ; c1ccc(-n2c3ccccc3c3c(-n4c5ccccc5c5cc(-n6c7ccccc7c7ccccc76)ccc54)cccc32)cc1 ; c1ccc(-n2c3ccccc3c3cc(-n4c5ccccc5c5cc(-n6c7ccccc7c7ccccc76)ccc54)ccc32)cc1]

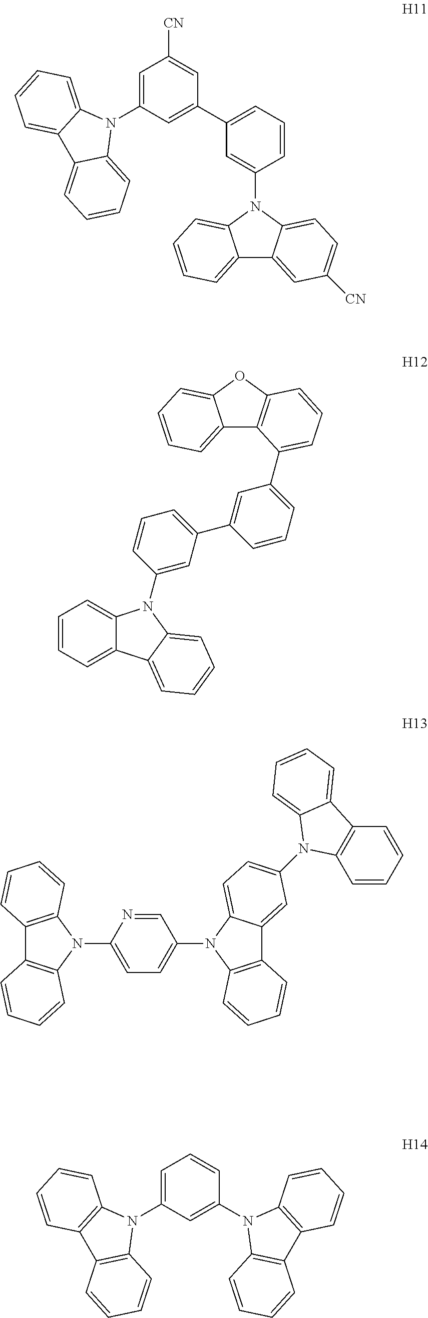 [SMILES: N#Cc1cc(-c2cccc(-n3c4ccccc4c4cc(C#N)ccc43)c2)cc(-n2c3ccccc3c3ccccc32)c1 ; c1cc(-c2cccc(-n3c4ccccc4c4ccccc43)c2)cc(-c2cccc3oc4ccccc4c23)c1 ; c1ccc2c(c1)c1ccccc1n2-c1ccc2c(c1)c1ccccc1n2-c1ccc(-n2c3ccccc3c3ccccc32)nc1 ; c1cc(-n2c3ccccc3c3ccccc32)cc(-n2c3ccccc3c3ccccc32)c1]

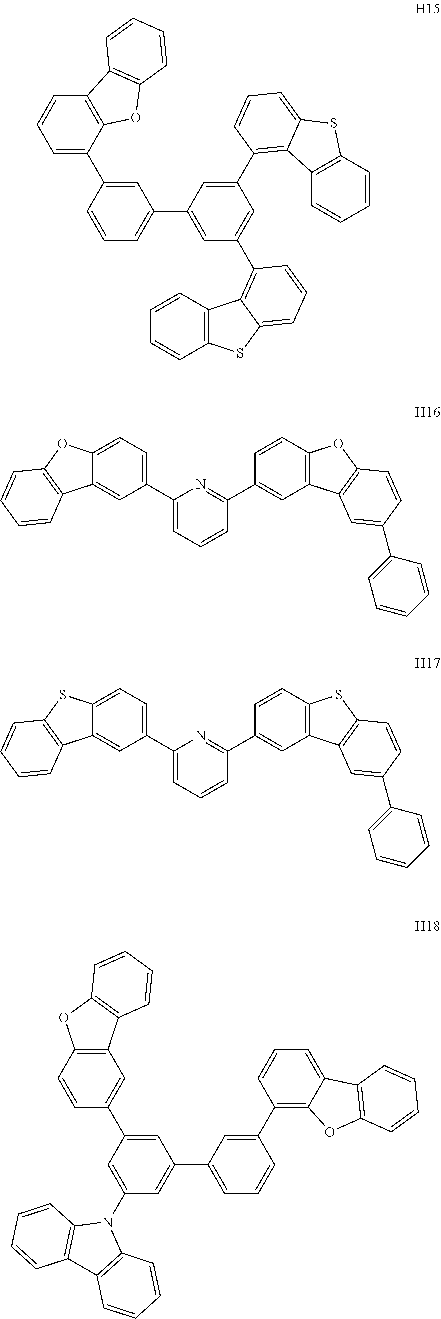 [SMILES: c1cc(-c2cc(-c3cccc4sc5ccccc5c34)cc(-c3cccc4sc5ccccc5c34)c2)cc(-c2cccc3c2oc2ccccc23)c1 ; c1ccc(-c2ccc3oc4ccc(-c5cccc(-c6ccc7oc8ccccc8c7c6)n5)cc4c3c2)cc1 ; c1ccc(-c2ccc3sc4ccc(-c5cccc(-c6ccc7sc8ccccc8c7c6)n5)cc4c3c2)cc1 ; c1cc(-c2cc(-c3ccc4oc5ccccc5c4c3)cc(-n3c4ccccc4c4ccccc43)c2)cc(-c2cccc3c2oc2ccccc23)c1]

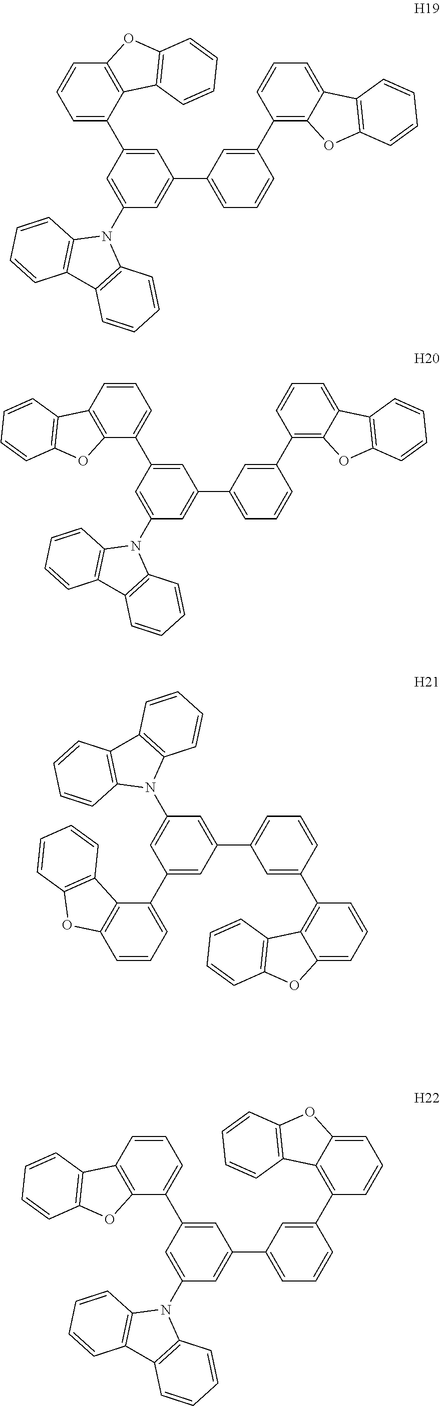 [SMILES: c1cc(-c2cc(-c3cccc4oc5ccccc5c34)cc(-n3c4ccccc4c4ccccc43)c2)cc(-c2cccc3c2oc2ccccc23)c1 ; c1cc(-c2cc(-c3cccc4c3oc3ccccc34)cc(-n3c4ccccc4c4ccccc43)c2)cc(-c2cccc3c2oc2ccccc23)c1 ; c1cc(-c2cc(-c3cccc4oc5ccccc5c34)cc(-n3c4ccccc4c4ccccc43)c2)cc(-c2cccc3oc4ccccc4c23)c1 ; c1cc(-c2cc(-c3cccc4c3oc3ccccc34)cc(-n3c4ccccc4c4ccccc43)c2)cc(-c2cccc3oc4ccccc4c23)c1]

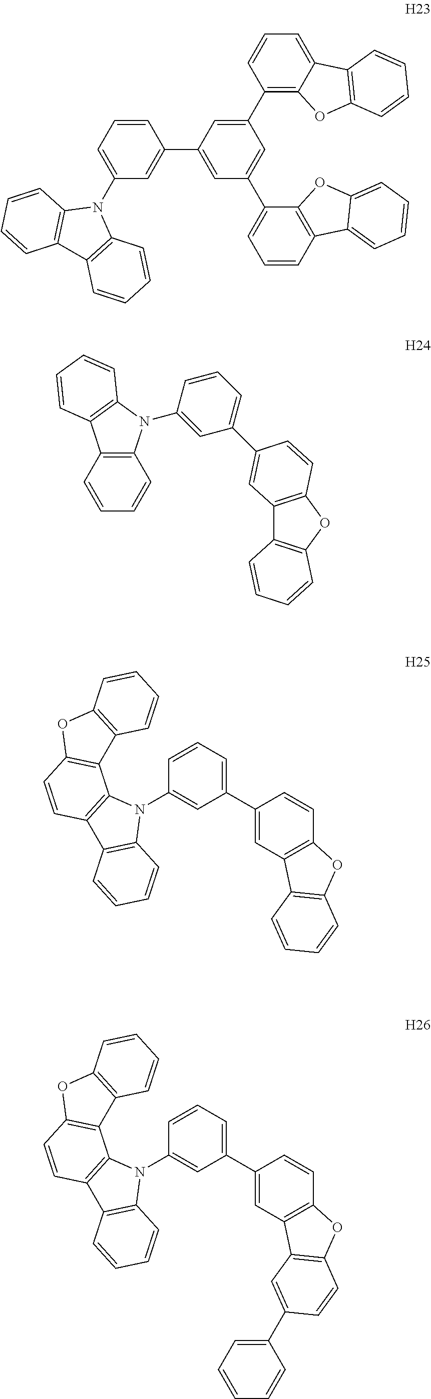 [SMILES: c1cc(-c2cc(-c3cccc4c3oc3ccccc34)cc(-c3cccc4c3oc3ccccc34)c2)cc(-n2c3ccccc3c3ccccc32)c1 ; c1cc(-c2ccc3oc4ccccc4c3c2)cc(-n2c3ccccc3c3ccccc32)c1 ; c1cc(-c2ccc3oc4ccccc4c3c2)cc(-n2c3ccccc3c3ccc4oc5ccccc5c4c32)c1 ; c1ccc(-c2ccc3oc4ccc(-c5cccc(-n6c7ccccc7c7ccc8oc9ccccc9c8c76)c5)cc4c3c2)cc1]

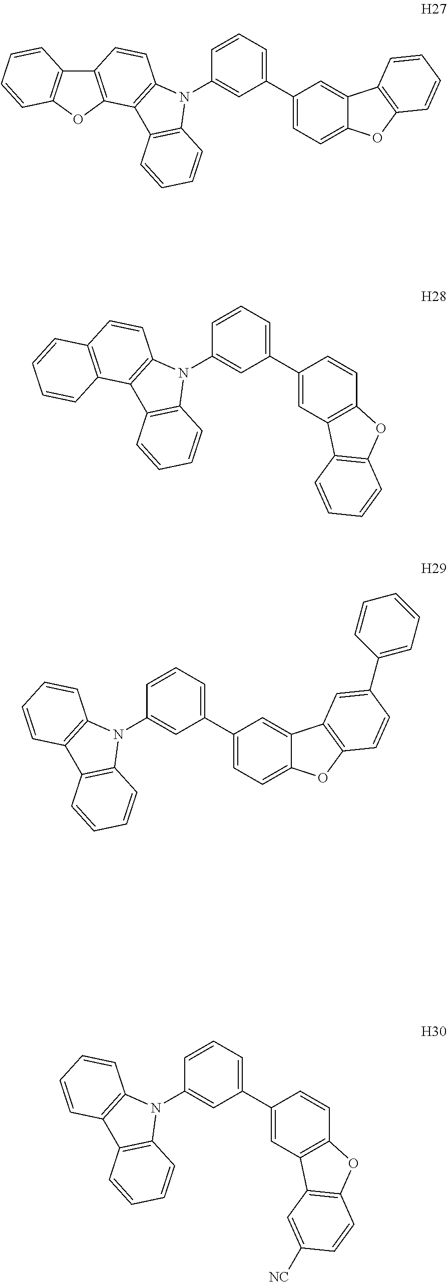 [SMILES: c1cc(-c2ccc3oc4ccccc4c3c2)cc(-n2c3ccccc3c3c4oc5ccccc5c4ccc32)c1 ; c1cc(-c2ccc3oc4ccccc4c3c2)cc(-n2c3ccccc3c3c4ccccc4ccc32)c1 ; c1ccc(-c2ccc3oc4ccc(-c5cccc(-n6c7ccccc7c7ccccc76)c5)cc4c3c2)cc1 ; N#Cc1ccc2oc3ccc(-c4cccc(-n5c6ccccc6c6ccccc65)c4)cc3c2c1]

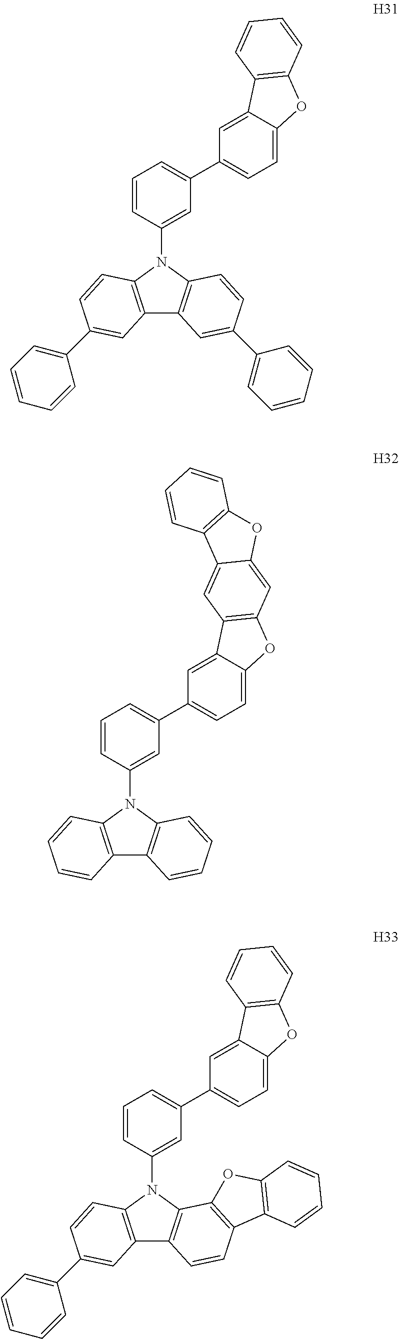 [SMILES: c1ccc(-c2ccc3c(c2)c2cc(-c4ccccc4)ccc2n3-c2cccc(-c3ccc4oc5ccccc5c4c3)c2)cc1 ; c1cc(-c2ccc3oc4cc5oc6ccccc6c5cc4c3c2)cc(-n2c3ccccc3c3ccccc32)c1 ; c1ccc(-c2ccc3c(c2)c2ccc4c5ccccc5oc4c2n3-c2cccc(-c3ccc4oc5ccccc5c4c3)c2)cc1]

### (Second Organic Compound)

The second organic compound for use in the organic light emitting device of the present invention is a delayed fluorescent material. In the present invention, a “delayed fluorescent material” is an organic compound which, in an excited state, undergoes reverse intersystem crossing from an excited triplet state to an excited singlet state, and which emits fluorescence (delayed fluorescence) in returning back from the excited singlet state to a ground state. In the invention, a compound which gives fluorescence having an emission lifetime of 100 ns (nanoseconds) or longer, when the emission lifetime is measured with a fluorescence lifetime measuring system (e.g., streak camera system by Hamamatsu Photonics KK), is referred to as a delayed fluorescent material.

Of the second organic compound, preferably, the difference between the excited lowest singlet energy and the excited lowest triplet energy at 77K, ΔE_{ST}(2) is 0.3 eV or less, more preferably 0.25 eV or less even more preferably 0.2 eV or less, further more preferably 0.15 eV or less, further more preferably 0.1 eV or less, further more preferably 0.07 eV or less, further more preferably 0.05 eV or less, further more preferably 0.03 eV or less, further more preferably 0.01 eV or less.

When ΔE_{ST}(2) is small, the second organic compound can readily undergo reverse intersystem crossing from the excited triplet state to the excited single state by thermal energy absorption and therefore can function as a thermal activation-type delayed fluorescent material. The thermal activation-type delayed fluorescent material can relatively readily undergo reverse intersystem crossing from the excited triplet state to the excited singlet state by absorbing the heat generated by the device, and therefore the resultant excited triplet energy can efficiently contribute toward light emission.

In the present invention, the lowest excited singlet energy (E_{S1}) and the lowest excited triplet energy (E_{T1}) of the compound are values determined according to the following process. ΔE_{ST} is a value determined by calculating E_{S1}−E_{T1}.

### (1) Lowest Excited Singlet Energy (E_{S1})

A thin film or a toluene solution (concentration: 10⁻⁵ mol/L) of the targeted compound is prepared as a measurement sample. The fluorescent spectrum of the sample is measured at room temperature (300 K). For the fluorescent spectrum, the emission intensity is on the vertical axis and the wavelength is on the horizontal axis. A tangent line is drawn to the rising of the emission spectrum on the short wavelength side, and the wavelength value λedge [nm] at the intersection between the tangent line and the horizontal axis is read. The wavelength value is converted into an energy value according to the following conversion expression to calculate E_{S1}.

$$Conversion Expression : {E}_{T 1} [ eV ] = 1239.85 / λ edge$$

For the measurement of the emission spectrum in Examples given below, an LED light source (by Thorlabs Corporation, M300L4) was used as an excitation light source along with a detector (by Hamamatsu Photonics K.K., PMA-12 Multichannel Spectroscope C10027-01).

### (2) Lowest Excited Triplet Energy (E_{T1})

The same sample as that for measurement of the lowest excited singlet energy (E_{S1}) is cooled to 77 [K] with liquid nitrogen, and the sample for phosphorescence measurement is irradiated with excitation light (300 nm), and using a detector, the phosphorescence thereof is measured. The emission after 100 milliseconds from irradiation with the excitation light is drawn as a phosphorescent spectrum. A tangent line is drawn to the rising of the phosphorescent spectrum on the short wavelength side, and the wavelength value λedge [nm] at the intersection between the tangent line and the horizontal axis is read. The wavelength value is converted into an energy value according to the following conversion expression to calculate E_{T1}.

$$Conversion Expression : {E}_{T 1} [ eV ] = 1239.85 / λ edge$$

The tangent line to the rising of the phosphorescent spectrum on the short wavelength side is drawn as follows. While moving on the spectral curve from the short wavelength side of the phosphorescent spectrum toward the maximum value on the shortest wavelength side among the maximum values of the spectrum, a tangent line at each point on the curve toward the long wavelength side is taken into consideration. With rising of the curve (that is, with increase in the vertical axis), the inclination of the tangent line increases. The tangent line drawn at the point at which the inclination value has a maximum value is referred to as the tangent line to the rising on the short wavelength side of the phosphorescent spectrum.

The maximum point having a peak intensity of 10% or less of the maximum peak intensity of the spectrum is not included in the maximum value on the above-mentioned shortest wavelength side, and the tangent line drawn at the point which is closest to the maximum value on the shortest wavelength side and at which the inclination value has a maximum value is referred to as the tangent line to the rising on the short wavelength side of the phosphorescent spectrum.

The second organic compound is a delayed fluorescent material of which the lowest excited singlet energy is smaller than that of the first organic compound and the triplet-regulating compound. Also the second organic compound is a delayed fluorescent material of which the lowest excite triplet energy is smaller than that of the first organic compound and of which the lowest excited triplet energy is larger than that of the triplet-regulating compound. When the light emitting layer contains the third organic compound, the second organic compound is a delayed fluorescent material of which the lowest excited singlet energy and the lowest excited triplet energy are larger than those of the third organic compound. The second organic compound can be a compound capable of emitting delayed fluorescence under some condition. In the case where the light emitting layer of the organic light emitting device of the present invention does not contain the third organic compound, the organic light emitting device of the present invention emits delayed fluorescence derived from the second organic compound. In the case where the light emitting layer of the organic light emitting device of the present invention contains the third organic compound, it is not essential that the organic light emitting device of the present invention emits delayed fluorescence derived from the second organic compound, and in the device, the light emission from the third organic compound is main light emission. In the organic light emitting device of the present invention, the second organic compound receives energy from the first organic compound in an excited singlet state, and transitions into an excited singlet state. Also the second organic compound can receive energy from the first organic compound in an excited triplet state to transition into an excited triplet state. Since ΔE_{ST} of the second organic compound is small, the second organic compound in an excited triplet state can readily undergo reverse intersystem crossing to be in the second organic compound in an excited singlet state. The second organic compound in an excited singlet state formed through the process emits fluorescence (delayed fluorescence) when returning back to a ground state in the absence of the third organic compound. However, when the third organic compound is present, the second organic compound in an excited singlet state gives the energy to the third organic compound to make the third organic compound transition to be in an excited singlet state.

When the light emitting layer does not contain the third organic compound, in the organic light emitting device of the present invention, the second organic compound mainly emits light. In that case, the maximum emission wavelength of the second organic compound is not specifically limited. Consequently, a light emitting material having a maximum emission wavelength in a visible region (380 to 780 nm) or a light emitting material having a maximum emission wavelength in an IR region (789 nm to 1 mm) can be appropriately selected and used. Preferred is a fluorescent material having a maximum emission wavelength in a visible region. For example, it is possible to select and use a light emitting material of which the maximum emission wavelength in a region of 380 to 780 nm falls within a range of 380 to 570 nm, or to select and use a light emitting material of which the maximum emission wavelength falls within a range of 380 to 500 nm, or to select and use a light emitting material of which the maximum emission wavelength falls within a range of 380 to 480 nm, or to select and use a light emitting material of which the maximum emission wavelength falls within a range of 420 to 480 nm.

In a preferred embodiment of the present invention, the constituent compounds are so selected and combined that the emission wavelength region of the first organic compound and the absorption wavelength region of the second organic compound can overlap with each other. In particular, it is preferable that the edge on the short wavelength side of the emission spectrum of the first organic compound can overlap with the edge on the long wavelength side of the absorption spectrum of the second organic compound (that is, the two can intersect with each other).

Preferred compounds usable as the second organic compounds are shown below. In the structural formulae of the following exemplary compounds, t-Bu represents a tertiary butyl group.

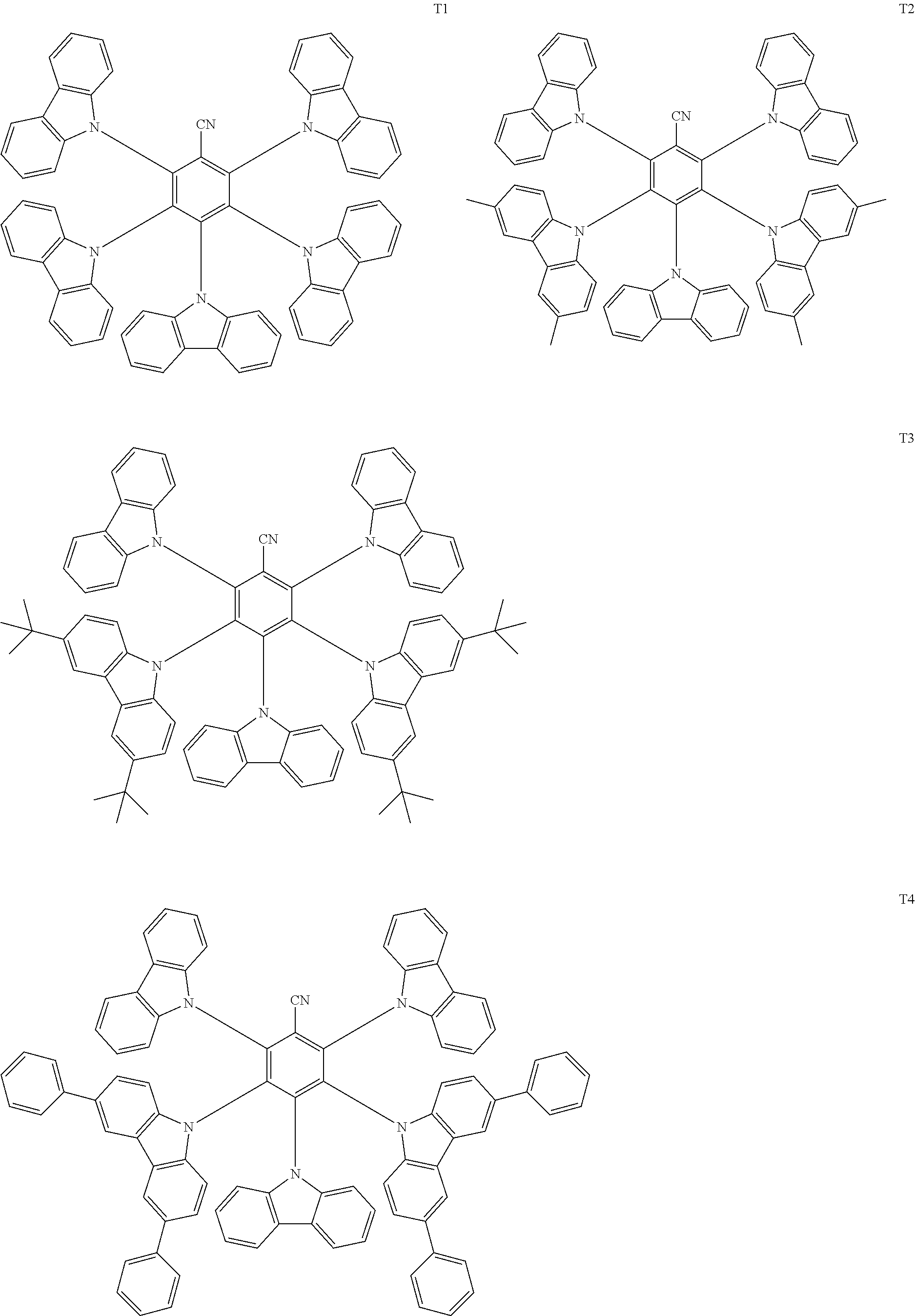

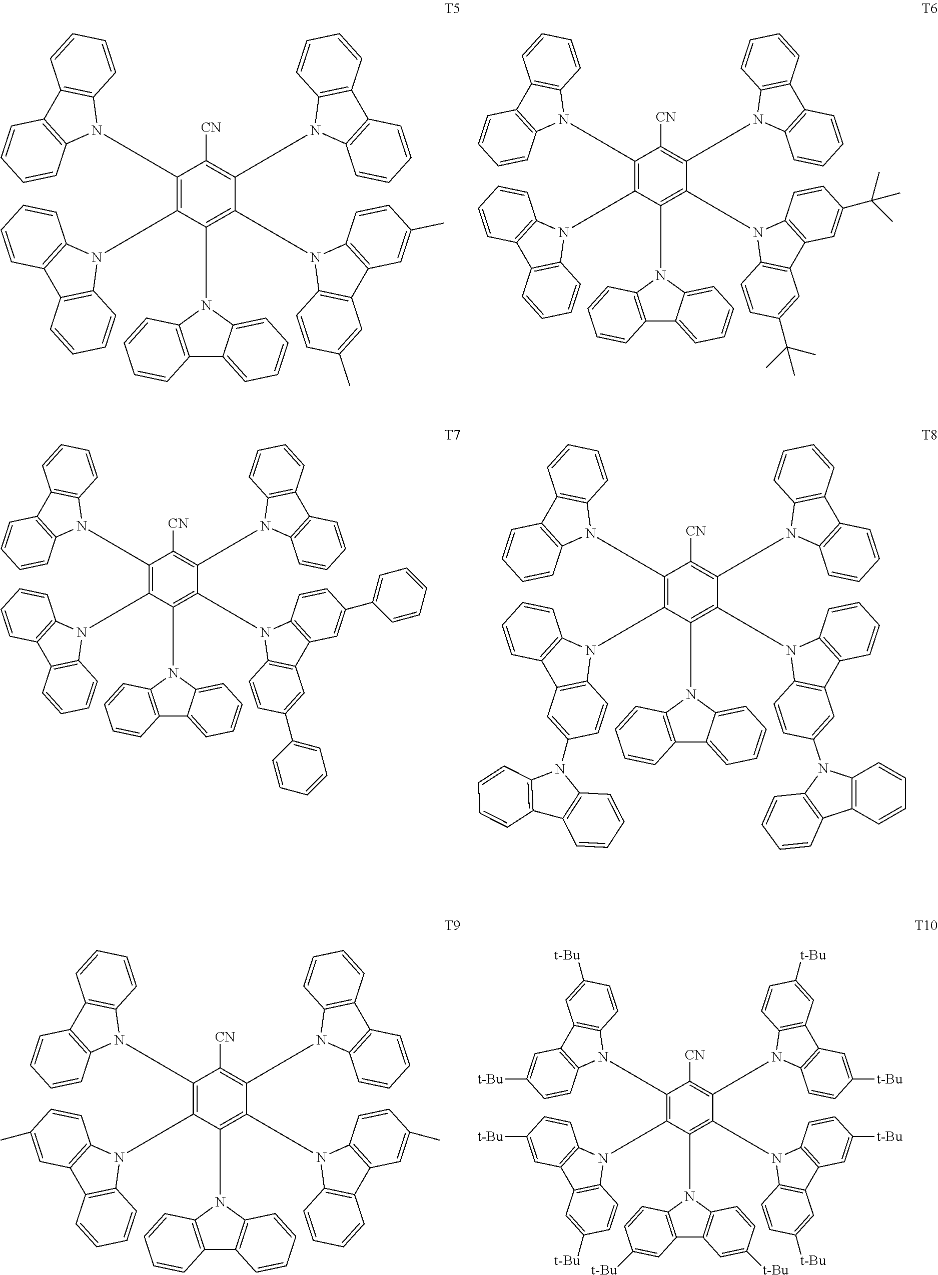

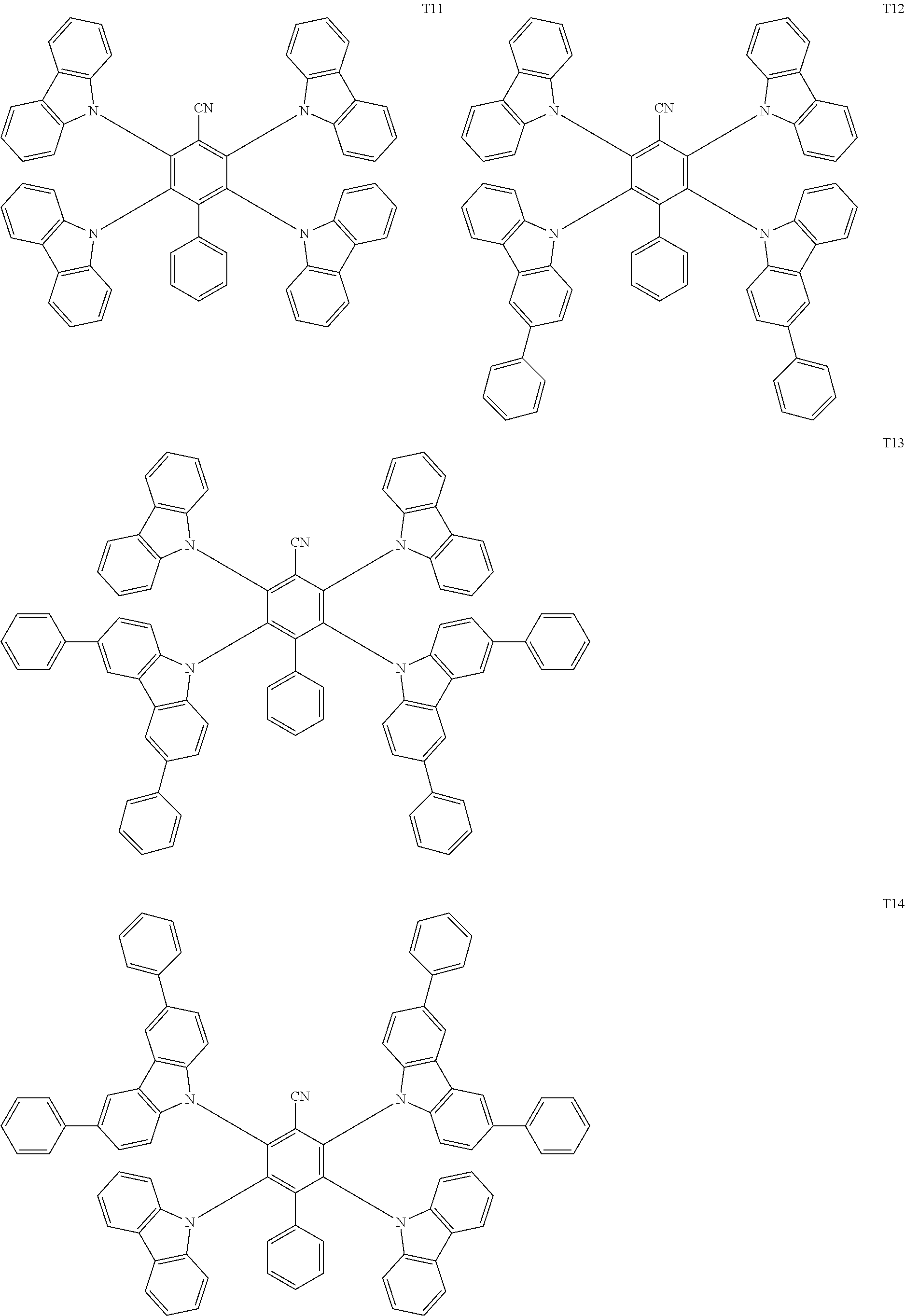

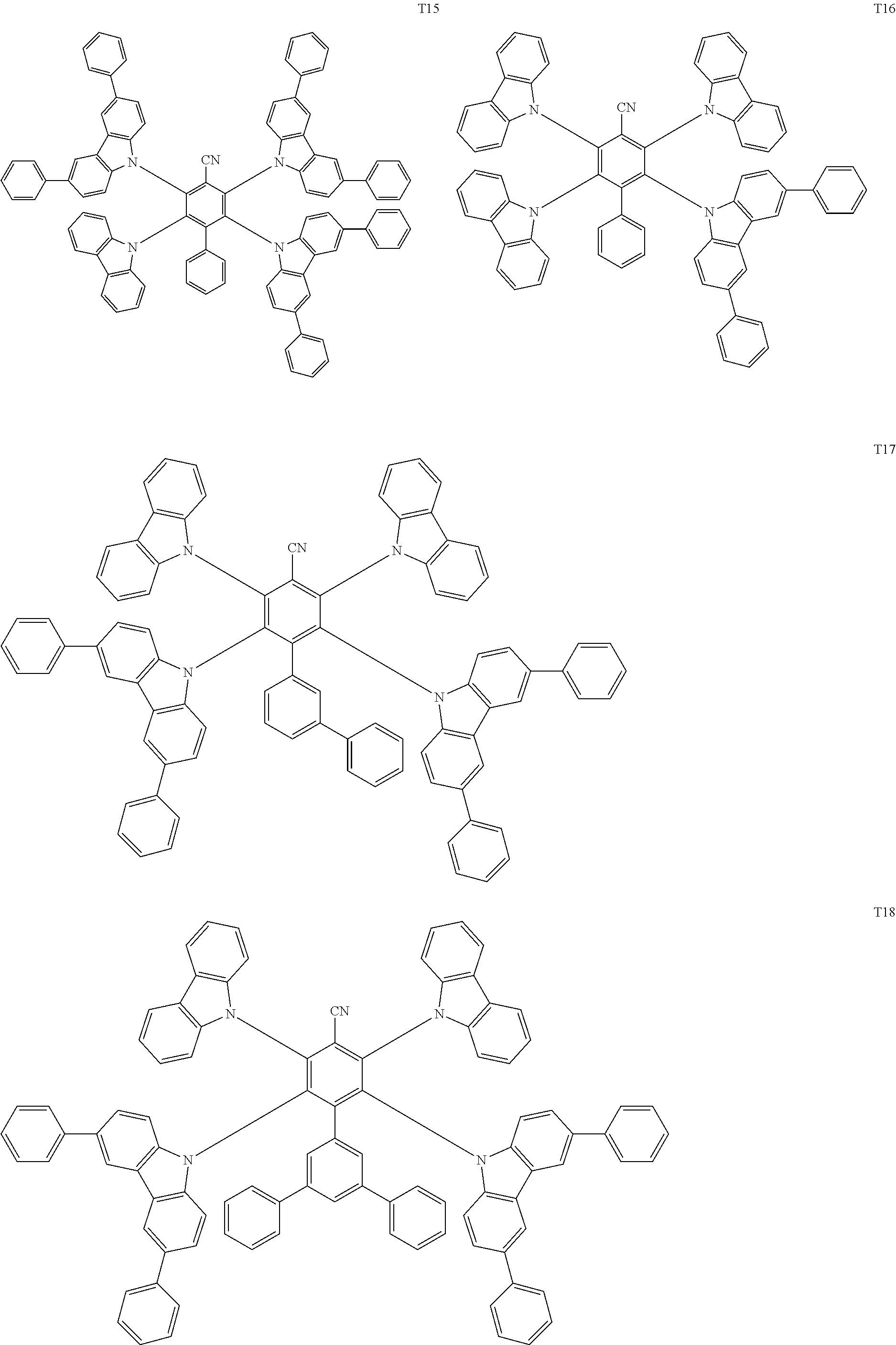

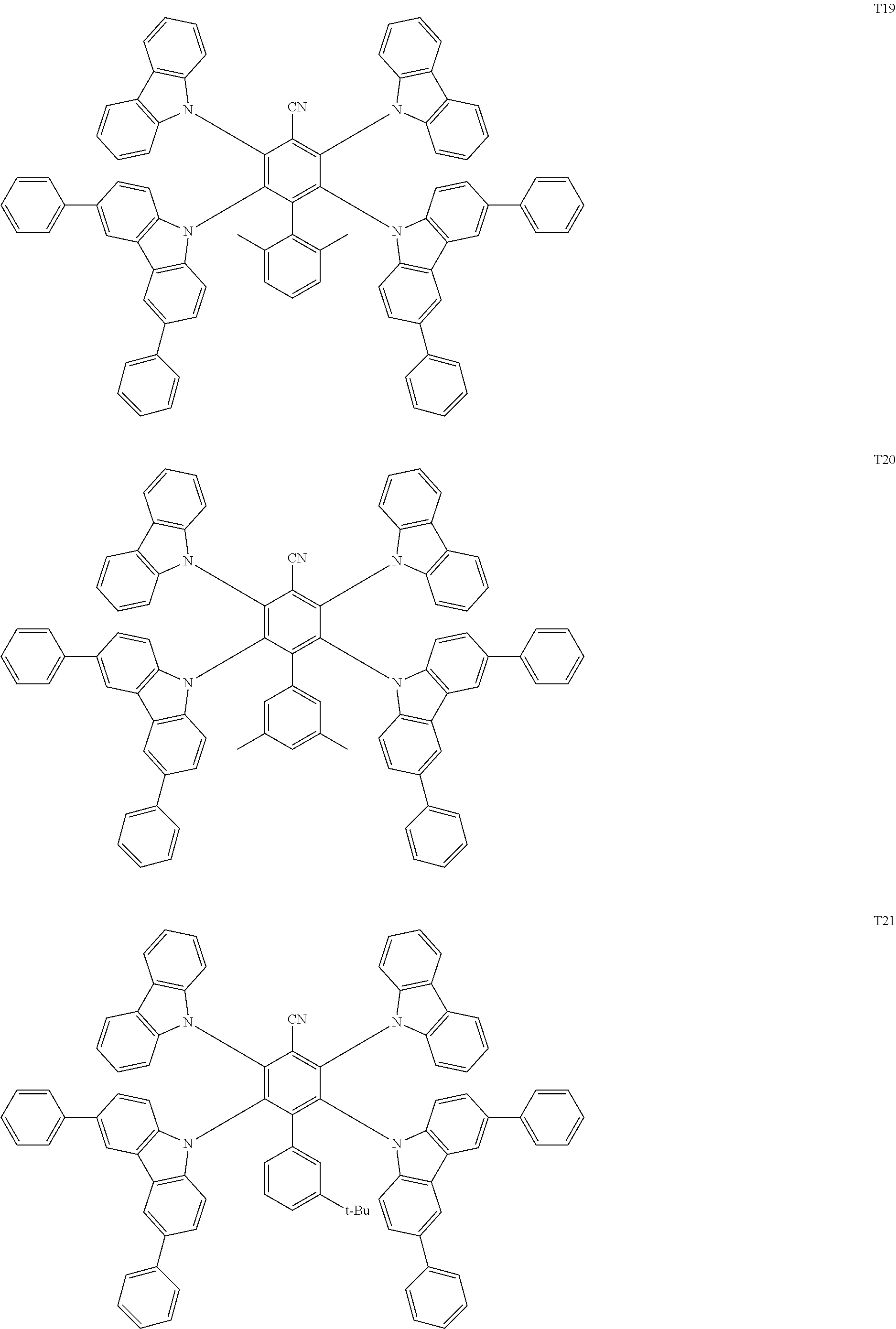 [SMILES: Cc1cccc(C)c1-c1c(-n2c3ccc(-c4ccccc4)cc3c3cc(-c4ccccc4)ccc32)c(-n2c3ccccc3c3ccccc32)c(C#N)c(-n2c3ccccc3c3ccccc32)c1-n1c2ccc(-c3ccccc3)cc2c2cc(-c3ccccc3)ccc21 ; Cc1cc(C)cc(-c2c(-n3c4ccc(-c5ccccc5)cc4c4cc(-c5ccccc5)ccc43)c(-n3c4ccccc4c4ccccc43)c(C#N)c(-n3c4ccccc4c4ccccc43)c2-n2c3ccc(-c4ccccc4)cc3c3cc(-c4ccccc4)ccc32)c1 ; CC(C)(C)c1cccc(-c2c(-n3c4ccc(-c5ccccc5)cc4c4cc(-c5ccccc5)ccc43)c(-n3c4ccccc4c4ccccc43)c(C#N)c(-n3c4ccccc4c4ccccc43)c2-n2c3ccc(-c4ccccc4)cc3c3cc(-c4ccccc4)ccc32)c1]

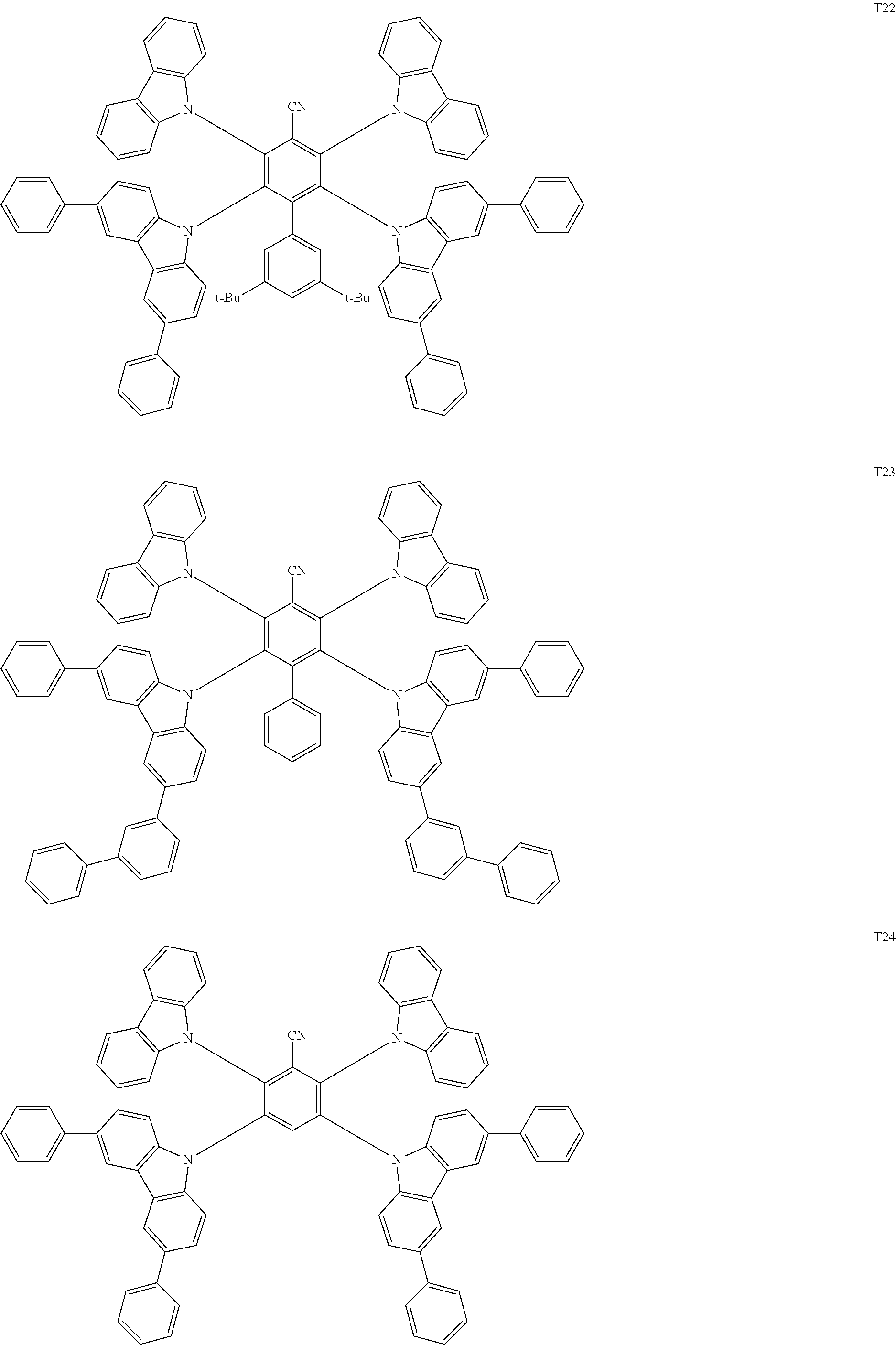 [SMILES: CC(C)(C)c1cc(-c2c(-n3c4ccc(-c5ccccc5)cc4c4cc(-c5ccccc5)ccc43)c(-n3c4ccccc4c4ccccc43)c(C#N)c(-n3c4ccccc4c4ccccc43)c2-n2c3ccc(-c4ccccc4)cc3c3cc(-c4ccccc4)ccc32)cc(C(C)(C)C)c1 ; N#Cc1c(-n2c3ccccc3c3ccccc32)c(-n2c3ccc(-c4ccccc4)cc3c3cc(-c4cccc(-c5ccccc5)c4)ccc32)c(-c2ccccc2)c(-n2c3ccc(-c4ccccc4)cc3c3cc(-c4cccc(-c5ccccc5)c4)ccc32)c1-n1c2ccccc2c2ccccc21 ; N#Cc1c(-n2c3ccccc3c3ccccc32)c(-n2c3ccc(-c4ccccc4)cc3c3cc(-c4ccccc4)ccc32)cc(-n2c3ccc(-c4ccccc4)cc3c3cc(-c4ccccc4)ccc32)c1-n1c2ccccc2c2ccccc21]

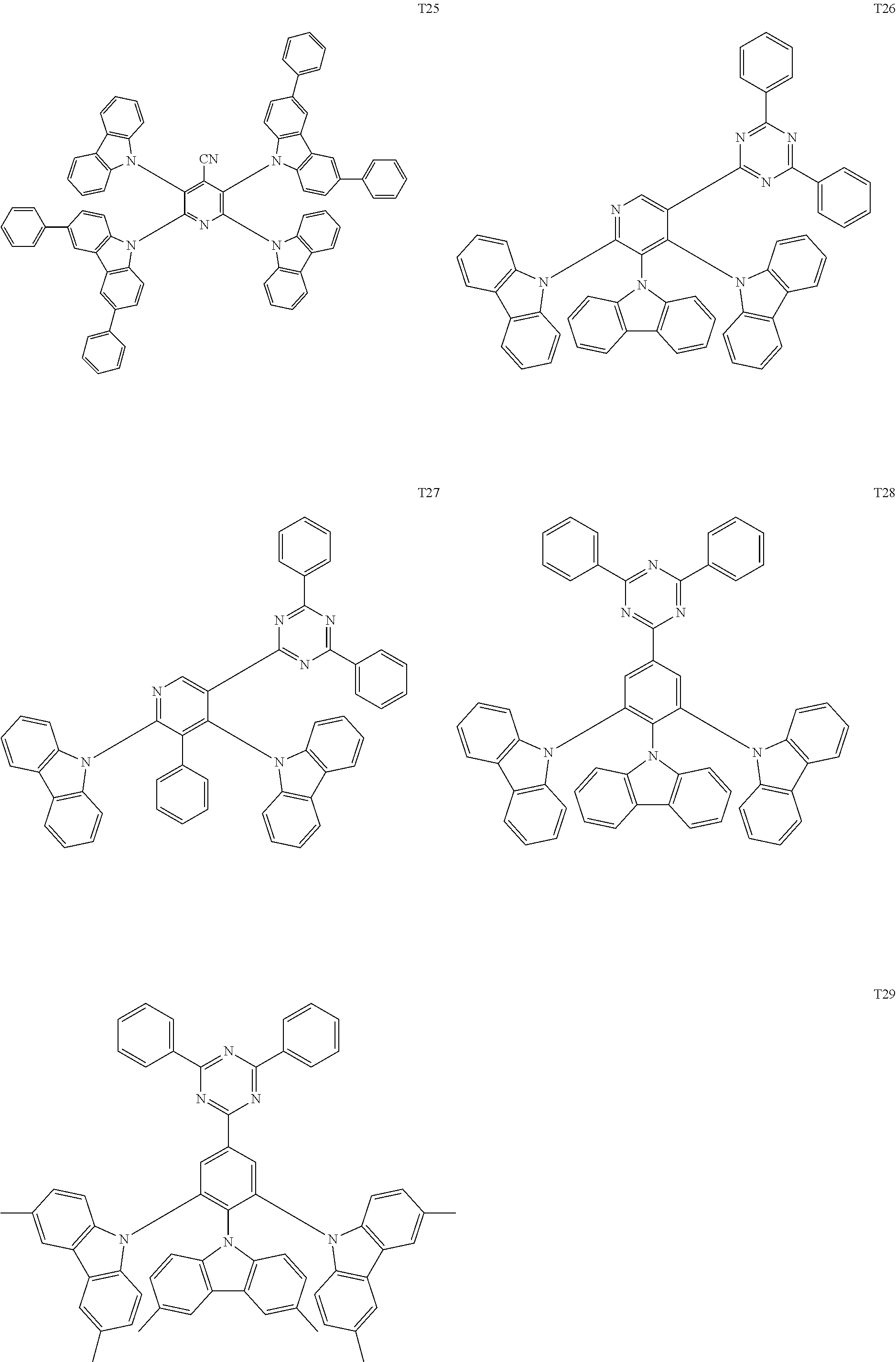

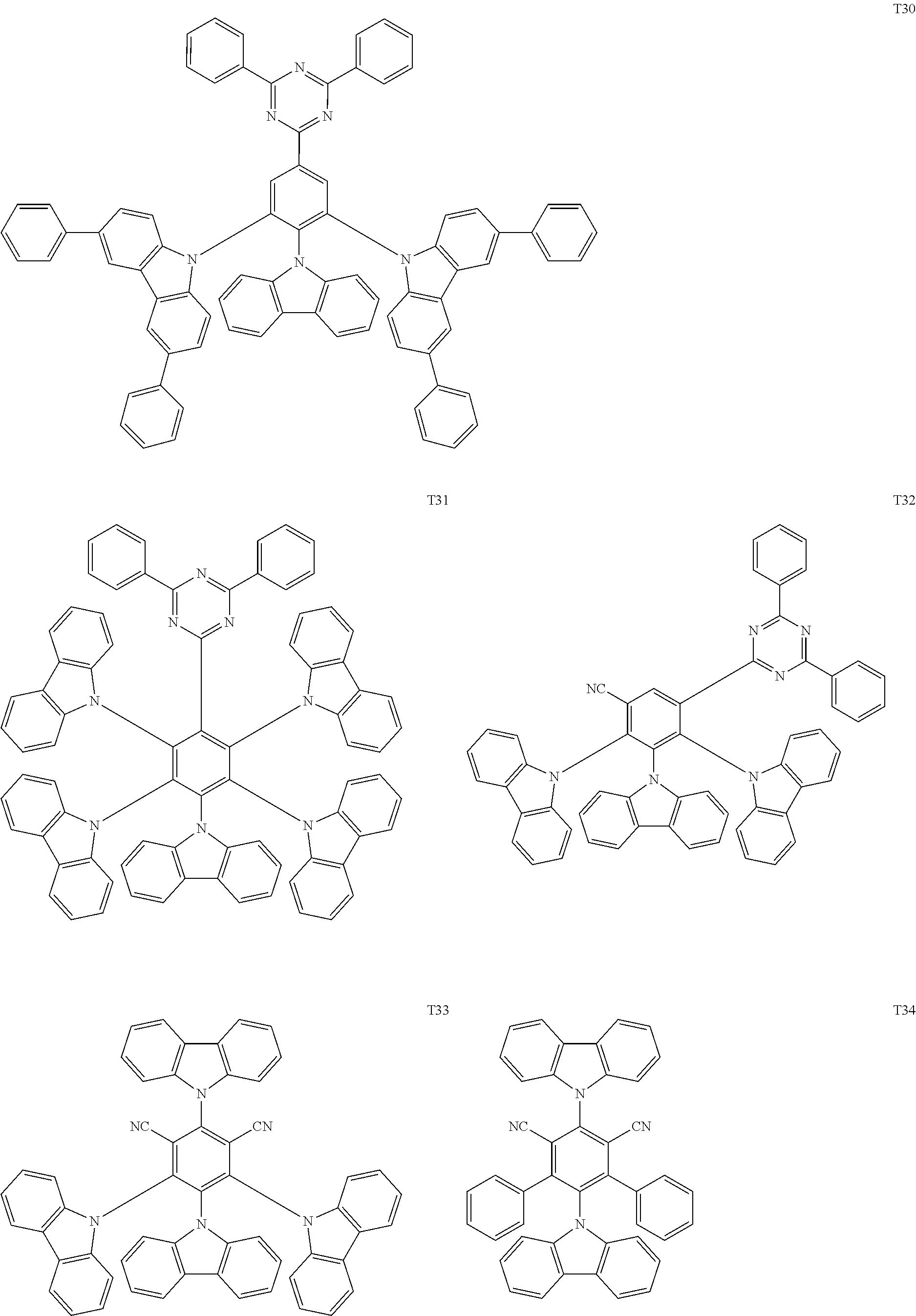

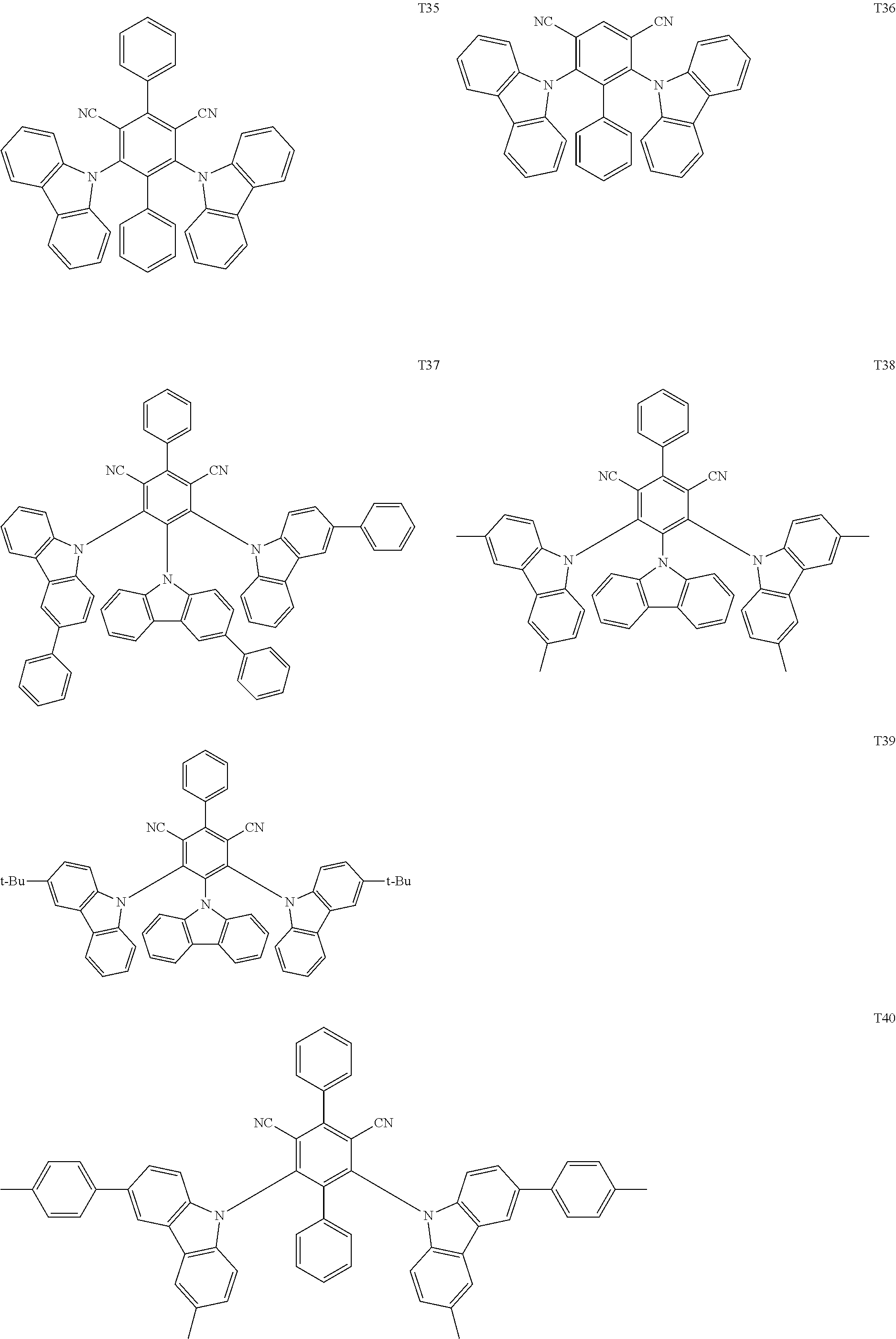

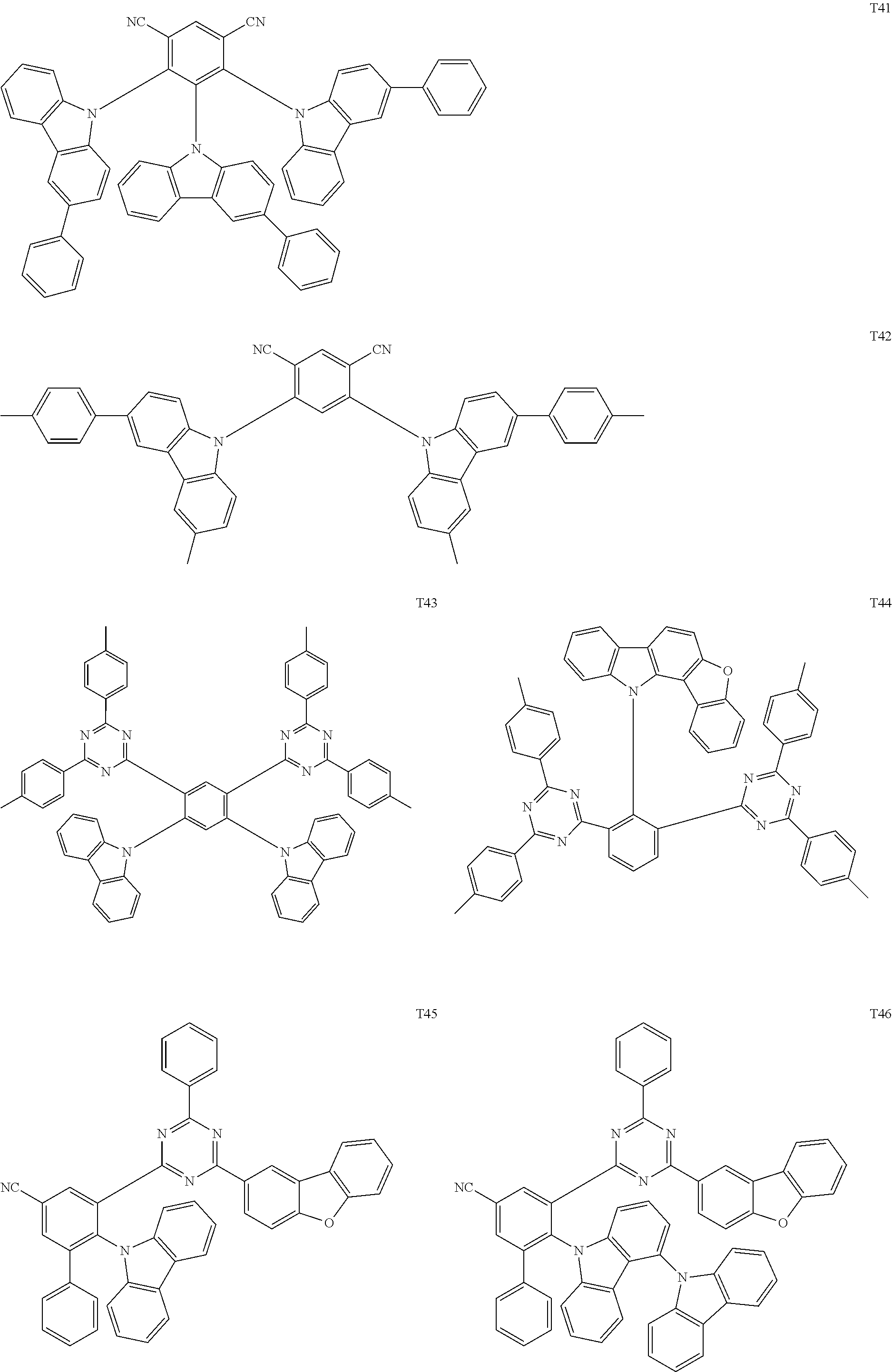

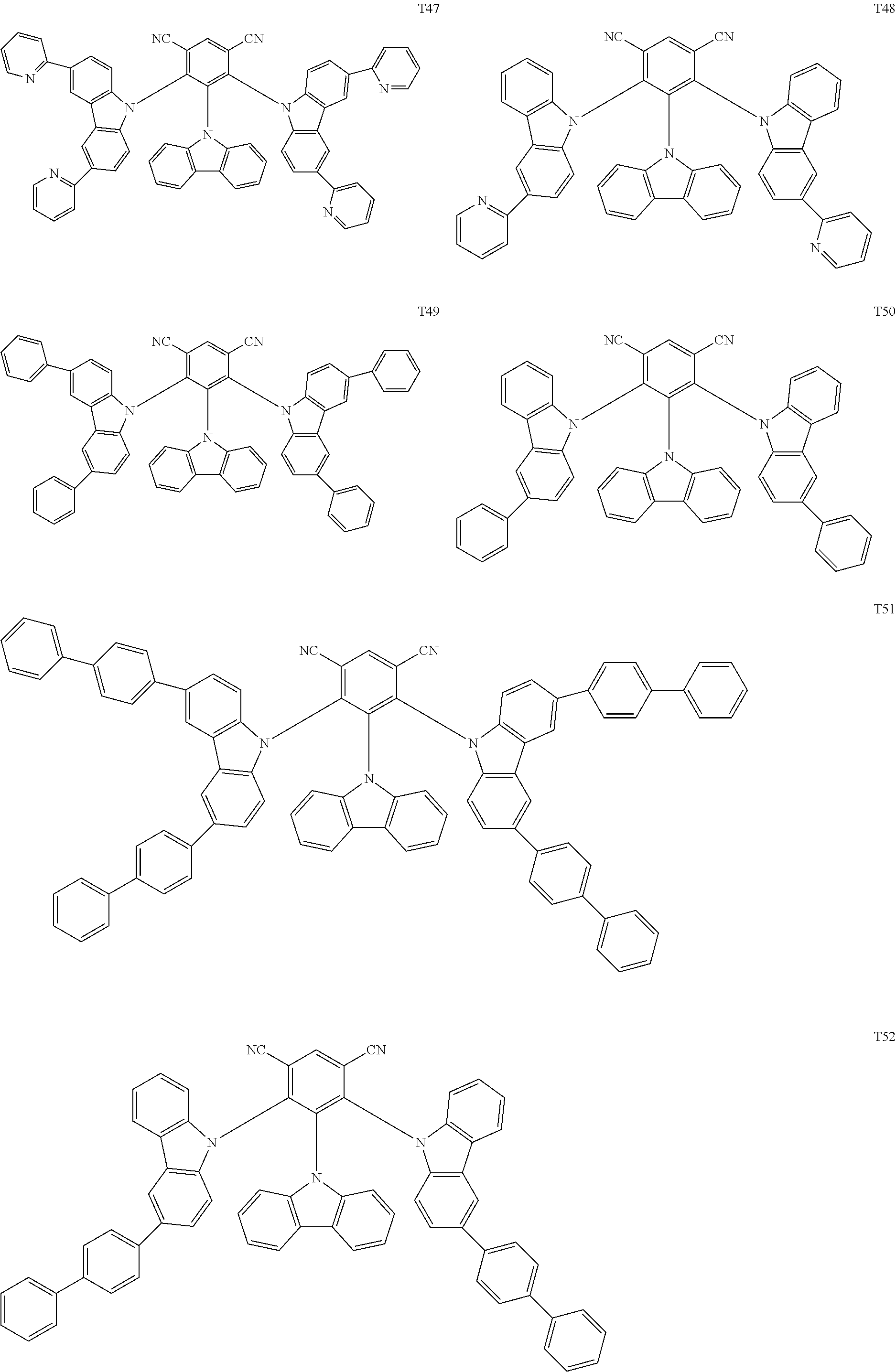

As the second organic compound, any other known delayed fluorescent materials than the above can be appropriately combined and used. Unknown delayed fluorescent materials can also be used.

As preferred delayed fluorescent materials, there can be mentioned compounds included in the general formulae described in WO2013/154064, paragraphs 0008 to 0048 and 0095 to 0133; WO2013/011954, paragraphs 0007 to 0047 and 0073-0085; WO2013/011955, paragraphs 0007 to 0033 and 0059 to 0066; WO2013/081088, paragraphs 0008 to 0071 and 0118 to 0133; JP 2013-256490 A, paragraphs 0009 to 0046 and 0093 to 0134; JP 2013-116975 A, paragraphs 0008 to 0020 and 0038 to 0040; WO2013/133359, paragraphs 0007 to 0032 and 0079 to 0084; WO2013/161437, paragraphs 0008 to 0054 and 0101-0121; JP 2014-9352 A, paragraphs 0007 to 0041 and 0060 to 0069; and JP 2014-9224 A, paragraphs 0008 to 0048 and 0067 to 0076; JP 2017-119663 A, paragraphs 0013 to 0025; JP 2017-119664 A, paragraphs 0013 to 0026; JP 2017-222623 A, paragraphs 0012 to 0025; JP 2017-226838 A, paragraphs 0010 to 0050; JP 2018-100411 A, paragraphs 0012 to 0043; WO2018/047853, paragraphs 0016 to 0044; and especially, exemplary compounds therein capable of emitting delayed fluorescence. In addition, also preferably employable here are light emitting materials capable of emitting delayed fluorescence, as described in JP 2013-253121 A, WO2013/133359, WO2014/034535, WO2014/115743, WO2014/122895, WO2014/126200, WO2014/136758, WO2014/133121, WO2014/136860, WO2014/196585, WO2014/189122, WO2014/168101, WO2015/008580, WO2014/203840, WO2015/002213, WO2015/016200, WO2015/019725, WO2015/072470, WO2015/108049, WO2015/080182, WO2015/072537, WO2015/080183, JP 2015-129240 A, WO2015/129714, WO2015/129715, WO2015/133501, WO2015/136880, WO2015/137244, WO2015/137202, WO2015/137136, WO2015/146541 and WO2015/159541. These patent publications described in this paragraph are hereby incorporated as a part of this description by reference.

Compounds represented by the following general formula (1) and emitting delayed fluorescence can be preferably used as the delayed fluorescent material in the present invention. In a preferred embodiment of the present invention, the compounds represented by the general formula (1) can be employed as the second organic compound.

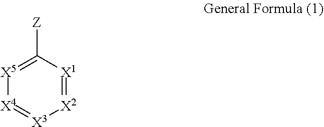

In the general formula (1), X¹ to X⁵ each represent N or C—R. R represents a hydrogen atom, a deuterium atom or a substituent. When two or more of X¹ to X⁵ each represent C—R, these (C—R)'s can be the same as or different from each other. However, at least one of X¹ to X⁵ is C-D (here D represents a donor group). When all X¹ to X⁵ each are C—R, Z represents an acceptor group, and when at least one of X¹ to X⁵ is N, Z represents a hydrogen atom, a deuterium atom or a substituent.

Among the compounds represented by the general formula (1), especially preferred compounds are compounds represented by the following general formula (2).

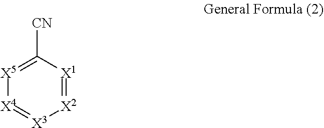

In the general formula (2), X¹ to X⁵ each represent N or C—R. R represents a hydrogen atom, a deuterium atom or a substituent. When two or more of X¹ to X⁵ each represent C—R, these (C—R)'s can be the same as or different from each other. However, at least one of X¹ to X⁵ is C-D (here D represents a donor group).

Regarding the description and the preferred range of the substituent which Z in the general formula (1) represents, reference can be made to the description and the preferred range of the substituent in the general formula (7) to be mentioned below. The acceptor group which Z in the general formula (1) represents is a group having a property of accepting an electron from the ring to which Z bonds, and for example, can be selected from groups having a positive Hammett's σₚ value. The donor group which D in the general formula (1) and the general formula (2) represents is a group having a property of donating an electron to the ring to which D bonds, and can be selected from groups having a negative Hammett's σₚ value. Hereinunder the acceptor group can be referred to as A.

Here, “Hammett's σₚ value” is one propounded by L. P. Hammett, and is one to quantify the influence of a substituent on the reaction rate or the equilibrium of a para-substituted benzene derivative. Specifically, the value is a constant (ap) peculiar to the substituent in the following equation that is established between a substituent and a reaction rate constant or an equilibrium constant in a para-substituted benzene derivative:

$$log ( k / {k}_{0} ) = ρ {σ}_{p}$$

$$or log ( K / {K}_{0} ) = ρ {σ}_{p}$$

In the above equations, k represents a rate constant of a benzene derivative not having a substituent; k₀ represents a rate constant of a benzene derivative substituted with a substituent; K represents an equilibrium constant of a benzene derivative not having a substituent; K₀ represents an equilibrium constant of a benzene derivative substituted with a substituent; ρ represents a reaction constant to be determined by the kind and the condition of reaction. Regarding the description relating to the “Hammett's σₚ value” and the numerical value of each substituent, reference can be made to the description relating to σₚ value in Hansch, C. et. al., Chem. Rev., 91, 165-195 (1991).

In the general formula (1) and the general formula (2), X¹ to X⁵ each represent N or C—R, and at least one thereof is C-D. Of X¹ to X⁵, the number of N is 0 to 4, and for example, cases are exemplified where X¹ and X³ and X⁵, X¹ and X³, X¹ and X⁴, X² and X³, X¹ and X⁵, X² and X⁴, X¹ alone, X² alone, or X³ alone are/is N's. Of X¹ to X⁵, the number of C-D is 1 to 5, and is preferably 2 to 5. For example, cases are exemplified where X¹ and X² and X³ and X⁴ and X⁵, X¹ and X² and X⁴ and X⁵, X¹ and X² and X³ and X⁴, X¹ and X³ and X⁴ and X⁵, X¹ and X³ and X⁵, X¹ and X² and X⁵, X¹ and X² and X⁴, X¹ and X³ and X⁴, X¹ and X³, X¹ and X⁴, X² and X³, X¹ and X⁵, X² and X⁴, X¹ alone, X² alone, or X³ alone are/is (C-D)'s. At least one of X¹ to X⁵ can be C-A. Here, A represents an acceptor group. Of X¹ to X⁵, the number of C-A is preferably 0 to 2, more preferably 0 or 1. A of C-A preferably includes a cyano group and an unsaturated nitrogen atom-having heterocyclic aromatic group. X¹ to X⁵ can be each independently C-D or C-A.

When two of X¹ to X⁵ that are next to each other represent C—R, two R's can bond to each other to form a cyclic structure. The cyclic structure to be formed by the two bonding to each other can be an aromatic ring or an aliphatic ring, or can contain a hetero atom, and further the cyclic structure can be a condensed ring of two or more rings. The hetero atom as referred to herein is preferably selected from the group consisting of a nitrogen atom, an oxygen atom and a sulfur atom. Examples of the cyclic structure to be formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cyclopentaene ring, a furan ring, a thiophene ring, a naphthyridine ring, a quinoxaline ring, and a quinoline ring. Many rings can be condensed to form a ring such as a phenanthrene ring or a triphenylene ring.

The donor group D in the general formula (1) and the general formula (2) is, for example, preferably a group represented by the following general formula (3).

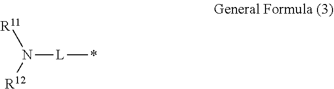

In the general formula (3), R¹¹ and R¹² each independently represent a substituted or unsubstituted alkyl group, a substituted or unsubstituted alkenyl group, a substituted or unsubstituted aryl group or a substituted or unsubstituted heteroaryl group. R¹¹ and R¹² can bond to each other to form a cyclic structure. L represents a single bond, a substituted or unsubstituted arylene group, or a substituted or unsubstituted heteroarylene group. The substituent that can be introduced into the arylene group or the heteroarylene group of L can be a group represented by the general formula (1) or the general formula (2), or can be a group represented by the general formulae (3) to (6) to be mentioned below. The groups represented by these (1) to (6) can be introduced up to the maximum number of the substituents capable of being introduced into L. In the case where plural groups represented by the general formulae (1) to (6) are introduced, the substituents can be the same as or different from each other. * indicates the bonding position to the carbon atom (C) that constitutes the ring skeleton of the ring in the general formula (1) or the general formula (2).

“Alkyl group” as referred to herein can be linear, branched or cyclic. Two or more of a linear moiety, a cyclic moiety and a branched moiety can be in the group as mixed. The carbon number of the alkyl group can be, for example, 1 or more, 2 or more, or 4 or more. The carbon number can also be 30 or less, 20 or less, 10 or less, 6 or less, or 4 or less. Specific examples of the alkyl group include a methyl group, an ethyl group, an n-propyl group, an isopropyl group, an n-butyl group, an isobutyl group, a tert-butyl group, an n-pentyl group, an isopentyl group, an n-hexyl group, an isohexyl group, a 2-ethylhexyl group, an n-heptyl group, an isoheptyl group, an n-octyl group, an isooctyl group, an n-nonyl group, an isononyl group, an n-decanyl group, an isodecanyl group, a cyclopentyl group, a cyclohexyl group, and a cycloheptyl group. The alkyl group of a substituent can be further substituted with an aryl group.

“Alkenyl group” can be linear, branched or cyclic. Two or more of a linear moiety, a cyclic moiety and a branched moiety can be in the group as mixed. The carbon number of the alkenyl group can be, for example, 2 or more, or 4 or more. The carbon number can also be 30 or less, 20 or less, 10 or less, 6 or less, or 4 or less. Specific examples of the alkenyl group include an ethenyl group, an n-propenyl group, an isopropenyl group, an n-butenyl group, an isobutenyl group, an n-pentenyl group, an isopentenyl group, an n-hexenyl group, an isohexenyl group, and a 2-ethylhexenyl group. The alkenyl group to be a substituent can be further substituted with a substituent.

“Aryl group” and “heteroaryl group” each can be a single ring or can be a condensed ring of two or more rings. In the case of a condensed ring, the number of the rings that are condensed is preferably 2 to 6, and, for example, can be selected from 2 to 4. Specific examples of the ring include a benzene ring, a pyridine ring, a pyrimidine ring, a triazine ring, a naphthalene ring, an anthracene ring, a phenanthrene ring, a triphenylene ring, a quinoline ring, a pyrazine ring, a quinoxaline ring, and a naphthyridine ring. Specific examples of the aryl ring or the heteroaryl ring include a phenyl group, a 1-naphthyl group, a 2-naphthyl group, a 1-anthracenyl group, a 2-anthracenyl group, a 9-anthracenyl group, a 2-pyridyl group, a 3-pyridyl group, and a 4-pyridyl group. For “arylene group” and “heteroarylene group”, the valance of the aryl group and the heteroaryl group is exchanged from 1 to 2, and the thus-exchanged description can be referred to.

The substituent means a monovalent group capable of being substituted for a hydrogen atom or a deuterium atom, and is not a concept to include condensation. Regarding the description and the preferred range of the substituent, reference can be made to the description and the preferred range of the substituent in the general formula (7) to be mentioned below.

The compound represented by the general formula (3) is preferably a compound represented by any of the following general formulae (4) to (6).

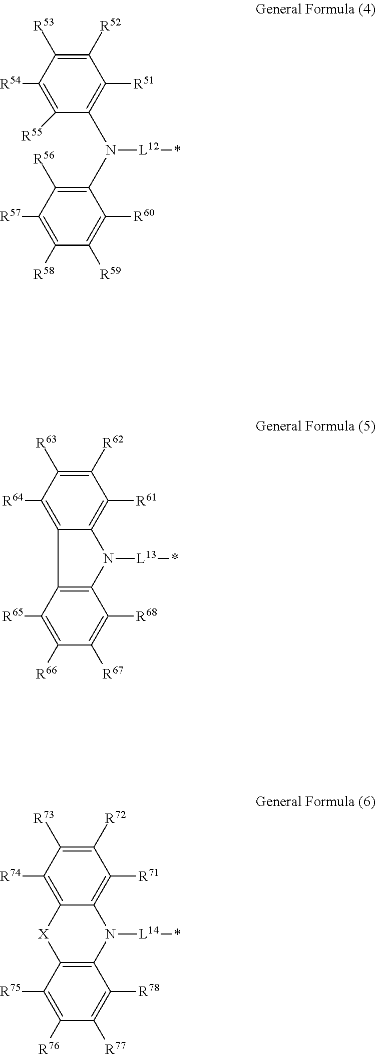

In the general formulae (4) to (6), R⁵¹ to R⁶⁰, R⁶¹ to R⁶⁸, and R⁷¹ to R⁷⁸ each independently represent a hydrogen atom, a deuterium atom or a substituent. Regarding the description and the preferred range of the substituent as referred to herein, reference can be made to the description and the preferred range of the substituent in the general formula (7) to be mentioned below. Also preferably, R⁵¹ to R⁶⁰, R⁶¹ to R⁶⁸, and R⁷¹ to R⁷⁸ each are a group represented by any of the above-mentioned general formulae (4) to (6). The number of the substituents in the general formulae (4) to (6) is not specifically limited. A case where all are unsubstituted (that is, a hydrogen atom or a deuterium atom) is also preferred. In the case where the general formulae (4) to (6) each have two or more substituents, the substituents can be the same as or different from each other. In the case where a substituent is in the general formulae (4) to (6), the substituent is preferably any of R⁵² to R⁵⁹ in the general formula (4), or any of R⁶² to R⁶⁷ in the general formula (5), or any of R⁷² to R⁷⁷ in the general formula (6).

In the general formulae (4) to (6), R⁵¹ and R⁵², R⁵² and R⁵³, R⁵³ and R⁵⁴, R⁵⁴ and R⁵⁵, R⁵⁵ and R⁵⁶, R⁵⁶ and R⁵⁷, R⁵⁷ and R⁵⁸, R⁵⁸ and R⁵⁹, R⁵⁹ and R⁶⁰, R⁶¹ and R⁶², R⁶² and R⁶³, R⁶³ and R⁶⁴, R⁶⁵ and R⁶⁶, R⁶⁶ and R⁶⁷, R⁶⁷ and R⁶⁸, R⁷¹ and R⁷², R⁷² and R⁷³, R⁷³ and R⁷⁴, R⁷⁵ and R⁷⁶, R⁷⁶ and R⁷⁷, and R⁷⁷ and R⁷⁸ each can bond to each other to form a cyclic structure. Regarding the description and the preferred examples of the cyclic structure, reference can be made to the description and the preferred examples of the cyclic structure in X¹ to X⁵ of the general formula (1) and the general formula (2) mentioned hereinabove.

In the general formula (6), X represents an oxygen atom, a sulfur atom, a substituted or unsubstituted nitrogen atom, a substituted or unsubstituted carbon atom, a substituted or unsubstituted silicon atom or a carbonyl group which is divalent and has a linking chain length of one atom, or represents a substituted or unsubstituted ethylene group, a substituted or unsubstituted vinylene group, a substituted or unsubstituted o-arylene group or a substituted or unsubstituted o-heteroarylene group which is divalent and has a linking chain length of two atoms. Regarding the specific examples and the preferred range of the substituent, reference can be made to the description of the substituent in the general formula (1) and the general formula (2) mentioned hereinabove.

In the general formulae (4) to (6), L¹² to L¹⁴ each represent a single bond, a substituted or unsubstituted arylene group, or a substituted or unsubstituted heteroarylene group. Regarding the description and the preferred range of the arylene group or the heteroarylene group that L¹² to L¹⁴ represent, reference can be made to the description and the preferred range of the arylene group and the heteroarylene group that L represents. L¹² to L¹⁴ each are preferably a single bond, or a substituted or unsubstituted arylene group. The substituent for the arylene group and the heteroarylene group as referred to herein can be the group represented by the general formulae (1) to (6). The group represented by the general formulae (1) to (6) can be introduced up to the maximum number of the substituents capable of being introduced into L¹¹ to L¹⁴. In the case where plural groups represented by the general formulae (1) to (6) are introduced, the substituents can be the same as or different from each other. * indicates the bonding position to the carbon atom (C) that constitutes the ring skeleton of the ring in the general formula (1) or the general formula (2).

In the present invention, a compound represented by the following general formula (7) and emitting delayed fluorescence can be especially preferably used as the delayed fluorescent material. In a preferred embodiment of the present invention, the compound represented by the general formula (7) can be used as the second organic compound.

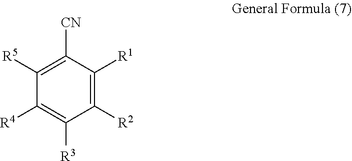

In the general formula (7), 0 to 4 of R¹ to R⁵ each are a cyano group, at least one of R¹ to R⁵ is a substituted amino group, and the rest of R¹ to R⁵ each are a hydrogen atom, a deuterium atom, or a substituent except a cyano group and a substituted amino group.

The substituted amino group as referred to herein is preferably a substituted or unsubstituted diarylamino group, and the two aryl groups constituting the substituted or unsubstituted diarylamino group can link together. The linking can be via a single bond (in that case, a carbazole ring is formed) or can also be via a linking group such as —O—, —S—, —N(R⁶)—, —C(R⁷)(R⁸)—, or —Si(R⁹)(R¹⁰)—. Here, R⁶ to R¹⁰ each represent a hydrogen atom, a deuterium atom or a substituent, and R⁷ and R⁸, and R⁹ and R¹⁰ each may bond to each other to form a cyclic structure.

Any of R¹ to R⁵ can be a substituted amino group, and for example, R¹ and R², R¹ and R³, R¹ and R⁴, R¹ and R⁵, R² and R³, R² and R⁴, R¹ and R² and R³, R¹ and R² and R⁴, R¹ and R² and R⁵, R¹ and R³ and R⁴, R¹ and R³ and R⁵, R² and R³ and R⁴, R¹ and R² and R³ and R⁴, R¹ and R² and R³ and R⁵, R¹ and R² and R⁴ and R⁵, and R¹ and R² and R³ and R⁴ and R⁵ each can be a substituted amino group. Any of R¹ to R⁵ can also be a cyano group, and for example, R¹, R², R³, R¹ and R², R¹ and R³, R¹ and R⁴, R¹ and R⁵, R² and R³, R² and R⁴, R¹ and R² and R³, R¹ and R² and R⁴, R¹ and R² and R⁵, R¹ and R³ and R⁴, R¹ and R³ and R⁵, and R² and R³ and R⁴ can be a cyano group.

R¹ to R⁵ which are neither a cyano group nor a substituted amino group each represent a hydrogen atom, a deuterium atom or a substituent. Examples of the substituent as referred to herein include a hydroxy group, a halogen atom (for example, a fluorine atom, a chlorine atom, a bromine atom, an iodine atom), an alkyl group (for example, having 1 to 40 carbon atoms), an alkoxy group (for example, having 1 to 40 carbon atoms), an alkylthio group (for example, having 1 to 40 carbon atoms), an aryl group (for example, having 6 to 30 carbon atoms), an aryloxy group (for example, having 6 to 30 carbon atoms), an arylthio group (for example, having 6 to 30 carbon atoms), a heteroaryl group (for example, having 5 to 30 ring skeleton-constituting atoms), a heteroaryloxy group (for example, having 5 to 30 ring skeleton-constituting atoms), a heteroarylthio group (for example, having 5 to 30 ring skeleton-constituting atoms), an acyl group (for example, having 2 to 40 carbon atoms), an alkenyl group (for example, having 2 to 40 carbon atoms), an alkynyl group (for example, having 2 to 40 carbon atoms), an alkoxycarbonyl group (for example, having 2 to 40 carbon atoms), an aryloxycarbonyl group (for example, having 7 to 40 carbon atoms), a heteroaryloxycarbonyl group (for example, having 4 to 40 carbon atoms, a silyl group (for example, a trialkylsilyl group having 1 to 40 carbon atoms), a nitro group, and Substituent Group A including groups listed herein and substituted with one or more groups also listed herein. Preferred examples of the substituent with which the aryl group of the diarylamino group is substituted also include the substituents of Substituent Group A mentioned hereinabove, and additionally include a cyano group and a substituted amino group.

Regarding compounds included in the general formula (7) and specific examples thereof, reference can be made to WO2013/154064, paragraphs 0008 to 0048, WO2015/080183, paragraphs 0009 to 0030, WO2015/129715, paragraphs 0006 to 0019, JP 2017-119663, paragraphs 0013 to 0025, and JP 2017-119664 paragraphs 0013 to 0026, incorporated herein as a part of the present specification by reference.

A compound represented by the following general formula (8) and emitting delayed fluorescence can also be especially preferably used as the delayed fluorescent material in the present invention. In a preferred embodiment of the present invention, the compound represented by the general formula (8) can be used as the second organic compound.

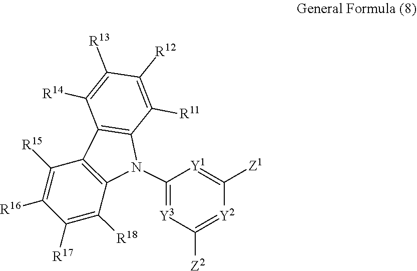

In the general formula (8), any two of Y¹, Y² and Y³ are nitrogen atoms, and the remaining one is a methine group, or all Y¹, Y² and Y³ are nitrogen atoms. Z¹ and Z² each independently represent a hydrogen atom, a deuterium atom or a substituent. R¹¹ to R¹⁸ each independently represent a hydrogen atom, a deuterium atom or a substituent, and at least one of R¹¹ to R¹⁸ is preferably a substituted or unsubstituted arylamino group, or a substituted or unsubstituted carbazolyl group. The benzene ring to constitute the arylamino group, and the benzene ring to constitute the carbazolyl group can bond to any one of R¹¹ to R¹⁸ via a single bond or a linking group. The compound represented by the general formula (8) contains at least two carbazole structures in the molecule. Examples of the substituent that Z¹ and Z² can take include substituents of Substituent Group A mentioned above. Specific examples of the substituent that R¹¹ to R¹⁸, the arylamino group and the carbazolyl group can take include substituents of Substituent Group A mentioned above, and a cyano group, a substituted arylamino group and a substituted alkylamino group. R¹¹ and R¹², R¹² and R¹³, R¹³ and R¹⁴, R¹⁵ and R¹⁶, R¹⁶ and R¹⁷, and R¹⁷ and R¹⁸ each can bond to each other to form a cyclic structure.

Among the compounds represented by the general formula (8), compounds represented by the following general formula (9) are especially useful.

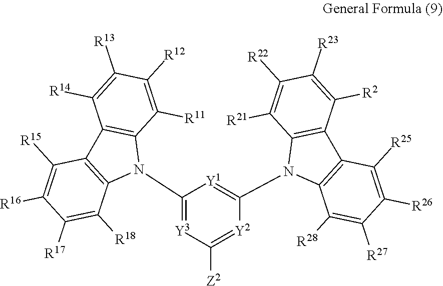

In the general formula (9), any two of Y¹, Y² and Y³ are nitrogen atoms and the remaining one is a methine group, or all Y¹, Y² and Y³ are nitrogen atoms. Z² represents a hydrogen atom, a deuterium atom or a substituent. R¹¹ to R¹⁸, and R²¹ to R²⁸ each independently represent a hydrogen atom, a deuterium atom or a substituent. At least one of R¹¹ to R¹⁸, and/or at least one of R²¹ to R²⁸ each are preferably a substituted or unsubstituted arylamino group, or a substituted or unsubstituted carbazolyl group. The benzene ring to constitute the arylamino group, and the benzene ring to constitute the carbazolyl group can bond to any one of R¹¹ to R¹⁸, or R²¹ to R²⁸ via a single bond or a linking group. Examples of the substituent that Z² can take include substituents of Substituent Group A mentioned above. Specific examples of the substituent that R¹¹ to R¹⁸, R²¹ to R²⁸, the arylamino group and the carbazolyl group can take include substituents of Substituent Group A mentioned above, and a cyano group, a substituted arylamino group and a substituted alkylamino group. R¹¹ and R¹², R¹² and R¹³, R¹³ and R¹⁴, R¹⁵ and R¹⁶, R¹⁶ and R¹⁷, R¹⁷ and R¹⁸, R²¹ and R²², R²² and R²³, R²³ and R²⁴, R²⁵ and R²⁶, R²⁶ and R²⁷, and R²⁷ and R²⁸ each can bond to each other to form a cyclic structure.

Regarding compounds included in the general formula (9) and specific examples thereof, reference can be made to compounds described in WO2013/081088, paragraphs 0020 to 0062, and Appl. Phys. Let, 98, 083302 (2011), incorporated herein as a part of the present description by reference.

A compound represented by the following general formula (10) and emitting delayed fluorescence can also be especially preferably used as the delayed fluorescent material in the present invention.

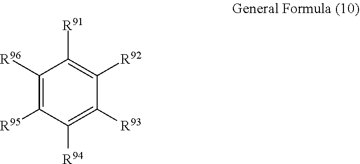

In the general formula (10), R⁹¹ to R⁹⁶ each independently represent a hydrogen atom, a deuterium atom, a donor group or an acceptor group, and at least one of them is a donor group, at least two each are an acceptor group. Though not specifically limited, the substitution position of the at least two acceptor groups preferably includes two acceptor groups that are in a meta-position to each other. For example, in the case where R⁹¹ is a donor group, preferred examples include a structure where at least R⁹² and R⁹⁴ are acceptor groups, and a structure where at least R⁹² and R⁹⁶ are acceptor groups. The acceptor groups existing in the molecule can be all the same as or different from each other, and a structure where they are all the same can be selected. Preferably, the number of the acceptor groups is 2 to 3, and, for example, 2 can be selected. Two or more donor groups can exist in the molecule, and in that case all the donor groups can be the same as or different from each other. Preferably, the number of the donor groups is 1 to 3, and can be, for example, 1 alone or can be 2. Regarding the description and the preferred range of the donor group and the acceptor group, reference can be made to the description and the preferred range of D and Z in the general formula (1). In particular, in the general formula (10), the donor group is preferably represented by the general formula (3), and the acceptor group is preferably a cyano group or is represented by the following general formula (11).

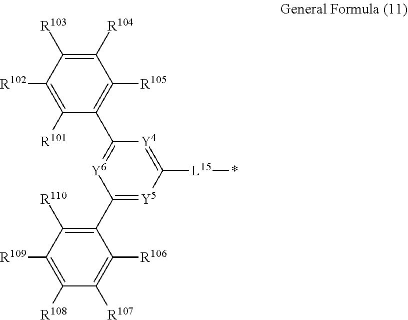

In the general formula (11), Y⁴ to Y⁶ each represent a nitrogen atom or a methine group, but at least one is a nitrogen atom, and preferably all are nitrogen atoms. R¹⁰¹ to R¹¹⁰ each independently represent a hydrogen atom, a deuterium atom, or a substituent, but at least one is preferably an alkyl group. Regarding the description and the preferred range of the substituent as referred to herein, reference can be made to the description and the preferred range of the substituent in the general formula (7) mentioned above. L¹⁵ represents a single bond or a linking group, for which reference can be made to the description and the preferred range of L in the general formula (3) mentioned above. In one embodiment of the present invention, L¹⁵ in the general formula (11) is a single bond. * indicates the bonding position to the carbon atom (C) constituting the ring skeleton of the ring in the general formula (10).

In another preferred embodiment of the present invention, a compound represented by the following general formula (12) can be employed as the second organic compound.

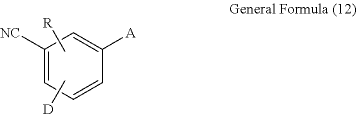

Among the compounds represented by the general formula (12), especially preferred are compounds represented by the following general formula (13) and compounds represented by the general formula (14).

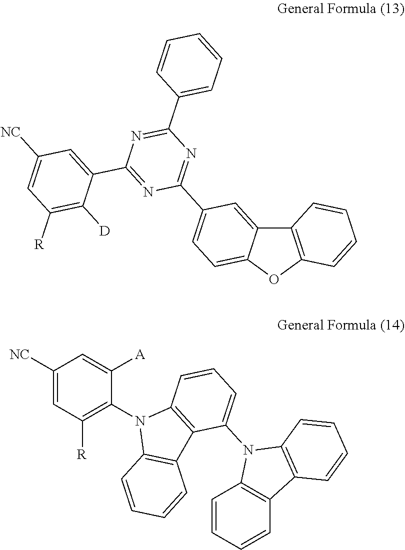

In the general formulae (12) to (14), D represents a donor group, A represents an acceptor group, R represents a hydrogen atom, a deuterium atom or a substituent. Regarding the description and the preferred range of the donor group and the acceptor group, reference can be made to the corresponding description and preferred range in the general formula (1). Examples of the substituent of R include an alkyl group and an aryl group substituted with one group or a combination of two or more groups selected from an alkyl group and an aryl group.

Specific examples of the donor group preferred as D in the general formulae (12) to (14) are shown below. In the specific examples, * indicates a bonding position, and “D” represents deuterium.

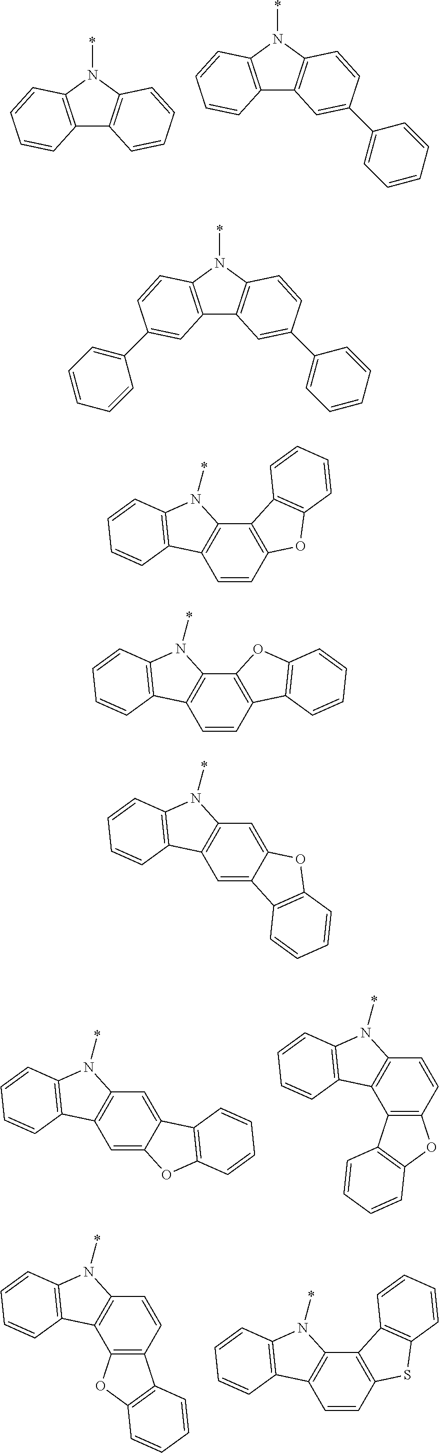

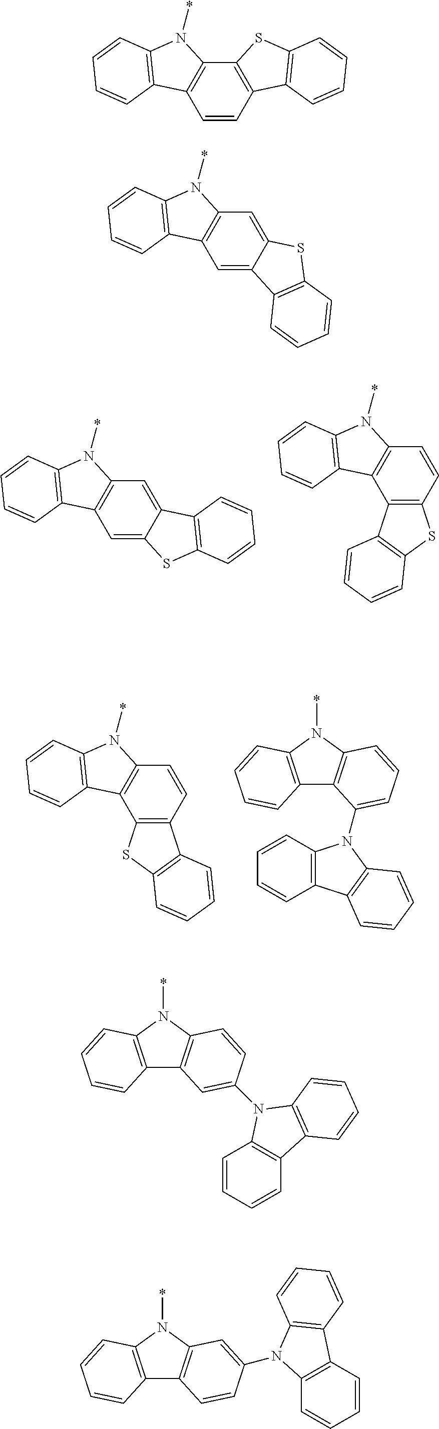

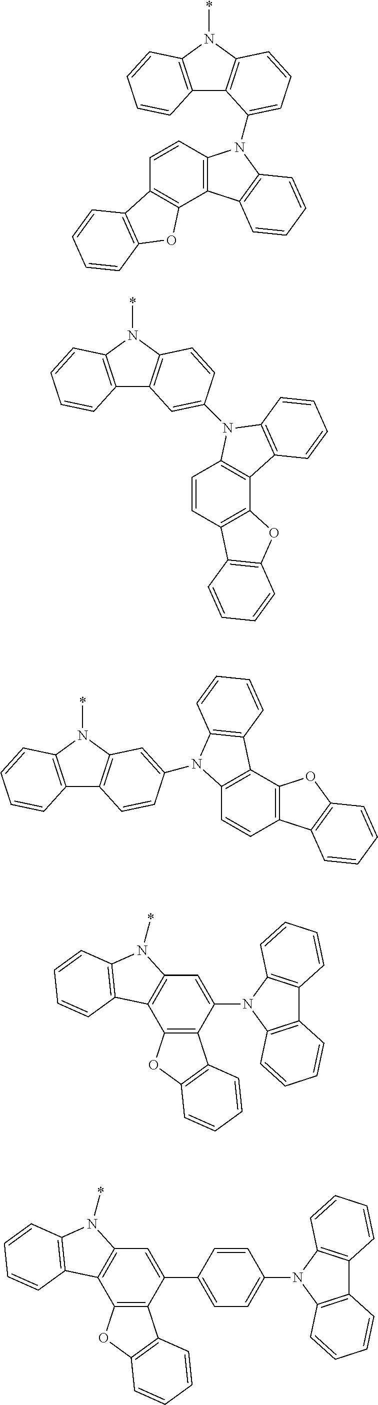

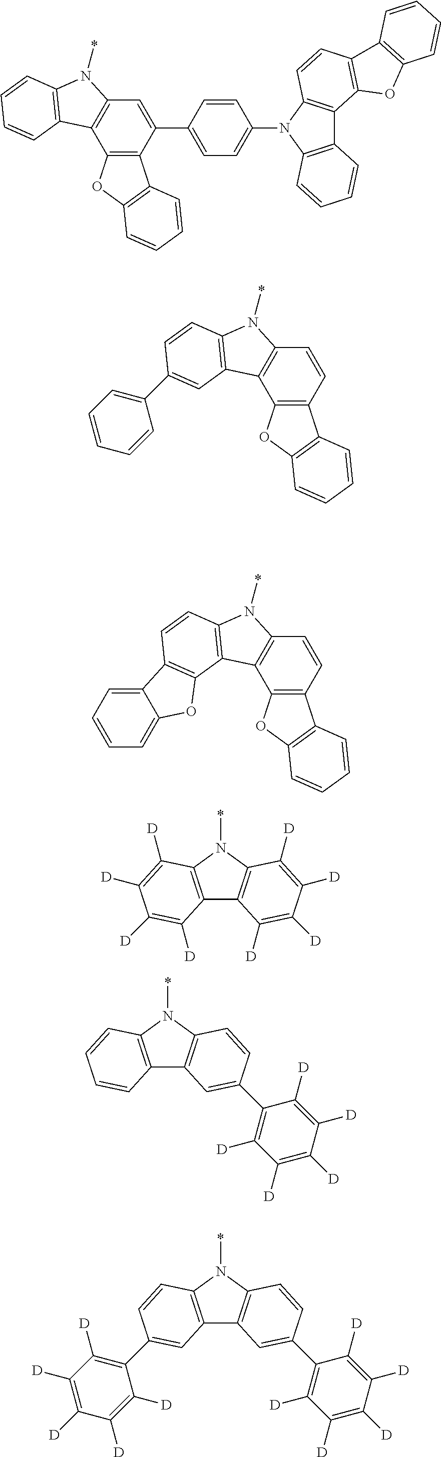

Specific examples of the acceptor group preferred as A in the general formulae (12) to (14) are shown below. In the specific examples, * indicates a bonding position, and “D” represents deuterium.

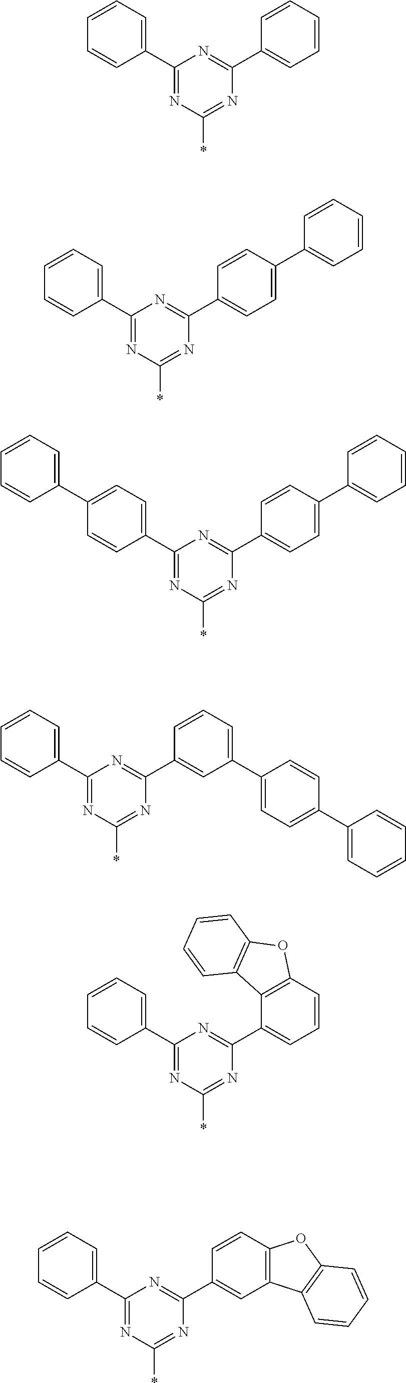

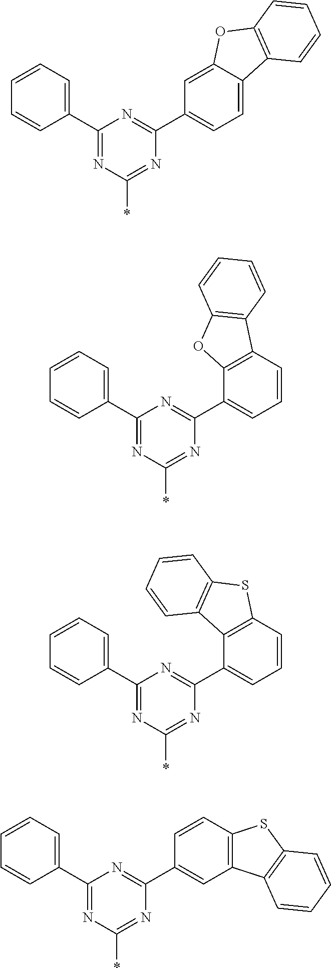

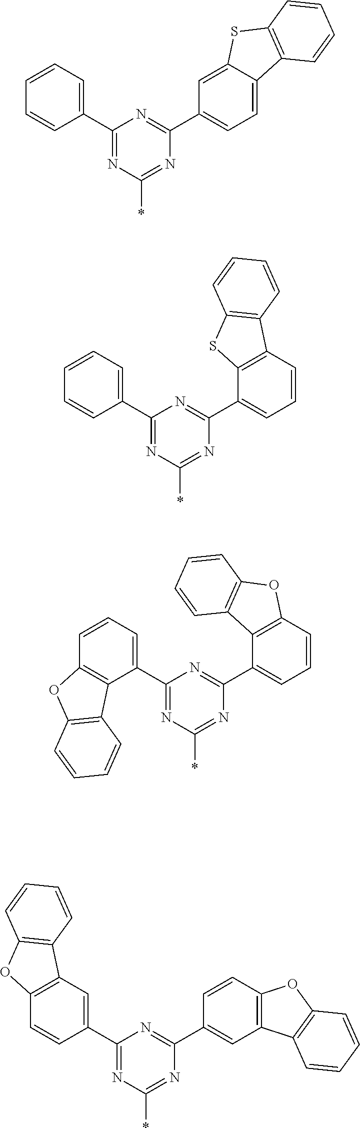

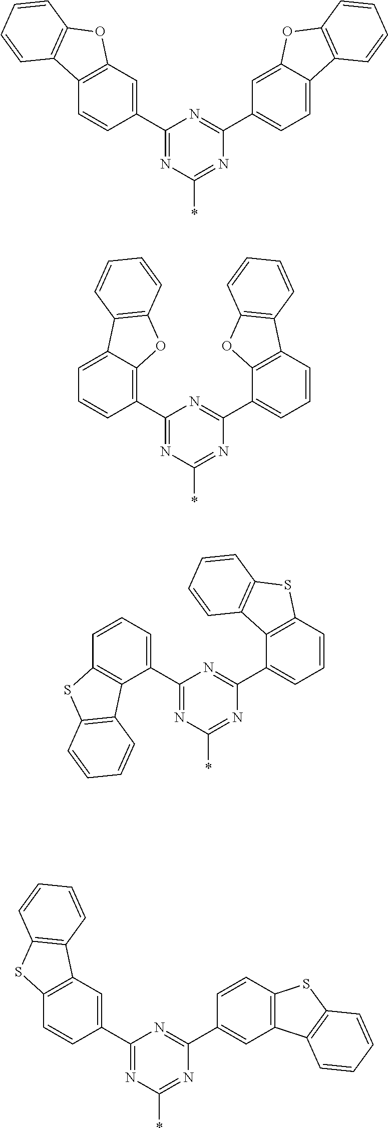

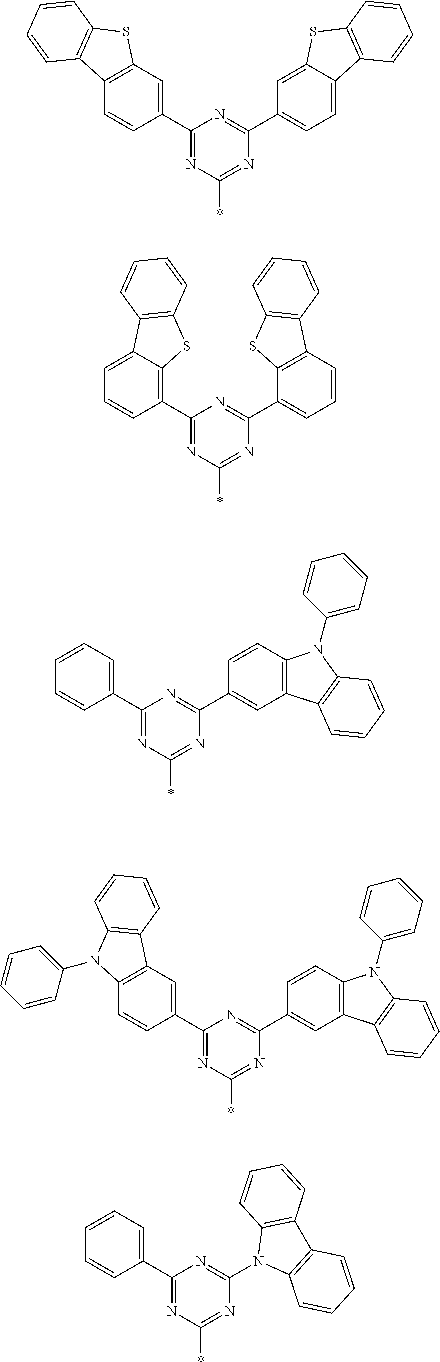

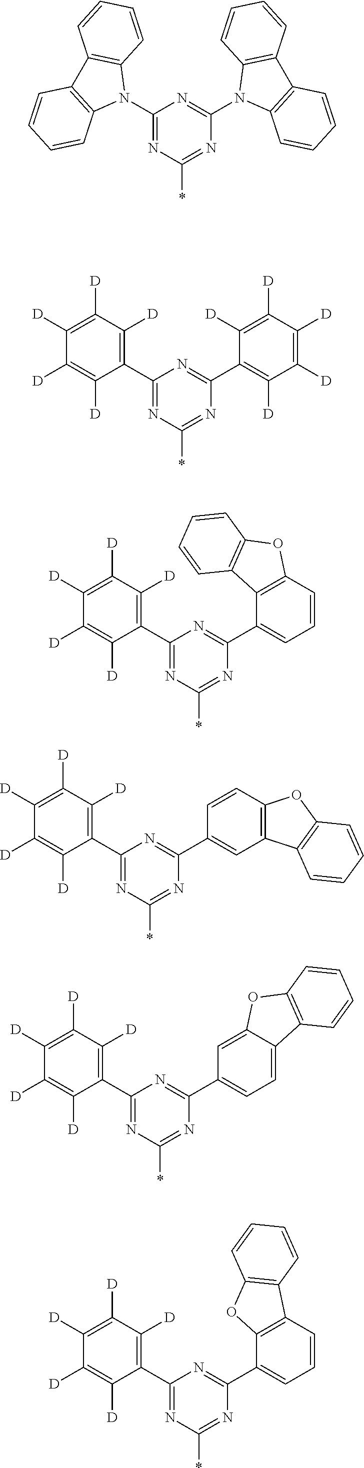

Preferred examples of R in the general formulae (12) to (14) are shown below. In the specific examples, * indicates a bonding position, and “D” represents deuterium.

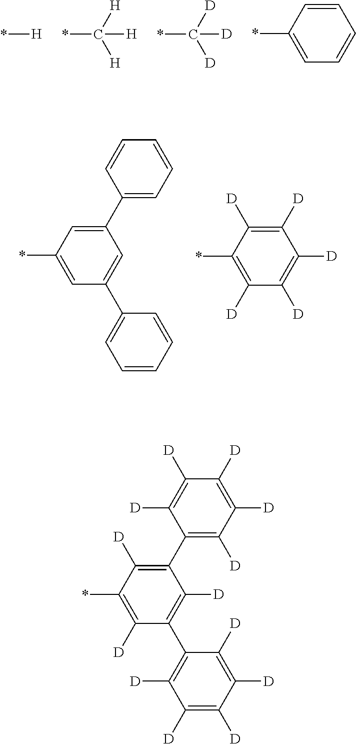

### (Third Organic Compound)

The third compound is a compound of which the lowest excited singlet energy is smaller than that of the first organic compound, the second organic compound and the triplet-regulating compound. The third organic compound is a compound of which the lowest excited triplet energy is smaller than that of the first organic compound and the second organic compound, and of which the lowest excited triplet energy is larger than that of the triplet-regulating compound. The organic light emitting device of the present invention emits fluorescence derived from the third organic compound. Emission from the third organic compound generally includes delayed fluorescence. The maximum component of emission from the organic light emitting device of the present invention is emission from the third organic compound. Namely, of emission from the organic light emitting device of the present invention, the amount of emission from the third organic compound is the maximum. Having received energy from the first organic compound in an excited singlet state, from the second organic compound in an excited singlet state, and from the second organic that has been in an excited singlet state through reverse intersystem crossing from an excited triplet state, the third organic compound thus transitions into an excited singlet state. In a preferred embodiment of the present invention, the third organic compound receives energy from the second organic compound in an excited singlet state and from the second organic that has been in an excited singlet state through reverse intersystem crossing from an excited triplet state, and thus transitions into an excited singlet state. Thereafter the third organic compound emits fluorescence when it returns back to a ground state from the resultant excited singlet state.

The fluorescent material for use as the third organic compound is not specifically limited so far as it can emit light after having received energy from the first organic compound and the second organic compound in the manner as above, and the emission from the fluorescent material of the type can include any of fluorescence, delayed fluorescence and phosphorescence. Preferably, the emission includes fluorescence and delayed fluorescence, and more preferably the maximum component of emission from the third organic compound is fluorescence.

So far as satisfying the requirements in the present invention, two or more kinds of third organic compounds can be used. For example, by using two or more kinds of third organic compounds that differ in the emission color, a desired color can be emitted. Also. using one kind of a third organic compound can provide monochromatic emission.

In the present invention, the maximum emission wavelength of the compound usable as the third organic compound is not specifically limited. Consequently, a light emitting material having a maximum emission wavelength in a visible region (380 to 780 nm) and a light emitting material having a maximum emission wavelength in an IR region (780 nm to 1 mm) can be appropriately selected and used. Preferred is a fluorescent material having a maximum emission wavelength in a visible region. For example, a light emitting material of which the maximum emission in a region of 380 nm to 780 nm falls within a region of 380 to 570 nm can be selected and used, or a light emitting material of which the maximum emission wavelength falls within a region of 380 to 500 nm can be selected and used, or a light emitting material of which the maximum emission wavelength falls within a region of 380 to 480 nm can be selected and used, or a light emitting material of which the maximum emission wavelength falls within a region of 420 to 480 nm can be selected and used.

In a preferred embodiment of the present invention, the compounds are selected and combined so that the emission wavelength region of the second organic compound and the absorption wavelength region of the third organic compound can overlap with each other. Especially preferably, the edge on the short wavelength side of the emission spectrum of the second organic compound can overlap with the edge on the long wavelength side of the absorption spectrum of the third organic compound (that is, the two intersect with each other).

Preferred compounds for use as the third organic compound are shown below. In the structural formulae of the following exemplary compounds, Et represents an ethyl group.

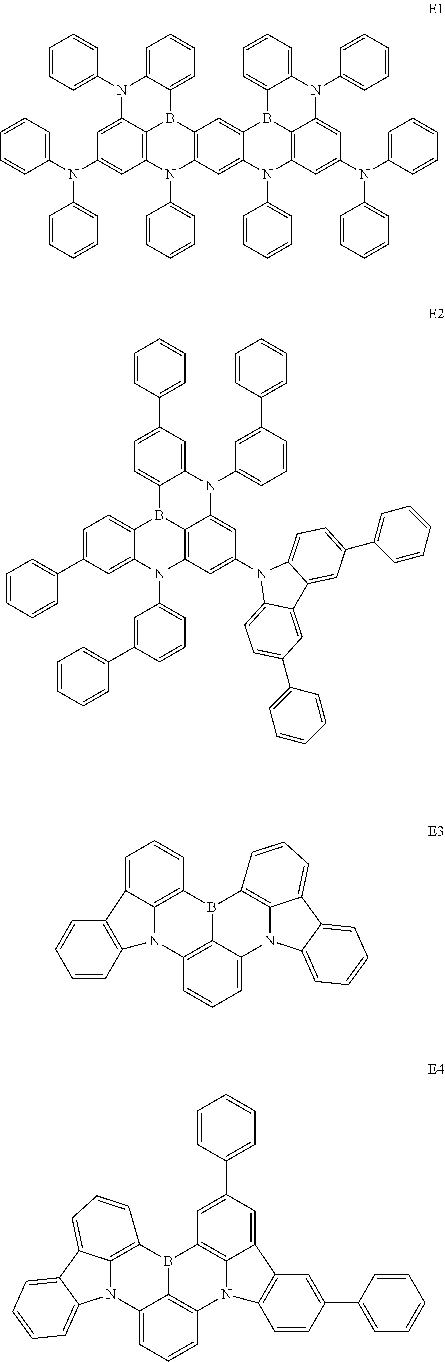 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; c1ccc(-c2cccc(N3c4cc(-c5ccccc5)ccc4B4c5ccc(-c6ccccc6)cc5N(c5cccc(-c6ccccc6)c5)c5cc(-n6c7ccc(-c8ccccc8)cc7c7cc(-c8ccccc8)ccc76)cc3c54)c2)cc1 ; c1cc2c3c(c1)-n1c4ccccc4c4cccc(c41)B3c1cccc3c4ccccc4n-2c13 ; c1ccc(-c2ccc3c(c2)c2cc(-c4ccccc4)cc4c2n3-c2cccc3c2B4c2cccc4c5ccccc5n-3c24)cc1]

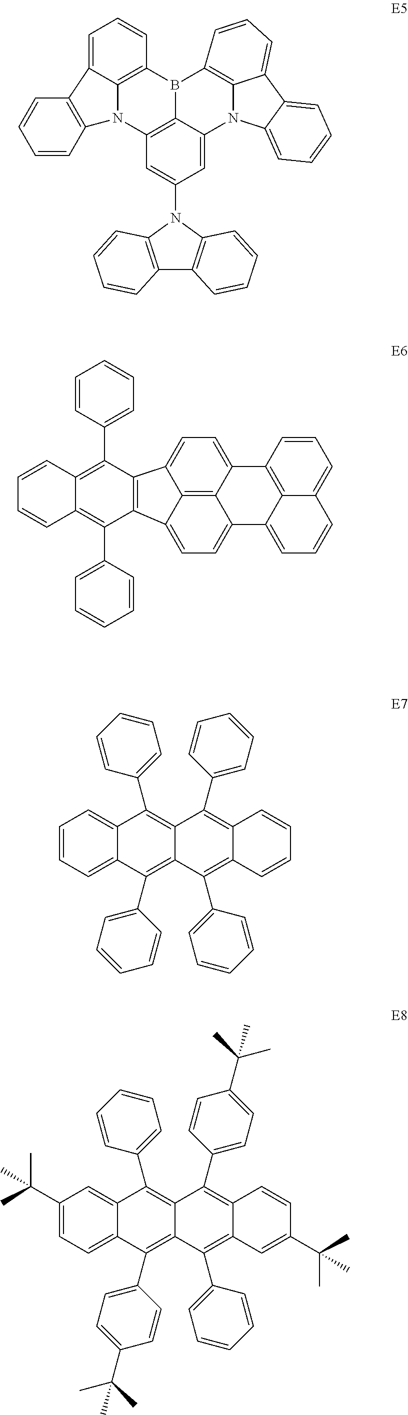

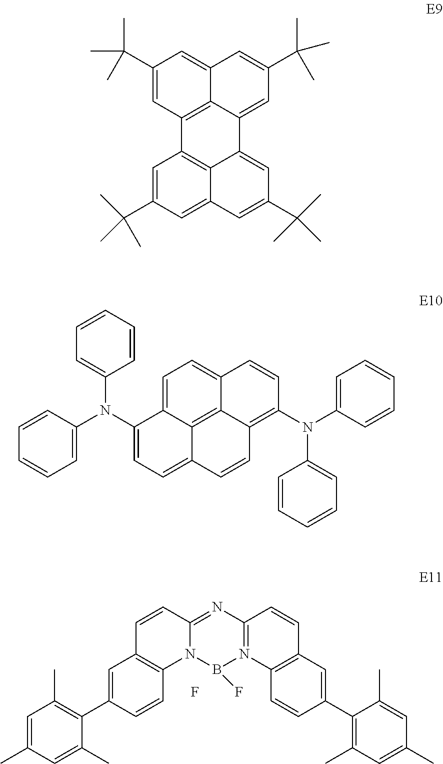

Preferred compounds are Compounds E1 to E5 and derivatives having the skeletons thereof. The derivatives include compounds substituted with an alkyl group, an aryl group, a heteroaryl group, or a diarylamino group.

Also the compounds described in WO2015/022974, paragraphs 0220 to 0239 can be especially preferably used as the third organic compound in the present invention.

### (Triplet-Regulating Compound)

The triplet-regulating compound is a compound of which the lowest excited singlet energy is smaller than that of the first organic compound and of which the lowest excited singlet energy is larger than that of the second organic compound. Also the triplet-regulating compound is a compound of which the lowest excited triplet energy is smaller than that of the first organic compound and the second organic compound. When the light emitting layer of the organic light emitting device of the present invention contains the third organic compound, the triplet-regulating compound is a compound of which the lowest excited singlet energy is larger than that of the third organic compound and of which the lowest excited triplet energy is smaller than that of the third organic compound.

In the organic light emitting device of the present invention, the triplet-regulating compound receives energy from the first organic compound, the second organic compound and the third organic compound of an optional component that are in an excited triplet state, and transitions into an excited triplet state. In particular, the triplet-regulating compound receives energy from the second organic compound and the third organic compound of an optional component that are in an excited triplet state, and can deactivate the triplet excitons of those compounds, and therefore can suppress the influence of the triplet-triplet interaction and the triplet-charge interaction on these organic compounds to thereby improve the device durability.

In the case where the light emitting layer of the device does not contain the third organic compound, the triplet-regulating compound can be one that satisfies the requirement (a) and the requirement (b). In the case where the layer contains the third organic compound, the triplet-regulating compound can be one that satisfies the requirement (a1) and the requirement (b1). In one preferred embodiment of the present invention, the triplet-regulating compound is a compound represented by the following general formula (15).

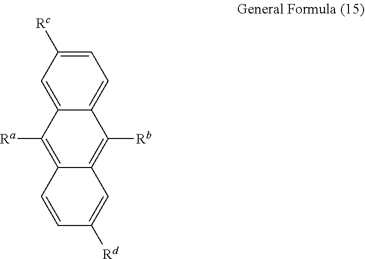

In the general formula (15), R^{a} and R^{b} each independently represent a substituted or unsubstituted aryl group. R^{c} and R^{d} each independently represent a hydrogen atom, a deuterium atom, a substituted or unsubstituted alkyl group, a substituted or unsubstituted alkoxy group, a substituted or unsubstituted aryl group, a substituted or unsubstituted aryloxy group, a substituted or unsubstituted amino group, a halogen atom, a cyano group, a substituted or unsubstituted silyl group. R^{c} and R^{d} each are preferably a hydrogen atom, a deuterium atom, or a substituted or unsubstituted aryl group.

The substituent that the alkyl group, the alkoxy group, the aryl group, the aryloxy group and the silyl group can take in the general formula (15) includes an alkyl group, an alkoxy group, an aryl group, an aryloxy group, a halogen atom, a cyano group and a silyl group. Preferred substituents are an alkyl group and an aryl group.

For the aryl group, the alkyl group, the aryl moiety of the aryloxy group, and the alkyl moiety of the alkoxy group herein, reference can be made to the description and the specific examples of the aryl group and the alkyl group in the general formula (3). Examples of the halogen atom include a fluorine atom, a chlorine atom, a bromine atom and an iodine atom. The silyl group is preferably a substituted or unsubstituted trialkylsilyl group, and for the alkyl moiety that constitute the trialkylsilyl group, reference can be made to the description and the specific examples of the alkyl group in the general formula (3). A hetero atom-containing ring can be condensed with the aryl group. Examples of the hetero atom include a nitrogen atom, an oxygen atom and a sulfur atom.

In one preferred embodiment of the present invention, R^{a} and R^{b} are the same, and R^{c} and R^{d} each are a hydrogen atom or a deuterium atom (preferably a hydrogen atom). In another preferred embodiment of the present invention, R^{a} and R^{b} are different, and R^{c} and R^{d} each are a hydrogen atom or a deuterium atom (preferably a hydrogen atom).

In one preferred embodiment of the present invention, at least one of R^{c} and R^{d} is a hydrogen atom or a deuterium atom (preferably a hydrogen atom).

In one preferred embodiment of the present invention, R^{a}, R^{b} and R^{c} each are independently a substituted or unsubstituted aryl group. At that time, R^{d} can be a hydrogen atom. Or R^{d} can be a substituted or unsubstituted aryl group.

In one preferred embodiment of the present invention, the triplet-regulating compound is a compound represented by the following general formula (16).

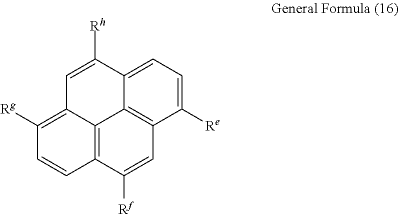

In the general formula (16), R^{e}, R^{f}, R^{g} and R^{h} each independently represent a hydrogen atom, a deuterium atom, a substituted or unsubstituted alkyl group, a substituted or unsubstituted aryl group, a substituted or unsubstituted alkoxy group, a substituted or unsubstituted aryloxy group, a substituted or unsubstituted amino group, a halogen atom, a cyano group, or a substituted or unsubstituted silyl group. Regarding the description and the preferred range of these substituents, reference can be made to the description and the preferred range of the corresponding substituents in the general formula (15). In one preferred embodiment of the present invention, R^{e} and R^{g} each are independently a substituted or unsubstituted aryl group, a substituted or unsubstituted alkoxy group, a substituted or unsubstituted aryloxy group, a substituted or unsubstituted amino group, a halogen atom, a cyano group or a substituted or unsubstituted silyl group, and R^{f} and R^{h} each are a hydrogen atom or a deuterium atom (preferably a hydrogen atom). In another preferred embodiment of the present invention, R^{e} and R^{g} each are independently a substituted or unsubstituted amino group, and R^{f} and R^{h} each are a hydrogen atom or a deuterium atom (preferably a hydrogen atom). R^{e}, R^{f}, R^{g} and R^{h} all can be a hydrogen atom or a deuterium atom (preferably a hydrogen atom.

In another preferred embodiment of the present invention, the triplet-regulating compound is a compound represented by the following general formula (17).

$$Het {Ar}^{1} - {L}^{21} - Het {Ar}^{2} \qquad General Formula ( 17 )$$

In the general formula (17), HetAr¹ and HetAr² each independently represent a group represented by the following general formula (18), and at least one of them is a group represented by the general formula (18) that is substituted by the following general formula (19). L²¹ represents a linking group, for which reference can be made to the description and the preferred range of L in the general formula (3) mentioned hereinabove. In one preferred embodiment of the present invention, L²¹ in the general formula (17) is an unsubstituted arylene group (having 6 to 16 carbon atoms).

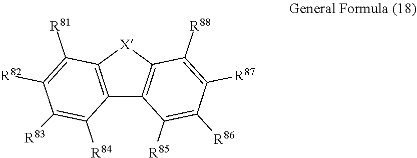

In the general formula (18), X represents an oxygen atom, a sulfur atom or N—R⁸⁹. One of R⁸¹ to R⁸⁹ bonds to L and the remaining R⁸¹ to R⁸⁹ each independently represent a hydrogen atom, a deuterium atom or a substituent. Regarding the description and the preferred range of the substituent as referred to herein, reference can be made to the description and the preferred range of the substituent in the general formula (7) mentioned hereinabove. For the description and the preferred range of the substituent herein, reference can also be made to the description and the preferred range of R^{c} and R^{d} in the general formula (15) mentioned above (but excluding a hydrogen atom). R⁸¹ and R⁸², R⁸² and R⁸³, R⁸³ and R⁸⁴, R⁸⁵ and R⁸⁶, R⁸⁶ and R⁸⁷, and R⁸⁷ and R⁸⁸ each can bond to each other to form a cyclic structure.

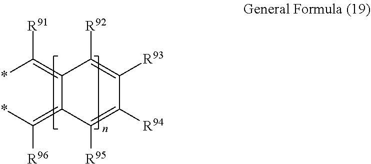

In the general formula (19), n represents an integer of 0 or more, and R⁹¹ to R⁹⁶ each independently represent a hydrogen atom, a deuterium atom or a substituent. Regarding the description and the preferred range of the substituent as referred to herein, reference can be made to the description and the preferred range of the substituent in the general formula (7) mentioned above. For the description and the preferred range of the substituent herein, reference can also be made to the description and the preferred range of R^{c} and R^{d} in the general formula (15) mentioned above (but excluding a hydrogen atom). n is preferably 0 to 3, and can be, for example, 0 or can be 1. * indicates the bonding position to the carbon atom that constitutes the ring skeleton of the ring in the general formula (18).

Of the compounds represented by the general formula (17), in particular, compounds represented by the following general formula (20) can be preferably employed.

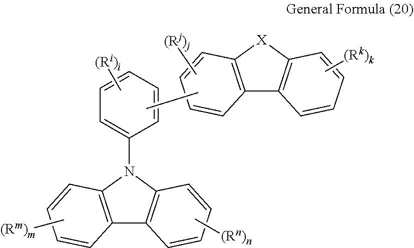

In the general formula (20), X represents an oxygen atom, a sulfur atom or N—R^{p}. Rⁱ, R^{j}, R^{k}, R^{m}, Rⁿ and R^{p} each independently represent a substituent. For the description and the preferred range of the substituent herein, reference can be made to the description and the preferred range of the substituent in the general formula (18) mentioned above. l, k, m and n in the general formula (20) each independently represents an integer of any of 0 to 4. j represents an integer of any of 0 to 3. i, j, k, m and n can be independently selected, for example, within a range of 0 to 2, and can be selected within a range of 0 to 1, and all these can be 0. In one preferred embodiment of the present invention, X represents an oxygen atom. In another preferred embodiment of the present invention, X represents an oxygen atom or a sulfur atom, and bond to the benzene ring in the center of the general formula (20) at the 2-position of the dibenzofuran ring or dibenzothiophene ring that contains X. In another preferred embodiment of the present invention, the tricyclic structure that contains X bonds to the benzene ring in the center at the meta-position of the 9-carbazolyl group.

In one preferred embodiment of the present invention, the triplet-regulating compound is a symmetric compound.

Two or more kinds of triplet-regulating compounds can be used, so far as they satisfy the requirement (a) and the requirement (b).

Preferred compounds usable as the triplet-regulating compounds are shown below.

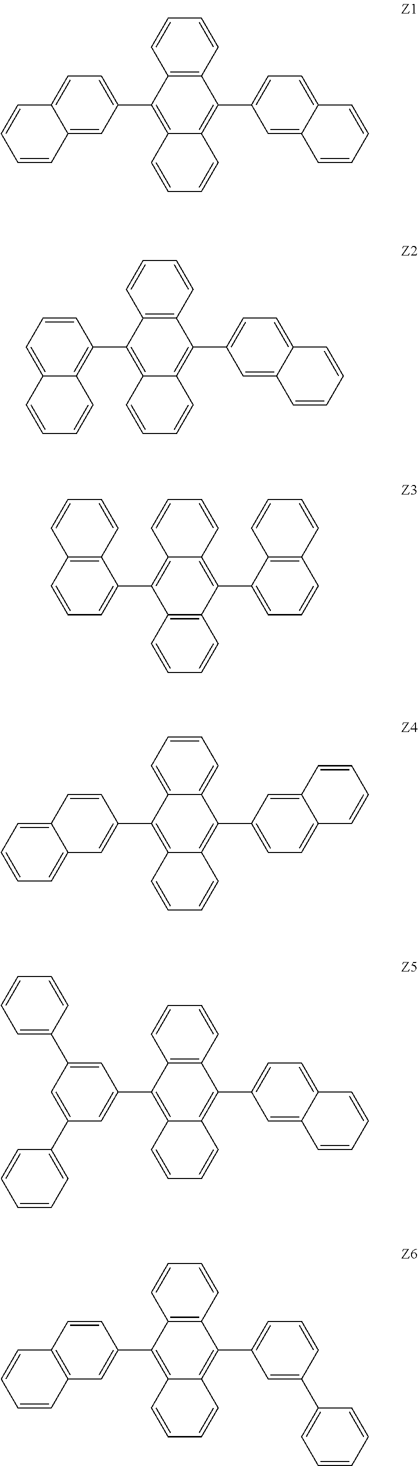

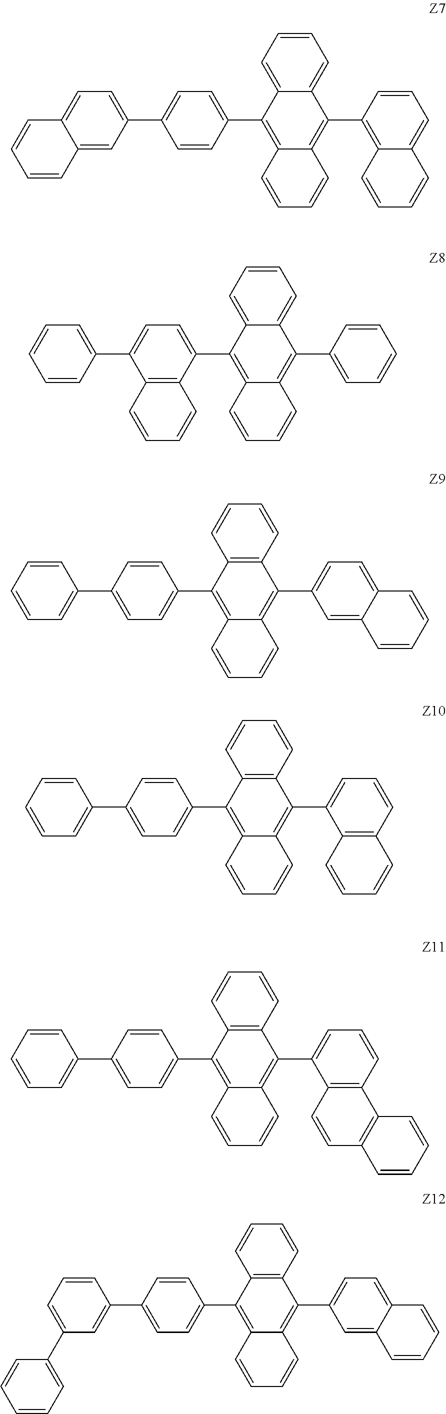

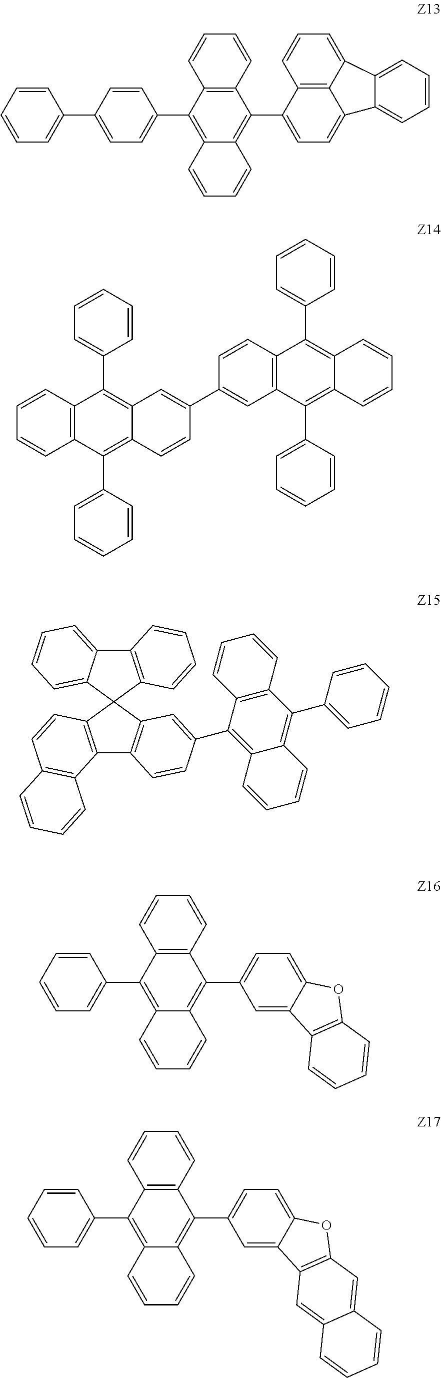

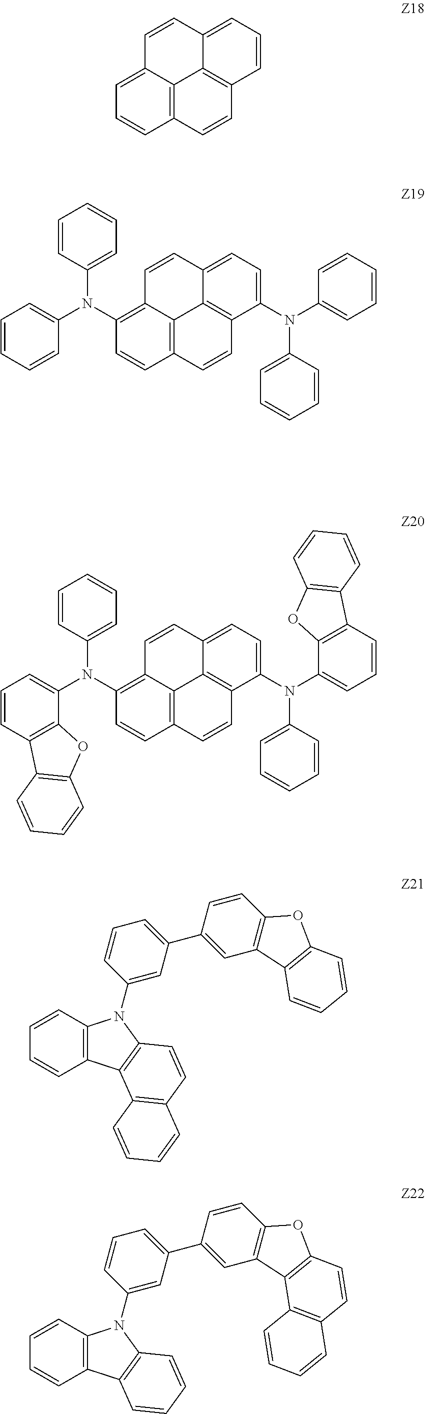

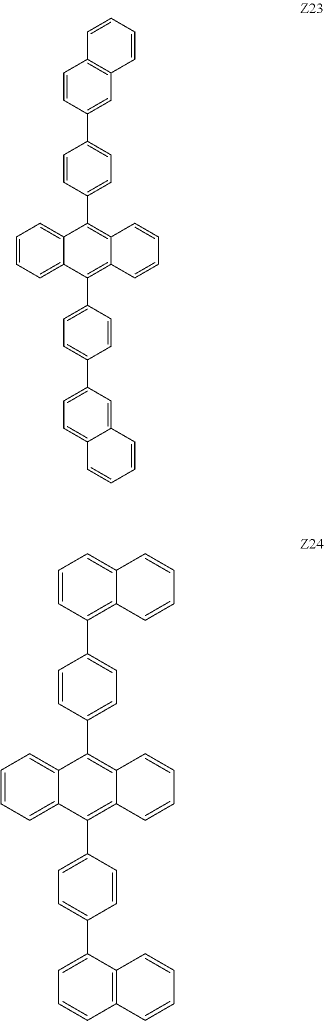

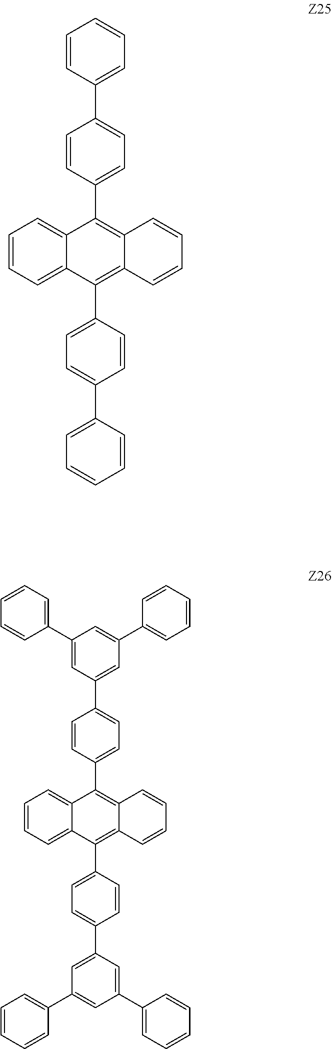

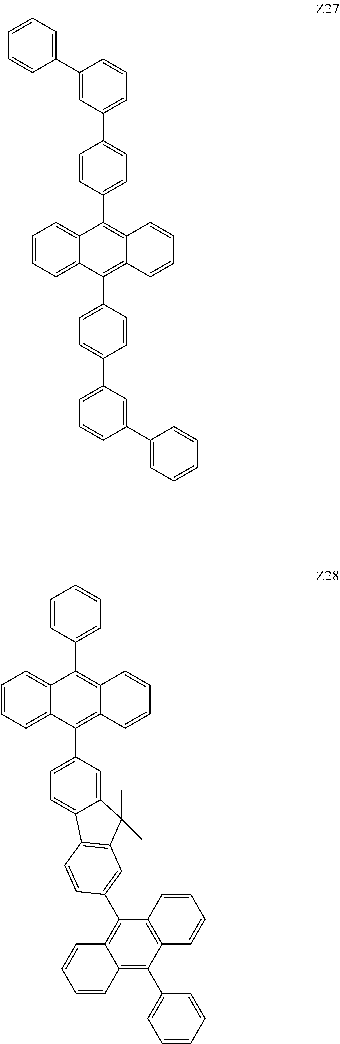

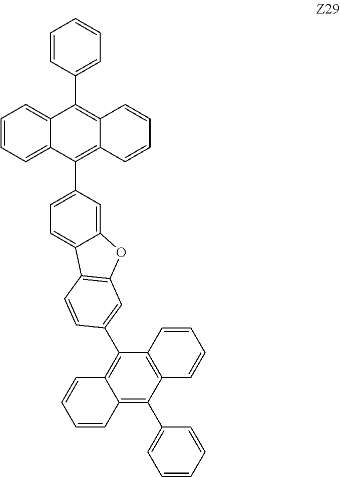 [SMILES: c1ccc(-c2c3ccccc3c(-c3ccc4c(c3)oc3cc(-c5c6ccccc6c(-c6ccccc6)c6ccccc56)ccc34)c3ccccc23)cc1]

### (Light Emitting Layer)

The light emitting layer of the light emitting device of the present invention contains the first organic compound and the second organic compound satisfying the requirement (a) and the requirement (b). Or the light emitting layer of the light emitting device of the present invention contains the first organic compound, the second organic compound and the third organic compound satisfying the requirement (a1) and the requirement (b2). The light emitting layer can be designed to contain neither a compound nor a metal element for transmitting and receiving charge or energy, in addition to the first organic compound, the second organic compound and the third organic compound. The light emitting layer can be composed of the first organic compound and the second organic compound alone, or can be composed of the first organic compound, the second organic compound and the third organic compound alone. The light emitting layer can be composed of a compound alone that consists of atoms selected from the group consisting of a carbon atom, a hydrogen atom, a deuterium atom, a nitrogen atom, a boron atom, an oxygen atom and a sulfur atom. For example, the light emitting layer can be composed of a compound alone that consists of atoms selected from the group consisting of a carbon atom, a hydrogen atom, a deuterium atom, a nitrogen atom, a boron atom, and an oxygen atom. For example, the light emitting layer can be composed of a compound alone that consists of atoms selected from the group consisting of a carbon atom, a hydrogen atom, a deuterium atom, a nitrogen atom, a boron atom, and an oxygen atom. For example, the light emitting layer can be composed of a compound alone that consists of atoms selected from the group consisting of a carbon atom, a hydrogen atom, a deuterium atom, a nitrogen atom, a boron atom, and a sulfur atom. For example, the light emitting layer can be composed of a compound alone that consists of atoms selected from the group consisting of a carbon atom, a hydrogen atom, a deuterium atom, a nitrogen atom, and a boron atom. For example, the light emitting layer can be composed of a compound alone that consists of atoms selected from the group consisting of a carbon atom, a hydrogen atom, a deuterium atom, a nitrogen atom, an oxygen atom, and a sulfur atom. For example, the light emitting layer can be composed of a compound alone that consists of atoms selected from the group consisting of a carbon atom, a hydrogen atom, a deuterium atom, and a nitrogen atom. Or the first organic compound, the second organic compound and the third organic compound of an optional component can be each independently a compound composed of atoms selected from the group consisting of a carbon atom, a hydrogen atom, a nitrogen atom, an oxygen atom and a sulfur atom. For example, the first organic compound, the second organic compound and the third organic compound of an optional component can be each independently a compound composed of atoms selected from the group consisting of a carbon atom, a hydrogen atom, a nitrogen atom, and an oxygen atom. For example, the first organic compound, the second organic compound and the third organic compound of an optional component can be each independently a compound composed of atoms selected from the group consisting of a carbon atom, a hydrogen atom, a nitrogen atom, and a sulfur atom. For example, the first organic compound, the second organic compound and the third organic compound of an optional component can be each independently a compound composed of atoms selected from the group consisting of a carbon atom, a hydrogen atom, a deuterium atom. and a nitrogen atom.

The light emitting layer can be formed by co-evaporation of the first organic compound, the second organic compound and the third organic compound of an optional component, or can be formed according to a coating method that uses a solution prepared by dissolving the first organic compound, the second organic compound and the third organic compound of an optional component. When the light emitting layer is formed by co-evaporation, two or more of the first organic compound, the second organic compound and the third organic compound of an optional component can be previously mixed and put into a crucible or the like to be an evaporation source, and the light emitting layer can be formed by co-evaporation using the evaporation source. For example, the first organic compound and the second organic compound are previously mixed to form one evaporation source, and the light emitting layer can be formed by co-evaporation using the previously-prepared evaporation source and an evaporation source of the third organic compound.

### (Layer Configuration of Organic Electroluminescent Device)

By forming a light emitting layer that contains the first organic compound and the second organic compound satisfying the requirement (a) and the requirement (b), and by forming a barrier layer that contains a triplet-regulating compound in contact with (laminated on) the light emitting layer, there can be provided an excellent organic light emitting device such as an organic photoluminescent device (organic PL device) and an organic electroluminescent device (organic EL device).

The thickness of the light emitting layer can be, for example, 1 to 15 nm, or can be 2 to 10 nm, or can be 3 to 7 nm.

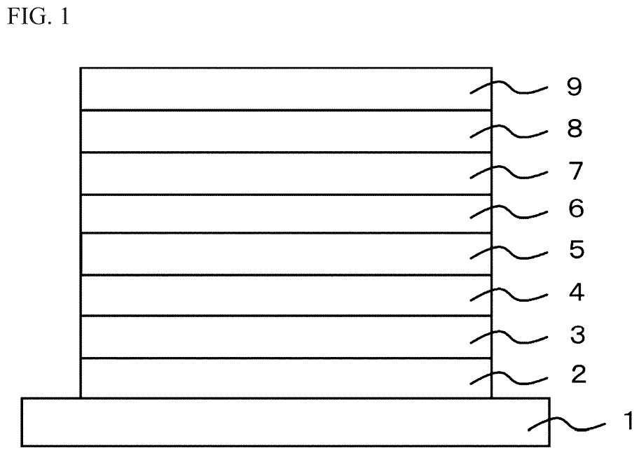

An organic photoluminescent device has a configuration that has at least a light emitting layer and a barrier layer in contact with (laminated on) the light emitting layer, formed on a substrate. An organic electroluminescent device has a configuration that has at least an anode, a cathode, and an organic layer formed between the anode and the cathode. The organic layer contains at least a light emitting layer and a barrier layer in contact with (laminated on) the light emitting layer, and can be a light emitting layer and a barrier layer in contact with (laminated on) the light emitting layer alone, or can have any other one or more organic layers than a light emitting layer and a barrier layer in contact with (laminated on) the light emitting layer. Such other organic layers than a light emitting layer include a hole transporting layer, a hole injection layer, an electron barrier layer, a hole barrier layer, an electron injection layer, an electron transporting layer, and an exciton barrier layer. The hole transporting layer can also be a hole injection transporting layer having a hole injection function, and the electron transporting layer can also be an electron injection transporting layer having an electron injection function. A specific configuration example of an organic electroluminescent device is shown in FIG. 1. In FIG. 1, 1 is a glass substrate, 2 is an anode, 3 is a hole injection layer, 4 is a hole transporting layer, 5 is an electron barrier layer, 6 is a light emitting layer, 7 is a hole barrier layer, 8 is a hole transporting layer, and 9 is a cathode.

In the case where the organic electroluminescent device of the present invention is a multi-wavelength emission-type organic light emitting device, the device can be so designed that the shortest wavelength emission contains delayed fluorescence. The device can be so designed that the shortest wavelength emission does not contain delayed fluorescence.

### (Production Method for Organic Light Emitting Device)

The production method for the organic light emitting device of the present invention is not specifically limited.

A preferred production method includes a step of forming a triplet-regulating compound-containing barrier layer, and forming a light emitting layer containing a first organic compound and a second organic compound of a delayed fluorescent material, so as to be in contact with (laminated on) the barrier layer. For example, in the case where an organic layer is laminated on an anode to produce an organic electroluminescent device, a triplet-regulating compound-containing electron barrier layer is formed, and a light emitting layer containing a first organic compound and a second organic compound can be formed so as to be layered on the electron barrier layer.

Another preferred production method includes a step of forming a light emitting layer containing a first organic compound and a second organic compound of a delayed fluorescent material, and forming a triplet-regulating compound-containing barrier layer so as to be in contact with (laminated on) the light emitting layer. For example, in the case where an organic layer is laminated on an anode to produce an organic electroluminescent device, a light emitting layer containing a first organic compound and a second organic compound is formed, and a triplet-regulating compound-containing hole barrier layer can be formed so as to be layered on the light emitting layer.

These preferred production methods can be combined. Namely, a triplet-regulating compound-containing first barrier layer is formed, then a light emitting layer containing a first organic compound and a second organic compound is formed so as to be in contact with (laminated on) the first barrier layer, and further a triplet-regulating compound-containing second barrier layer can be formed so as to be in contact with (laminated on) the light emitting layer. At that time, the triplet-regulating compound to constitute the first barrier layer and that to constitute the second barrier layer can be the same or different. Also the thickness of the first barrier layer can be the same as that of the second barrier layer. In the case where an organic layer is laminated on an anode to produce an organic electroluminescent device, the first barrier layer can be an electron barrier layer and the second barrier layer can be a hole barrier layer.

In the production method of the present invention, the first organic compound, the second organic compound and the triplet-regulating compound for use in the light emitting layer and the barrier layer that are in contact with each other are so selected as to satisfy the above-mentioned requirements (a) and (b). Also the light emitting layer can contain a third organic compound, and in that case, the first organic compound, the second organic compound, the third organic compound and the triplet-regulating compound for use in the light emitting layer and the barrier layer that are in contact with each other are so selected as to satisfy the above-mentioned requirements (a1) and (b1).

The method of forming the light emitting layer and the barrier layer is not specifically limited. A preferred forming method is an evaporation method. The layers can also be formed by a coating method. The light emitting layer and the barrier layer in contact with each other can be formed continuously, or can be formed intermittently. Preferably the layers are formed continuously.

The production method of the present invention can be readily implemented by using an ordinary organic light emitting device production line (production equipment). Namely, in an ordinary production line, materials to be used in forming the light emitting layer and the barrier layer are changed so as to satisfy the requirements (a) and (b), and thus the production method of the present invention can be simply implemented. Consequently, the advantage of the production method of the present invention is that the method can be implemented without changing or newly creating a production line. After the production method of the present invention has been implemented, the production line can be again returned back to a production line for an organic light emitting device different from the present invention. Consequently, the industrial applicability of the production method of the present invention is great in the point that the method can be implemented economically and within a short period of time.

The production method of the present invention is not specifically limited in point of the method of forming the other layers and structures so far as the materials satisfying the requirements (a) and (b) are used to form the light emitting layer and the barrier layer so as to be in contact with each other. For example, the method can further include a step of forming an electrode such as an anode and a cathode, and can further include a step of forming any other layer than the light emitting layer and the barrier layer. In the case where the production method of the present invention is used for producing, for example, an organic electroluminescent device, one or more organic layers are sequentially formed on an anode, a barrier layer is formed thereon, a light emitting layer is formed thereon, one or more organic layers are formed thereon, and a cathode is formed thereon. Or one or more organic layers are sequentially formed on an anode, a light emitting layer is formed thereon, a barrier layer is formed thereon, one or more organic layers are formed thereon, and a cathode is formed thereon. Further, one or more organic layers are sequentially formed on an anode, a first barrier layer is formed thereon, a light emitting layer is formed thereon, a second barrier layer is formed thereon, one or more organic layers are formed thereon, and a cathode is formed thereon. In these production methods, the cathode and the anode can be exchanged, and layers are formed on the cathode, and finally the anode is formed. Further, modification or addition obvious to those skilled in the art can be made in these methods.

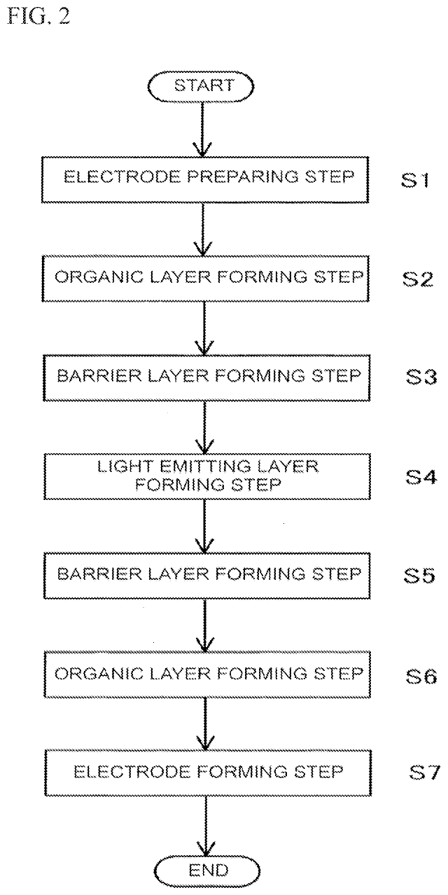

FIG. 2 is a flowchart showing a process for implementing a production method for an organic light emitting device. In the case where an organic electroluminescent device is produced, an electrode is prepared (S1), and an organic layer is formed on the electrode (S2). Next, on the thus-formed organic layer, a barrier layer is formed (S3), and a light emitting layer is further thereon (S4). On the thus-formed light emitting layer, another barrier layer is further formed (S5), and an organic layer differing from that formed in S2 is further formed thereon (S6). Finally, an electrode is formed on the organic layer (S7) to produce an organic electroluminescent device. In production, one or both of the organic layer-forming steps S2 and S6 can be omitted. Also one of the barrier layer-forming steps S3 and S5 can be omitted. In the case where an organic photoluminescent device is produced, the electrode-preparing step S1 and the electrode-forming step S7 can be omitted. In the production method of the present invention, it is necessary that the materials for use in the barrier layer-forming step S3 and the materials for use in the light emitting layer-forming step S4 are selected so as to satisfy the requirements (a) and (b), or the materials for use in the light emitting layer-forming step S4 and the materials for use in the barrier layer-forming step S5 are selected so as to satisfy the requirements (a) and (b).

In the following, the constituent members and the other layers than the light emitting layer of the organic electroluminescent device are described.

### Substrate:

In some embodiments, the organic electroluminescent device of the invention is supported by a substrate, wherein the substrate is not particularly limited and may be any of those that have been commonly used in an organic electroluminescent device, for example those formed of glass, transparent plastics, quartz and silicon.

### Anode

In some embodiments, the anode of the organic electroluminescent device is made of a metal, an alloy, an electroconductive compound, or a combination thereof. In some embodiments, the metal, alloy, or electroconductive compound has a large work function (4 eV or more). In some embodiments, the metal is Au. In some embodiments, the electroconductive transparent material is selected from CuI, indium tin oxide (ITO), SnO₂, and ZnO. In some embodiments, an amorphous material capable of forming a transparent electroconductive film, such as IDIXO (In₂O₃—ZnO), is be used. In some embodiments, the anode is a thin film. In some embodiments the thin film is made by vapor deposition or sputtering. In some embodiments, the film is patterned by a photolithography method. In some embodiments, where the pattern may not require high accuracy (for example, approximately 100 μm or more), the pattern may be formed with a mask having a desired shape on vapor deposition or sputtering of the electrode material. In some embodiments, when a material can be applied as a coating, such as an organic electroconductive compound, a wet film forming method, such as a printing method and a coating method is used. In some embodiments, when the emitted light goes through the anode, the anode has a transmittance of more than 10%, and the anode has a sheet resistance of several hundred Ohm per square or less. In some embodiments, the thickness of the anode is from 10 to 1,000 nm. In some embodiments, the thickness of the anode is from 10 to 200 nm. In some embodiments, the thickness of the anode varies depending on the material used.

### Cathode

In some embodiments, the cathode is made of an electrode material a metal having a small work function (4 eV or less) (referred to as an electron injection metal), an alloy, an electroconductive compound, or a combination thereof. In some embodiments, the electrode material is selected from sodium, a sodium-potassium alloy, magnesium, lithium, a magnesium-cupper mixture, a magnesium-silver mixture, a magnesium-aluminum mixture, a magnesium-indium mixture, an aluminum-aluminum oxide (Al₂O₃) mixture, indium, a lithium-aluminum mixture, and a rare earth metal. In some embodiments, a mixture of an electron injection metal and a second metal that is a stable metal having a larger work function than the electron injection metal is used. In some embodiments, the mixture is selected from a magnesium-silver mixture, a magnesium-aluminum mixture, a magnesium-indium mixture, an aluminum-aluminum oxide (Al₂O₃) mixture, a lithium-aluminum mixture, and aluminum. In some embodiments, the mixture increases the electron injection property and the durability against oxidation. In some embodiments, the cathode is produced by forming the electrode material into a thin film by vapor deposition or sputtering. In some embodiments, the cathode has a sheet resistance of several hundred Ohm per square or less. In some embodiments, the thickness of the cathode ranges from 10 nm to 5 μm. In some embodiments, the thickness of the cathode ranges from 50 to 200 nm. In some embodiments, for transmitting the emitted light, any one of the anode and the cathode of the organic electroluminescent device is transparent or translucent. In some embodiments, the transparent or translucent electroluminescent devices enhances the light emission luminance.

In some embodiments, the cathode is formed with an electroconductive transparent material, as described for the anode, to form a transparent or translucent cathode. In some embodiments, a device comprises an anode and a cathode, both being transparent or translucent.

### Injection Layer

An injection layer is a layer between the electrode and the organic layer. In some embodiments, the injection layer decreases the driving voltage and enhances the light emission luminance. In some embodiments the injection layer includes a hole injection layer and an electron injection layer. The injection layer can be positioned between the anode and the light emitting layer or the hole transporting layer, and between the cathode and the light emitting layer or the electron transporting layer. In some embodiments, an injection layer is present. In some embodiments, no injection layer is present.

Preferred compound examples for use as a hole injection material are shown below.

MoO₃,

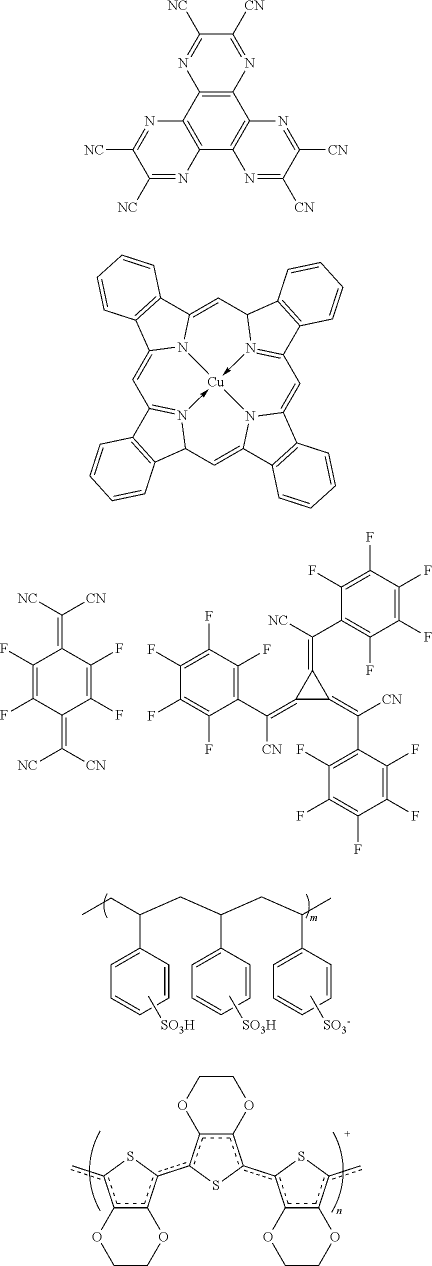

Next, preferred compound examples for use as an electron injection material are shown below.

LiF, CsF,

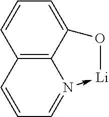

### Barrier Layer

A barrier layer is a layer capable of inhibiting charges (electrons or holes) and/or excitons present in the light emitting layer from being diffused outside the light emitting layer. In some embodiments, the electron barrier layer is between the light emitting layer and the hole transporting layer, and inhibits electrons from passing through the light emitting layer toward the hole transporting layer. In some embodiments, the hole barrier layer is between the light emitting layer and the electron transporting layer, and inhibits holes from passing through the light emitting layer toward the electron transporting layer. In some embodiments, the barrier layer inhibits excitons from being diffused outside the light emitting layer. In some embodiments, the electron barrier layer and the hole barrier layer are exciton barrier layers. As used herein, the term “electron barrier layer” or “exciton barrier layer” includes a layer that has the functions of both electron barrier layer and of an exciton barrier layer.

### Hole Barrier Layer

A hole barrier layer acts as an electron transporting layer. In some embodiments, the hole barrier layer inhibits holes from reaching the electron transporting layer while transporting electrons. In some embodiments, the hole barrier layer enhances the recombination probability of electrons and holes in the light emitting layer. The material for the hole barrier layer may be the same materials as ones which will be described later for the electron transporting layer.

When the hole barrier layer is in contact with (laminated on) the light emitting layer, the hole barrier layer preferably contains a triplet-regulating compound.

Preferred compound examples for use for the hole barrier layer are shown below.

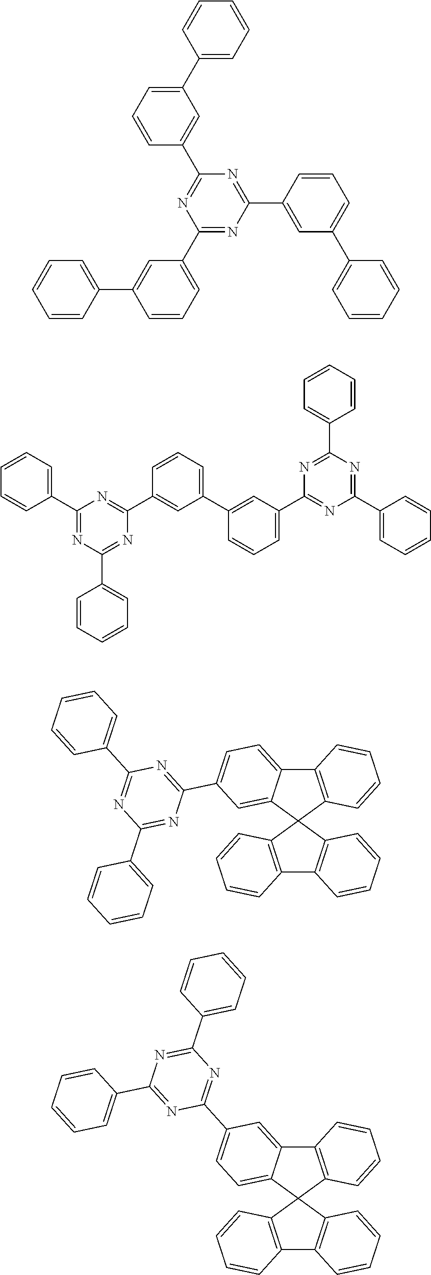 [SMILES: c1ccc(-c2cccc(-c3nc(-c4cccc(-c5ccccc5)c4)nc(-c4cccc(-c5ccccc5)c4)n3)c2)cc1 ; c1ccc(-c2nc(-c3ccccc3)nc(-c3cccc(-c4cccc(-c5nc(-c6ccccc6)nc(-c6ccccc6)n5)c4)c3)n2)cc1 ; c1ccc(-c2nc(-c3ccccc3)nc(-c3ccc4c(c3)C3(c5ccccc5-c5ccccc53)c3ccccc3-4)n2)cc1 ; c1ccc(-c2nc(-c3ccccc3)nc(-c3ccc4c(c3)-c3ccccc3C43c4ccccc4-c4ccccc43)n2)cc1]

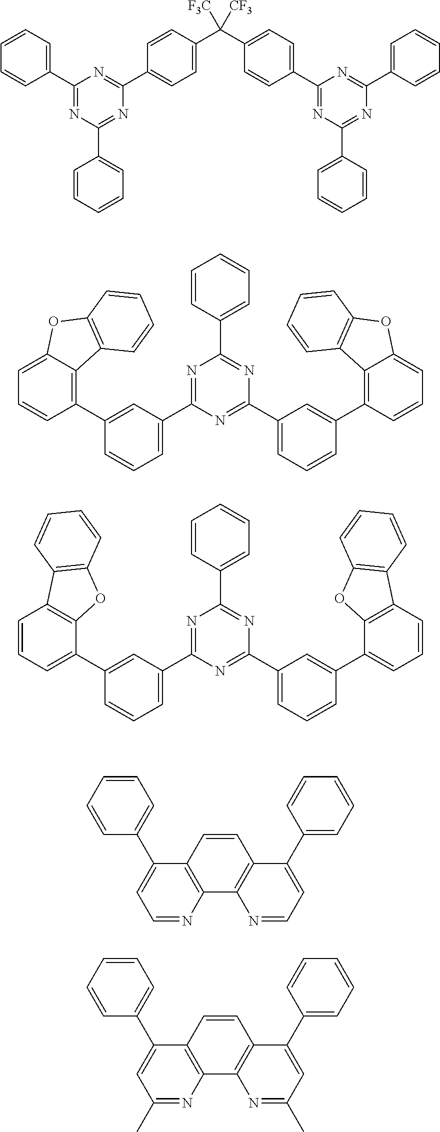

### Electron Barrier Layer

As electron barrier layer transports holes. In some embodiments, the electron barrier layer inhibits electrons from reaching the hole transporting layer while transporting holes. In some embodiments, the electron barrier layer enhances the recombination probability of electrons and holes in the light emitting layer. The material for the electron barrier layer may be the same materials as ones which will be described later for the hole transporting layer.

When the electron barrier layer is in contact with (laminated on) the light emitting layer, the electron barrier layer preferably contains a triplet-regulating compound.

Preferred compound examples except triplet-regulating compounds for use as the electron barrier material are shown below.

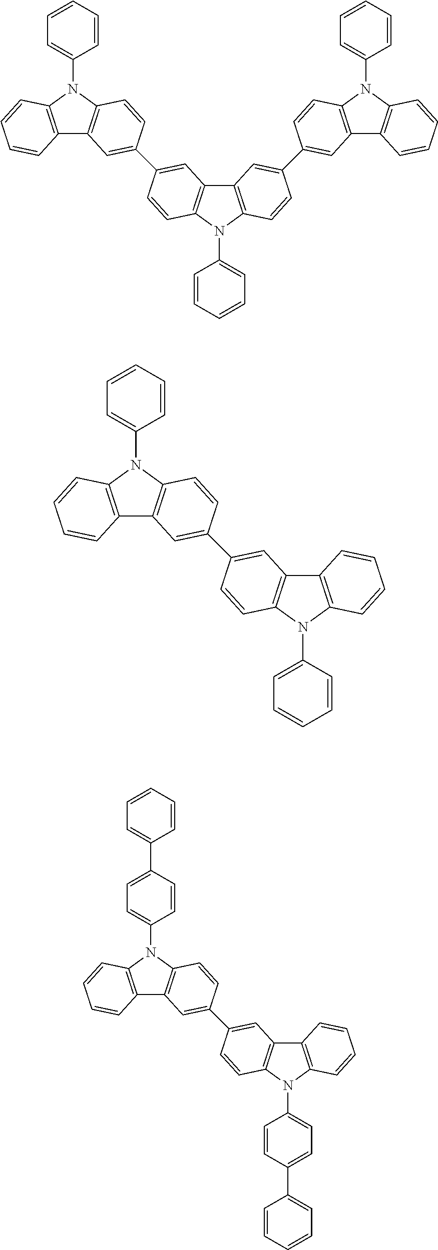 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

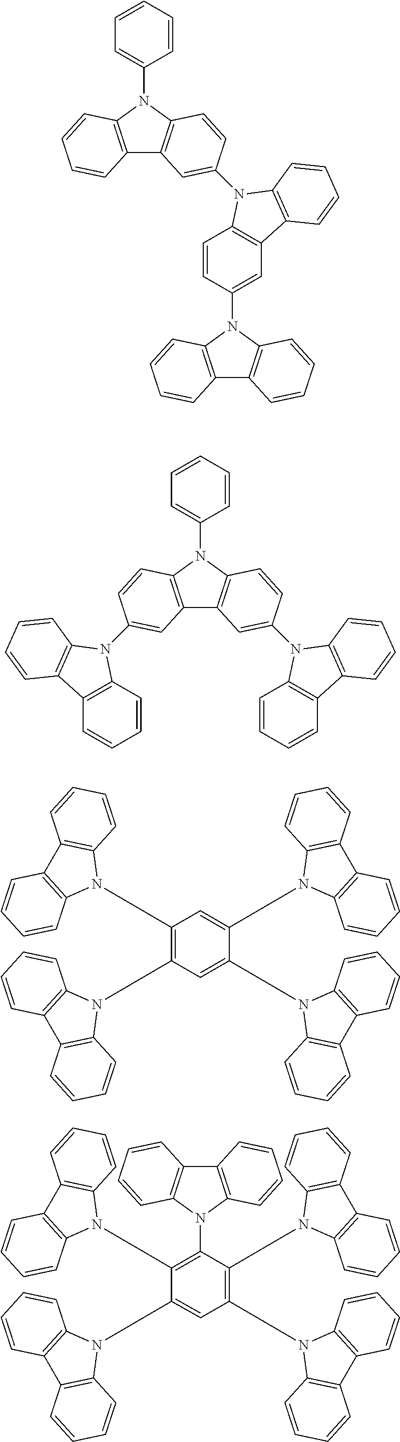

### Exciton Barrier Layer

An exciton barrier layer inhibits excitons generated through recombination of holes and electrons in the light emitting layer from being diffused to the charge transporting layer. In some embodiments, the exciton barrier layer enables effective confinement of excitons in the light emitting layer. In some embodiments, the light emission efficiency of the device is enhanced. In some embodiments, the exciton barrier layer is in contact with (laminated on) the light emitting layer on any of the side of the anode and the side of the cathode, and on both the sides. In some embodiments, where the exciton barrier layer is on the side of the anode, the layer can be between the hole transporting layer and the light emitting layer and in contact with (laminated on) the light emitting layer. In some embodiments, where the exciton barrier layer is on the side of the cathode, the layer can be between the light emitting layer and the cathode and in contact with (laminated on) the light emitting layer. In some embodiments, a hole injection layer, an electron barrier layer, or a similar layer is between the anode and the exciton barrier layer that is in contact with (laminated on) the light emitting layer on the side of the anode. In some embodiments, a hole injection layer, an electron barrier layer, a hole barrier layer, or a similar layer is between the cathode and the exciton barrier layer that is in contact with (laminated on) the light emitting layer on the side of the cathode. In some embodiments, the exciton barrier layer comprises excited singlet energy and excited triplet energy, at least one of which is higher than the excited singlet energy and the excited triplet energy of the light emitting material, respectively.

When the exciton barrier layer is in contact with (laminated on) the light emitting layer, the exciton barrier layer preferably contains a triplet-regulating compound.

### Hole Transporting Layer

The hole transporting layer comprises a hole transporting material. In some embodiments, the hole transporting layer is a single layer. In some embodiments, the hole transporting layer comprises a plurality layers.

In some embodiments, the hole transporting material has one of injection or transporting property of holes and barrier property of electrons. In some embodiments, the hole transporting material is an organic material. In some embodiments, the hole transporting material is an inorganic material. Examples of known hole transporting materials that may be used herein include but are not limited to a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer, or a combination thereof. In some embodiments, the hole transporting material is selected from a porphyrin compound, an aromatic tertiary amine compound, and a styrylamine compound. In some embodiments, the hole transporting material is an aromatic tertiary amine compound. Preferred compound examples for use as the hole transporting material are shown below.

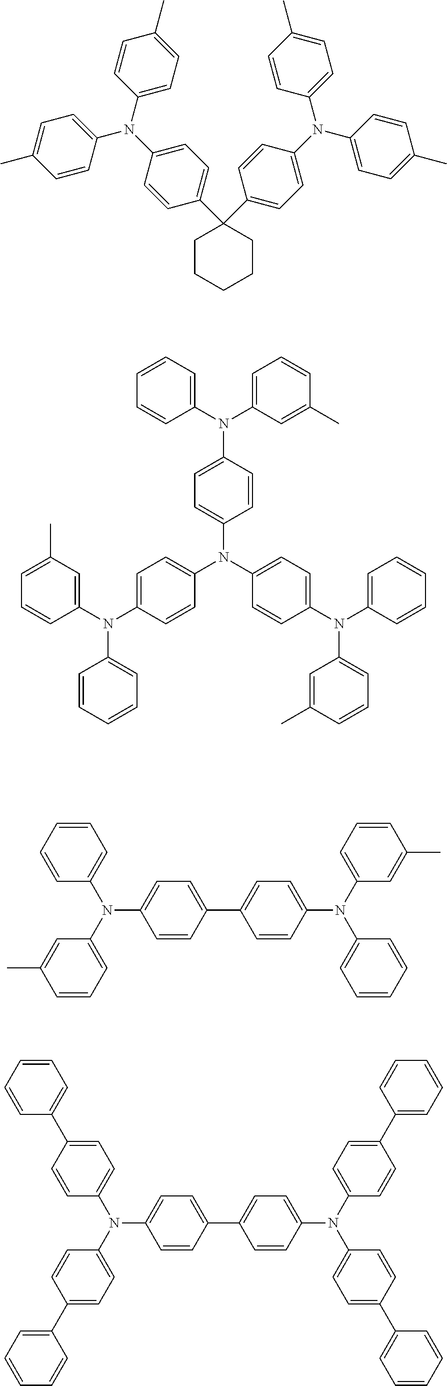

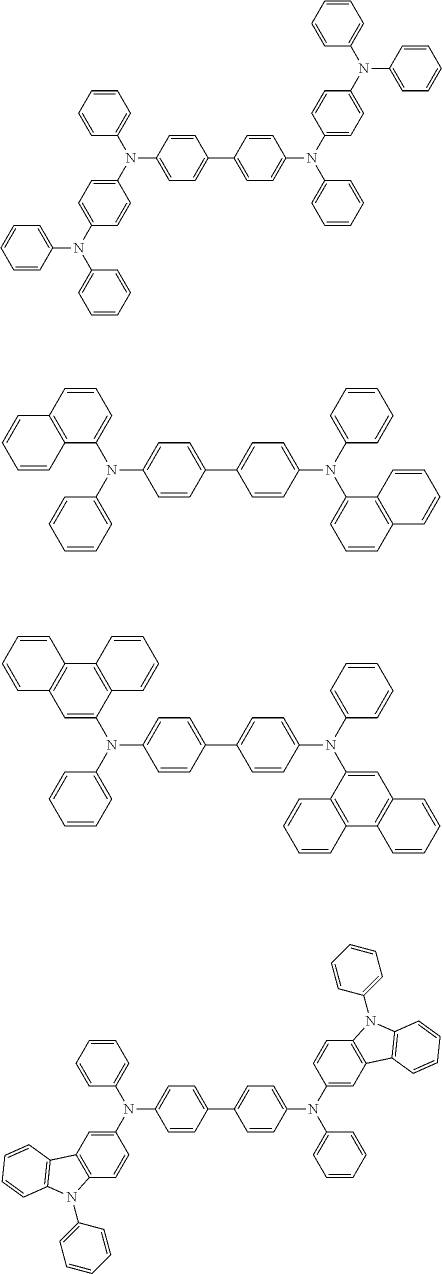 [SMILES: c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc(N(c2ccc(-c3ccc(N(c4ccccc4)c4cc5ccccc5c5ccccc45)cc3)cc2)c2cc3ccccc3c3ccccc23)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

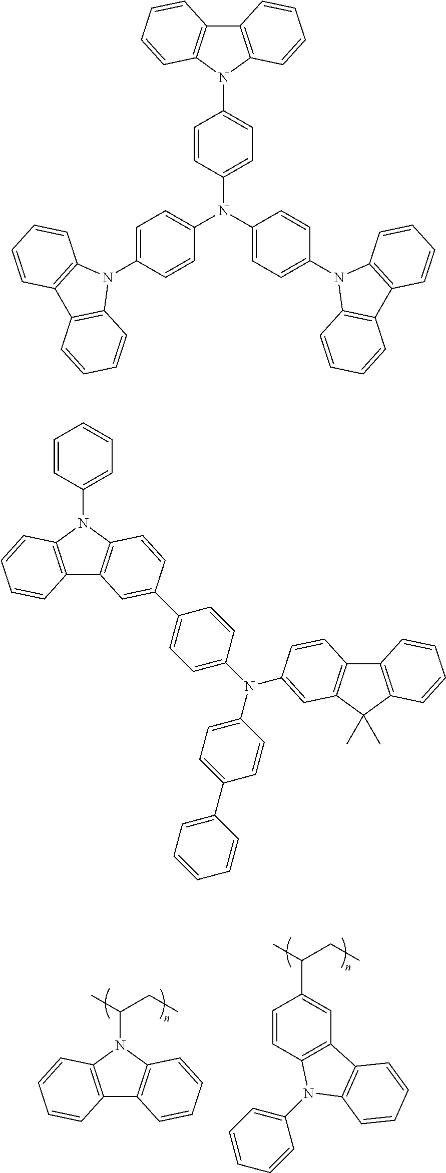

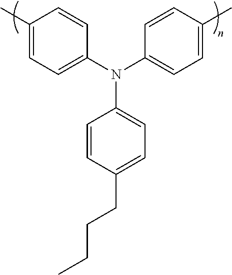

### Electron Transporting Layer

The electron transporting layer comprises an electron transporting material. In some embodiments, the electron transporting layer is a single layer. In some embodiments, the electron transporting layer comprises a plurality of layer.

In some embodiments, the electron transporting material needs only to have a function of transporting electrons, which are injected from the cathode, to the light emitting layer. In some embodiments, the electron transporting material also function as a hole barrier material. Examples of the electron transporting layer that may be used herein include but are not limited to a nitro-substituted fluorene derivative, a diphenylquinone derivative, a thiopyran dioxide derivative, carbodiimide, a fluorenylidene methane derivative, anthraquinodimethane, an anthrone derivatives, an azole derivative, an azine derivative, an oxadiazole derivative, or a combination thereof, or a polymer thereof. In some embodiments, the electron transporting material is a thiadiazole derivative, or a quinoxaline derivative. In some embodiments, the electron transporting material is a polymer material. Preferred compound examples for use as the electron transporting material are shown below.

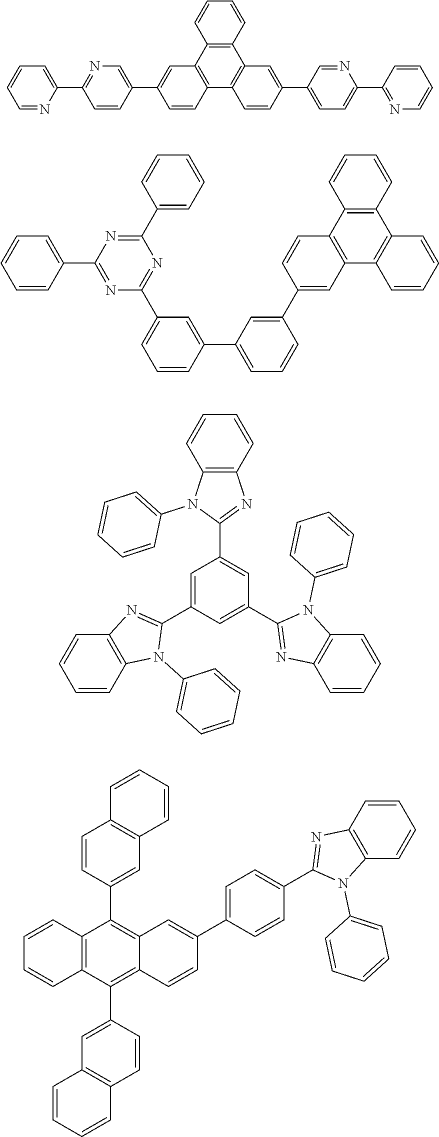

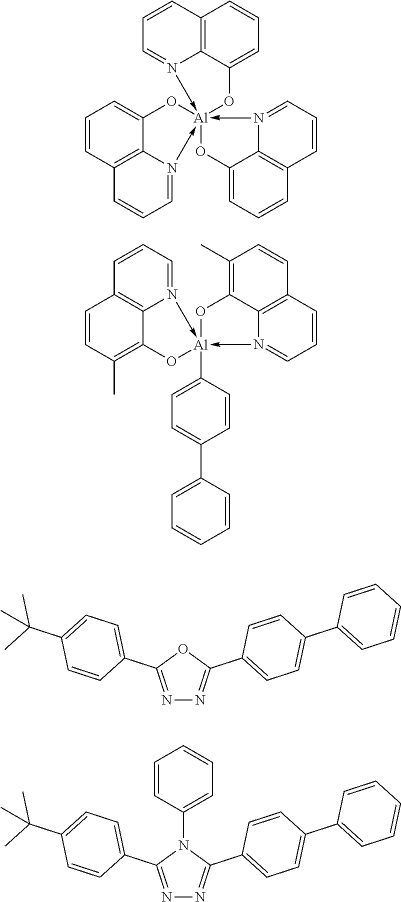

Hereinunder compound examples preferred as a material that can be added to the organic layers are shown. For example, these can be added as a stabilization material.

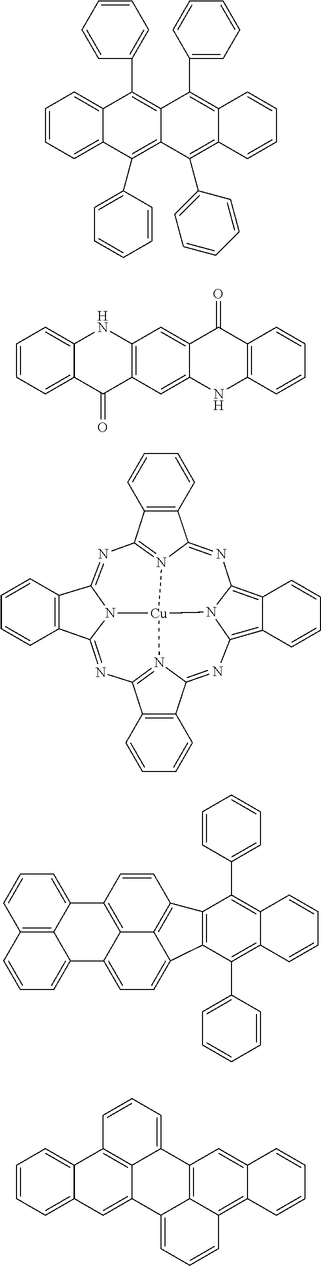

Preferred materials for use in the organic electroluminescent device are specifically shown. However, the materials usable in the invention should not be limitatively interpreted by the following exemplary compounds. Compounds that are exemplified as materials having a specific function can also be used as materials having any other function.

### Devices

In some embodiments, an light emitting layer is incorporated into a device. For example, the device includes, but is not limited to an OLED bulb, an OLED lamp, a television screen, a computer monitor, a mobile phone, and a tablet.

In some embodiments, an electronic device comprises an OLED comprising an anode, a cathode, and at least one organic layer comprising a light emitting layer between the anode and the cathode.

In some embodiments, compositions described herein may be incorporated into various light-sensitive or light-activated devices, such as a OLEDs or photovoltaic devices. In some embodiments, the composition may be useful in facilitating charge transfer or energy transfer within a device and/or as a hole-transport material. The device may be, for example, an organic light emitting diode (OLED), an organic integrated circuit (O-IC), an organic field-effect transistor (O-FET), an organic thin-film transistor (O-TFT), an organic light emitting transistor (O-LET), an organic solar cell (O-SC), an organic optical detector, an organic photoreceptor, an organic field-quench device (O-FQD), a light emitting electrochemical cell (LEC) or an organic laser diode (O-laser).

### Bulbs or Lamps

In some embodiments, an electronic device comprises an OLED comprising an anode, a cathode, and at least one organic layer comprising a light emitting layer between the anode and the cathode.

In some embodiments, a device comprises OLEDs that differ in color. In some embodiments, a device comprises an array comprising a combination of OLEDs. In some embodiments, the combination of OLEDs is a combination of three colors (e.g., RGB). In some embodiments, the combination of OLEDs is a combination of colors that are not red, green, or blue (for example, orange and yellow green). In some embodiments, the combination of OLEDs is a combination of two, four, or more colors.

In some embodiments, a device is an OLED light comprising:
a circuit board having a first side with a mounting surface and an opposing second side, and defining at least one aperture;
at least one OLED on the mounting surface, the at least one OLED configured to emanate light, comprising:
   an anode, a cathode, and at least one organic layer comprising a light emitting layer between the anode and the cathode;
a housing for the circuit board; and
at least one connector arranged at an end of the housing, the housing and the connector defining a package adapted for installation in a light fixture.

In some embodiments, the OLED light comprises a plurality of OLEDs mounted on a circuit board such that light emanates in a plurality of directions. In some embodiments, a portion of the light emanated in a first direction is deflected to emanate in a second direction. In some embodiments, a reflector is used to deflect the light emanated in a first direction.

### Displays or Screens

In some embodiments, the compounds of the invention can be used in a screen or a display. In some embodiments, the compounds of the invention are deposited onto a substrate using a process including, but not limited to, vacuum evaporation, deposition, vapor deposition, or chemical vapor deposition (CVD). In some embodiments, the substrate is a photoplate structure useful in a two-sided etch provides a unique aspect ratio pixel. The screen (which may also be referred to as a mask) is used in a process in the manufacturing of OLED displays. The corresponding artwork pattern design facilitates a very steep and narrow tie-bar between the pixels in the vertical direction and a large, sweeping bevel opening in the horizontal direction. This allows the close patterning of pixels needed for high definition displays while optimizing the chemical deposition onto a TFT backplane.

The internal patterning of the pixel allows the construction of a 3-dimensional pixel opening with varying aspect ratios in the horizontal and vertical directions. Additionally, the use of imaged “stripes” or halftone circles within the pixel area inhibits etching in specific areas until these specific patterns are undercut and fall off the substrate. At that point the entire pixel area is subjected to a similar etch rate but the depths are varying depending on the halftone pattern. Varying the size and spacing of the halftone pattern allows etching to be inhibited at different rates within the pixel allowing for a localized deeper etch needed to create steep vertical bevels.

A preferred material for the deposition mask is invar. Invar is a metal alloy that is cold rolled into long thin sheet in a steel mill. Invar cannot be electrodeposited onto a rotating mandrel as the nickel mask. A preferred and more cost feasible method for forming the open areas in the mask used for deposition is through a wet chemical etching.

In some embodiments, a screen or display pattern is a pixel matrix on a substrate. In some embodiments, a screen or display pattern is fabricated using lithography (e.g., photolithography and e-beam lithography). In some embodiments, a screen or display pattern is fabricated using a wet chemical etch. In further embodiments, a screen or display pattern is fabricated using plasma etching.

### Methods of Manufacturing Devices

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light emitting layer, a counter electrode, and an encapsulation layer, and then is cut from the mother panel.

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light emitting layer, a counter electrode, and an encapsulation layer, and then is cut from the mother panel.

In another aspect, provided herein is a method of manufacturing an organic light emitting diode (OLED) display, the method comprising:
forming a barrier layer on a base substrate of a mother panel;
forming a plurality of display units in units of cell panels on the barrier layer;
forming an encapsulation layer on each of the display units of the cell panels;
applying an organic film to an interface portion between the cell panels.

In some embodiments, the barrier layer is an inorganic film formed of, for example, SiNx, and an edge portion of the barrier layer is covered with an organic film formed of polyimide or acryl. In some embodiments, the organic film helps the mother panel to be softly cut in units of the cell panel.

In some embodiments, the thin film transistor (TFT) layer includes a light emitting layer, a gate electrode, and a source/drain electrode. Each of the plurality of display units may include a thin film transistor (TFT) layer, a planarization film formed on the TFT layer, and a light emitting unit formed on the planarization film, wherein the organic film applied to the interface portion is formed of a same material as a material of the planarization film and is formed at a same time as the planarization film is formed. In some embodiments, a light emitting unit is connected to the TFT layer with a passivation layer and a planarization film therebetween and an encapsulation layer that covers and protects the light emitting unit. In some embodiments of the method of manufacturing, the organic film contacts neither the display units nor the encapsulation layer.

Each of the organic film and the planarization film may include any one of polyimide and acryl. In some embodiments, the barrier layer may be an inorganic film. In some embodiments, the base substrate may be formed of polyimide. The method may further include, before the forming of the barrier layer on one surface of the base substrate formed of polyimide, attaching a carrier substrate formed of a glass material to another surface of the base substrate, and before the cutting along the interface portion, separating the carrier substrate from the base substrate. In some embodiments, the OLED display is a flexible display.

In some embodiments, the passivation layer is an organic film disposed on the TFT layer to cover the TFT layer. In some embodiments, the planarization film is an organic film formed on the passivation layer. In some embodiments, the planarization film is formed of polyimide or acryl, like the organic film formed on the edge portion of the barrier layer. In some embodiments, the planarization film and the organic film are simultaneously formed when the OLED display is manufactured. In some embodiments, the organic film may be formed on the edge portion of the barrier layer such that a portion of the organic film directly contacts the base substrate and a remaining portion of the organic film contacts the barrier layer while surrounding the edge portion of the barrier layer.

In some embodiments, the light emitting layer includes a pixel electrode, a counter electrode, and an organic light emitting layer disposed between the pixel electrode and the counter electrode. In some embodiments, the pixel electrode is connected to the source/drain electrode of the TFT layer.

In some embodiments, when a voltage is applied to the pixel electrode through the TFT layer, an appropriate voltage is formed between the pixel electrode and the counter electrode, and thus the organic light emitting layer emits light, thereby forming an image. Hereinafter, an image forming unit including the TFT layer and the light emitting unit is referred to as a display unit.

In some embodiments, the encapsulation layer that covers the display unit and prevents penetration of external moisture may be formed to have a thin film encapsulation structure in which an organic film and an inorganic film are alternately stacked. In some embodiments, the encapsulation layer has a thin film encapsulation structure in which a plurality of thin films are stacked. In some embodiments, the organic film applied to the interface portion is spaced apart from each of the plurality of display units. In some embodiments, the organic film is formed such that a portion of the organic film directly contacts the base substrate and a remaining portion of the organic film contacts the barrier layer while surrounding an edge portion of the barrier layer.

In one embodiment, the OLED display is flexible and uses the soft base substrate formed of polyimide. In some embodiments, the base substrate is formed on a carrier substrate formed of a glass material, and then the carrier substrate is separated.

In some embodiments, the barrier layer is formed on a surface of the base substrate opposite to the carrier substrate. In one embodiment, the barrier layer is patterned according to a size of each of the cell panels. For example, while the base substrate is formed over the entire surface of a mother panel, the barrier layer is formed according to a size of each of the cell panels, and thus a groove is formed at an interface portion between the barrier layers of the cell panels. Each of the cell panels can be cut along the groove.

In some embodiments, the method of manufacture further comprises cutting along the interface portion, wherein a groove is formed in the barrier layer, wherein at least a portion of the organic film is formed in the groove, and wherein the groove does not penetrate into the base substrate. In some embodiments, the TFT layer of each of the cell panels is formed, and the passivation layer which is an inorganic film and the planarization film which is an organic film are disposed on the TFT layer to cover the TFT layer. At the same time as the planarization film formed of, for example, polyimide or acryl is formed, the groove at the interface portion is covered with the organic film formed of, for example, polyimide or acryl. This is to prevent cracks from occurring by allowing the organic film to absorb an impact generated when each of the cell panels is cut along the groove at the interface portion. That is, if the entire barrier layer is entirely exposed without the organic film, an impact generated when each of the cell panels is cut along the groove at the interface portion is transferred to the barrier layer, thereby increasing the risk of cracks. However, in one embodiment, since the groove at the interface portion between the barrier layers is covered with the organic film and the organic film absorbs an impact that would otherwise be transferred to the barrier layer, each of the cell panels may be softly cut and cracks may be prevented from occurring in the barrier layer. In one embodiment, the organic film covering the groove at the interface portion and the planarization film are spaced apart from each other. For example, if the organic film and the planarization film are connected to each other as one layer, since external moisture may penetrate into the display unit through the planarization film and a portion where the organic film remains, the organic film and the planarization film are spaced apart from each other such that the organic film is spaced apart from the display unit.

In some embodiments, the display unit is formed by forming the light emitting unit, and the encapsulation layer is disposed on the display unit to cover the display unit. As such, once the mother panel is completely manufactured, the carrier substrate that supports the base substrate is separated from the base substrate. In some embodiments, when a laser beam is emitted toward the carrier substrate, the carrier substrate is separated from the base substrate due to a difference in a thermal expansion coefficient between the carrier substrate and the base substrate.

In some embodiments, the mother panel is cut in units of the cell panels. In some embodiments, the mother panel is cut along an interface portion between the cell panels by using a cutter. In some embodiments, since the groove at the interface portion along which the mother panel is cut is covered with the organic film, the organic film absorbs an impact during the cutting. In some embodiments, cracks may be prevented from occurring in the barrier layer during the cutting.

In some embodiments, the methods reduce a defect rate of a product and stabilize its quality.

Another aspect is an OLED display including: a barrier layer that is formed on a base substrate; a display unit that is formed on the barrier layer; an encapsulation layer that is formed on the display unit; and an organic film that is applied to an edge portion of the barrier layer.

### (Design Method for Light Emitting Composition)

The present invention also provides a method for designing a light emitting composition having a long emission lifetime and excellent in stability.

The design method for a light emitting composition of the present invention includes the following steps 1 to 3.
[Step 1] evaluating the light emission efficiency and the lifetime of a composition containing a first organic compound, a second organic compound of a delayed fluorescent material and a triplet-regulating compound, and satisfying the following requirements (a) and (b),
[Step 2] carrying out at least once evaluating the light emission efficiency and the lifetime of a composition prepared by replacing at least one of the first organic compound, the second organic compound of a delayed fluorescent material and the triplet-regulating compound within the range satisfying the following requirements (a) and (b),
[Step 3] displaying the evaluation results.

$${E}_{S 1} ( 1 ) > {E}_{S 1} ( Q ) > {E}_{S 1} ( 2 ) \qquad Requirement ( a )$$

$${E}_{T 1} ( 1 ) > {E}_{T 1} ( 2 ) > {E}_{T 1} ( Q ) \qquad Requirement ( b )$$

Also the present invention provides a method for designing a light emitting composition containing a first organic compound, a second organic compound of a delayed fluorescent material, a third organic compound and a triplet-regulating compound, and the design method includes the following steps 1 to 3.
[Step 1] evaluating the light emission efficiency and the lifetime of a composition containing a first organic compound, a second organic compound of a delayed fluorescent material, a third organic compound and a triplet-regulating compound, and satisfying the following requirements (a1) and (b1),
[Step 2] carrying out at least once evaluating the light emission efficiency and the lifetime of a composition prepared by replacing at least one of the first organic compound, the second organic compound of a delayed fluorescent material, the third organic compound and the triplet-regulating compound within the range satisfying the following requirements (a1) and (b1),
[Step 3] displaying the evaluation results.

$${E}_{S 1} ( 1 ) > {E}_{S 1} ( Q ) > {E}_{S 1} ( 2 ) > {E}_{S 1} ( 3 ) \qquad Requirement ( a1 )$$

$${E}_{T 1} ( 1 ) > {E}_{T 1} ( 2 ) > {E}_{T 1} ( 3 ) > {E}_{T 1} ( Q ) \qquad Requirement ( b1 )$$

Evaluation of the emission efficiency and the lifetime can be carried out by actually emitting the light emitting composition, or can be carried out by calculation. In addition, evaluation can also be carried out by actually emitting the light emitting composition combined with a calculation method. Preferably, evaluation is carried out from a comprehensive viewpoint using a high level of practicality as an index. In the design method for a light emitting composition of the present invention, it is necessary to select and replace the first organic compound, the second organic compound, the third organic compound of an optional component and the triplet-regulating compound within a range satisfying the requirement (a) and the requirement (b), or within a range satisfying the requirement (a1) and the requirement (b1). Also it is necessary to select and replace the second organic compound from a delayed fluorescent material. For the compound replacement in the step 2, preferably, the compound is replaced to another one capable of attaining a more excellent evaluation. The step 2 can be carried out, for example, 10 times or more, 100 times or more, 1000 times or more, or 10000 times or more. In the step 2, any other properties than the light emission efficiency and the lifetime can also be evaluated. In the step 3, the evaluation results can be displayed as they are, or the evaluation results can be rearranged in descending order of thereof, or reevaluation can be performed based on the evaluation results, and the results can be displayed. At that time, the results of reevaluation can be displayed by changing the emphasis for each performance evaluated in the step 2. For example, in the case where the lifetime is considered to be the most important, the emphasis on the lifetime is enhanced and the reevaluated results can be displayed. Display in the step 3 is a concept including screen display on display units and printing, and means that the subjects are shown in the condition that humans or machines can recognize. Consequently, the display includes transmitting the results of the design method of the present invention as electronic information, for inputting them into other programs,

### (Program)

The program of the present invention is a program for carrying out the design method for the composition of the present invention. The program can be stored on a recording medium and can be transmitted and received by an electronic means.

The program of the present invention has a step of selecting a first organic compound, a second organic compound of a delayed fluorescent material and a triplet-regulating compound so as to satisfy the requirement (a) and the requirement (b), from the database of accumulation of the lowest excited singlet energy and the lowest excited triplet energy of a large number of compounds. The step can be a step of selecting a first organic compound, a second organic compound of a delayed fluorescent material, a third organic compound and a triplet-regulating compound so as to satisfy the requirement (a1) and the requirement (b1), from the database of accumulation of the lowest excited singlet energy and the lowest excited triplet energy of a large number of compounds.

The program of the present invention can have a step of evaluating the light emission efficiency and the lifetime of the composition containing the selected compounds by calculation. Or the program of the present invention can have a step of inputting the actually measured results of the light emission efficiency and the lifetime of the composition containing the selected compounds and evaluating them. Or the program of the present invention can have a step of evaluating the light emission efficiency and the lifetime of the composition containing the selected compounds by utilizing the database of accumulation of the actually measured results of the light emission efficiency and the lifetime of compositions of various compounds combined.

The program of the present invention can have a step of selecting combinations of excellent compounds based on specific criterion formulae on the basis of the evaluated results the light emission efficiency and the lifetime of various compounds. Also the program of the present invention can have a function of selecting compounds until results of an expected value or more can be attained and repeating the evaluation of the compositions containing the selected compounds. Or the program of the present invention can have a step of displaying the results of the evaluated light emission efficiency and lifetime, and a step displaying the results in order of superiority.

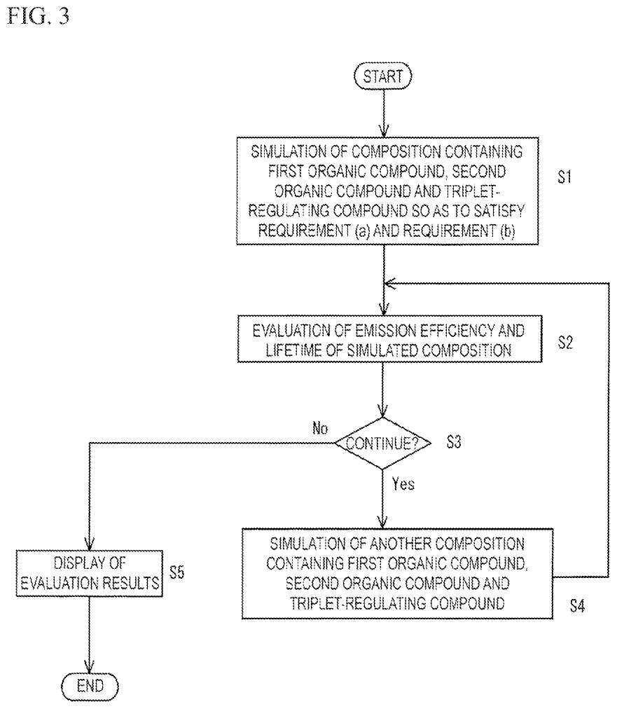

An example of a procedure of the program of the present invention is described with reference to FIG. 3. In one preferred embodiment of the program, first, at least one composition containing a first organic compound, a second organic compound and a triplet-regulating compound is simulated so as to satisfy the requirement (a) and the requirement (b) (S1), and the light emission efficiency and the lifetime of all the compositions are evaluated (S2). Subsequently, when any other compositions are desired to be determined, at least one compound of the first organic compound, the second organic compound and the triplet-regulating compound is replaced with any other compound, and at least one composition satisfying the requirement (a) and the requirement (b) is simulated (S4), and the light emission efficiency and the lifetime of all the compositions are evaluated (S2). In the case where any other composition is not determined, the evaluation results are displayed (S5), and the process is ended.

In the case where a composition containing a first organic compound, a second organic compound, a third organic compound and a triplet-regulating compound is evaluated, at least one composition containing the first organic compound, the second organic compound, the third organic compound and the triplet-regulating compound is simulated so as to satisfy the requirement (a1) and the requirement (b1) in S1. In S4, at least one compound of the first organic compound, the second organic compound, the third organic compound and the triplet-regulating compound is replaced with any other compound, and at least one composition to satisfy the requirement (a1) and the requirement (b1) is simulated. The others are the same as in FIG. 3.

These programs can be appropriately modified in a manner obvious to those skilled in the art.

### EXAMPLES

The features of the present invention will be described more specifically with reference to Examples given below. The materials, processes and procedures shown below can be appropriately modified unless they deviate from the substance of the invention. Accordingly, the scope of the invention is not construed as being limited to the specific examples shown below. The light emission characteristics were evaluated using a source meter (available from Keithley Instruments LLC, 2400 series), a semiconductor parameter analyzer (available from Agilent Technologies, Inc., E5273A), an optical power meter device (available from Newport Corporation, 1930C), an optical spectroscope (available from Ocean Optics Corporation, USB2000), a spectroradiometer (available from Topcon Corporation, SR-3), and a streak camera (available from Hamamatsu Photonics K.K., Model C4334). The lowest excited singlet energy E_{S1} and the lowest excited triplet energy E_{T1} of the compounds used in the following Examples and Comparative Examples are as shown in the following Table.

TABLE 1

| | | E_{S1} (eV) | E_{T1}(eV) |
|---|---|---|---|
| First Organic Compound | Compound H1 | 3.54 | 3.06 |
| Second Organic Compound | Compound T13 | 2.78 | 2.66 |
| Third Organic Compound | Compound E1 | 2.72 | 2.59 |
| Triplet-Regulating Compound | Compound Z1 | 2.90 | 2.13 |
| Comparative Compound | SF3TRZ | 3.52 | 2.81 |

### Example 1

On a glass substrate having, as formed thereon, an anode of indium tin oxide (ITO) having a thickness of 100 nm, the following thin films were laminated according to a vacuum evaporation method at a vacuum degree of 1×10⁻⁶ Pa. First, on ITO, HATCN was formed at a thickness of 10 nm, then NPD was formed thereon at a thickness of 30 nm, and further on this, TrisPCz was formed at a thickness of 10 nm. Next, the compound H1 was formed at a thickness of 5 nm to be an electron barrier layer. Further, the compound H1 (70% by weight) and the compound T13 (30% by weight) were co-evaporated from different evaporation sources to form a light emitting layer at a thickness of 30 nm. Next, Z1 was formed as a hole barrier layer at a thickness of 10 nm. Subsequently, SF3TRZ and Liq were co-evaporated from different evaporation sources to form an electron transporting layer at a thickness of 30 nm. At that time, SF3TRZ/Liq (by weight) was 7/3. Further, Liq was formed at a thickness of 2 nm, and then aluminum (Al) was deposited at a thickness of 100 nm to be a cathode. Through the process, an organic electroluminescent device of Example 1 was produced.

### Comparative Example 1

An organic electroluminescent device of Comparative Example 1 was produced according to the same production method of Example 1, only except the point that SF3TRZ was used in place of the compound Z1 for the hole barrier layer.

### Example 2

An organic electroluminescent device of Example 2 was produced according to the same production method of Example 1, only except the point that the compound Z1 was used in place of the compound H1 for the electron barrier layer.

### (Evaluation)

The organic electroluminescent devices were energized, and all gave delayed fluorescence emission derived from the second organic compound T13 (in every case, the maximum emission wavelength was 485 nm). The external quantum efficiency of the three organic electroluminescent devices was on the same level. The devices were continued to be energized at 2 mA/cm², and the time (LT95) in which the emission intensity became 95% of the initial emission intensity was measured. Based on LT95 of the device of Comparative Example 1 to be 1, the relative value of each other device is shown in Table 2. As shown in Table 2, it is confirmed that the lifetime of the device of Example 1 using the triplet-regulating compound (compound Z1) as the hole barrier layer and the device of Example 2 using the triplet-regulating compound (compound Z1) as the electron barrier layer was longer by 46% as compared with that of the device of Comparative Example 1 not using the triplet-regulating compound satisfying the requirements of the present invention as these barrier layers.

TABLE 2

| | | Light Emitting Layer | | | |
|---|---|---|---|---|---|
| | Electron | First | Second | Hole | LT95 |
| | Barrier | Organic | Organic | Barrier | (relative |
| | Layer | Compound | Compound | Layer | value) |
| Example 1 | Compound H1 | Compound H1 | Compound T13 | Compound Z1 | 1.46 |
| Example 2 | Compound Z1 | Compound H1 | Compound T13 | SF3TRZ | 1.46 |
| Comparative | Compound H1 | Compound H1 | Compound T13 | SF3TRZ | 1 |
| Example 1 | | | | | |

### Example 3

An organic electroluminescent device of Example 3 was produced according to the same production method of Example 1, only except the point that the light emitting layer was formed of the compound H1 (first organic compound: 69.5% by weight), the compound T13 (second organic compound: 30.0% by weight) and the compound E1 (third organic compound: 0.5% by weight).

### Comparative Example 2

An organic electroluminescent device of Comparative Example 2 was produced according to the same production method of Example 3, only except the point that SF3TRZ was used in place of the compound Z1 for the hole barrier layer.

### (Evaluation)

The organic electroluminescent devices produced in Example 3 and Comparative Example 2 were energized, and all gave delayed fluorescence emission derived from the third organic compound E1 (in every case, the maximum emission wavelength was 472 nm). The external quantum efficiency of the organic electroluminescent devices was measured, and as shown in Table 3, the device of Example 3 attained a high external quantum efficiency of more than 20%. The devices were continued to be energized at 2 mA/cm², and the time (LT95) in which the emission intensity became 95% of the initial emission intensity was measured. Based on LT95 of the device of Comparative Example 2 to be 1, the relative value of the other device is shown in Table 3. As shown in Table 3, it is confirmed that the lifetime of the device of Example 3 using the triplet-regulating compound (compound Z1) as the hole barrier layer and the device of Example 3 using the triplet-regulating compound (compound Z1) as the hole barrier layer was longer by four times as compared with that of the device of Comparative Example 2 not using the triplet-regulating compound satisfying the requirements of the present invention as the hole barrier layer.

TABLE 3

| | | Light Emitting Layer | | | | | |
|---|---|---|---|---|---|---|---|
| | | | Second | Third | | | LT95 |
| | Electron | First Organic | Organic | Organic | Hole Barrier | EQE | (relative |
| | Barrier Layer | Compound | Compound | Compound | Layer | (%) | value) |
| Example 3 | Compound | Compound | Compound | Compound | Compound | 20.4 | 4 |
| | H1 | H1 | T13 | E1 | Z1 | | |
| Comparative | Compound | Compound | Compound | Compound | SF3TRZ | 16.9 | 1 |
| Example 2 | H1 | H1 | T13 | E1 | | | |

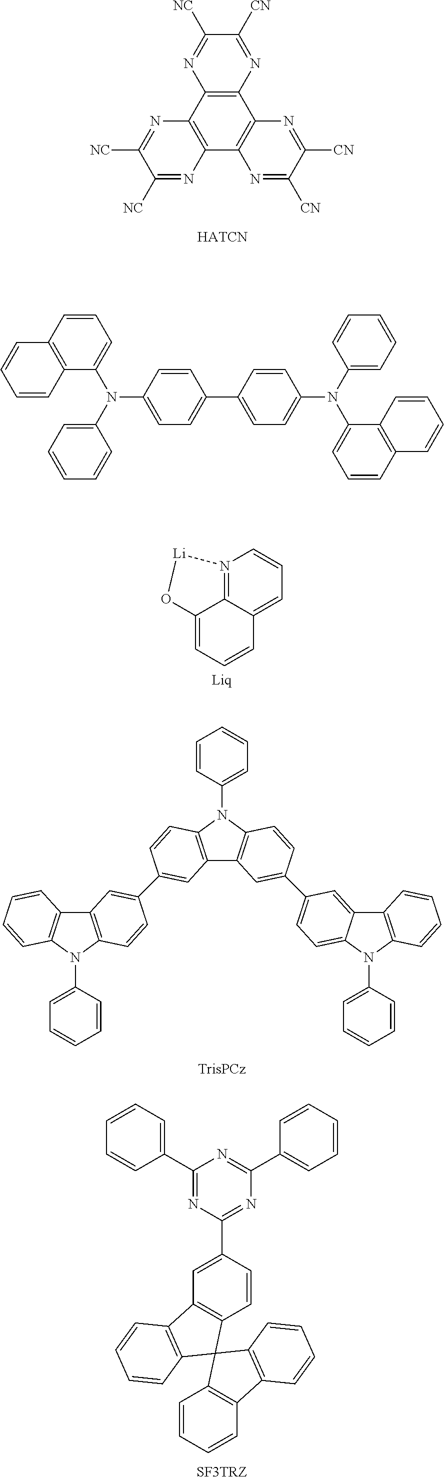

### INDUSTRIAL APPLICABILITY

According to the present invention, there can be provided a light emitting device having a long lifetime and being stable. Consequently, the industrial applicability of the present invention is great.

### REFERENCE SIGNS LIST

1 Glass Substrate
2 Anode
3 Hole Injection Layer
4 Hole Transporting Layer
5 Electron Barrier Layer
6 Light Emitting Layer
7 Hole Barrier Layer
8 Hole Transporting Layer
9 Cathode

1. An organic light emitting device having a light emitting layer that contains a first organic compound and a second organic compound, and a barrier layer containing a triplet-regulating compound in contact with the light emitting layer, wherein:
the second organic compound is a delayed fluorescent material,
the first organic compound, the second organic compound and the triplet-regulating compound satisfy the following requirements (a) and (b):
$${E}_{S 1} ( 1 ) > {E}_{S 1} ( Q ) > {E}_{S 1} ( 2 ) \qquad Requirement ( a )$$
$${E}_{T 1} ( 1 ) > {E}_{T 1} ( 2 ) > {E}_{T 1} ( Q ) \qquad Requirement ( b )$$
wherein:
E_{S1}(1) represents the lowest excited singlet energy of the first organic compound,
E_{S1}(2) represents the lowest excited singlet energy of the second organic compound,
E_{S1}(Q) represents the lowest excited singlet energy of the triplet-regulating compound,
E_{T1}(1) represents the lowest excited triplet energy at 77K of the first organic compound,
E_{T1}(2) represents the lowest excited triplet energy at 77K of the second organic compound,
E_{T1}(Q) represents the lowest excited triplet energy at 77K of the triplet-regulating compound.

2. The organic light emitting device according to claim 1, wherein the light emitting layer further contains a third organic compound, satisfying the following requirements (a1) and (b1):
$${E}_{S 1} ( 1 ) > {E}_{S 1} ( Q ) > {E}_{S 1} ( 2 ) > {E}_{S 1} ( 3 ) \qquad Requirement ( a1 )$$
$${E}_{T 1} ( 1 ) > {E}_{T 1} ( 2 ) > {E}_{T 1} ( 3 ) > {E}_{T 1} ( Q ) \qquad Requirement ( b1 )$$
wherein:
E_{S1}(1) represents the lowest excited singlet energy of the first organic compound,
E_{S1}(2) represents the lowest excited singlet energy of the second organic compound,
E_{S1}(3) represents the lowest excited singlet energy of the third organic compound,
E_{S1}(Q) represents the lowest excited singlet energy of the triplet-regulating compound,
E_{T1}(1) represents the lowest excited triplet energy at 77K of the first organic compound,
E_{T1}(2) represents the lowest excited triplet energy at 77K of the second organic compound,
E_{T1}(3) represents the lowest excited triplet energy at 77K of the third organic compound,
E_{T1}(Q) represents the lowest excited triplet energy at 77K of the triplet-regulating compound.

3. The organic light emitting device according to claim 1, wherein the concentration of the triplet-regulating compound in the barrier layer is more than 50%.

4. The organic light emitting device according to claim 1, wherein the triplet-regulating compound has a structure represented by the following general formula (15): 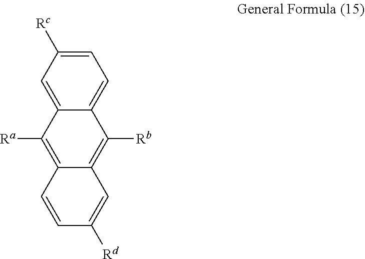
wherein R^{a} and R^{b} each independently represent a substituted or unsubstituted aryl group, R^{c} and R^{d} each independently represent a hydrogen atom, a deuterium atom, a substituted or unsubstituted alkyl group, a substituted or unsubstituted alkoxy group, a substituted or unsubstituted aryl group, a substituted or unsubstituted aryloxy group, a substituted or unsubstituted amino group, a halogen atom, a cyano group, or a substituted or unsubstituted silyl group.

5. The organic light emitting device according to claim 1 having the light emitting layer between an anode and a cathode, wherein the barrier layer is an electron barrier layer formed between the anode and the light emitting layer.

6. The organic light emitting device according to claim 1 having the light emitting layer between an anode and a cathode, wherein the barrier layer is a hole barrier layer formed between the cathode and the light emitting layer.

7. The organic light emitting device according to claim 1, wherein the second organic compound is such that the energy difference ΔEₛₜ between the lowest excited singlet state and the lowest excited triplet state at 77K is 0.3 eV or less.

8. The organic light emitting device according to claim 2, wherein the light emitting layer contains the third organic compound such that the energy difference ΔEₛₜ between the lowest excited singlet state and the lowest excited triplet state at 77K is 0.3 eV or less.

9. The organic light emitting device according to claim 1, wherein the light emitting layer is formed of a compound alone composed of atoms selected from the group consisting of a carbon atom, a hydrogen atom, a deuterium atom, a nitrogen atom, a boron atom, an oxygen atom and a sulfur atom.

10. The organic light emitting device according to claim 1, wherein the first organic compound, the second organic compound and the triplet-regulating compound each are independently a compound formed of atoms selected from the group consisting of a carbon atom, a hydrogen atom, a deuterium atom and a nitrogen atom.

11. The organic light emitting device according to claim 1, wherein the triplet-regulating compound is a compound composed of a carbon atom and a hydrogen atom alone.

12. The organic light emitting device according to claim 1, wherein the second organic compound contains a cyanobenzene structure.

13. A method for producing an organic light emitting device, comprising:
forming a light emitting layer containing a first organic compound and a second organic compound of a delayed fluorescent material, and forming a barrier layer containing a triplet-regulating compound so as to be in contact with the light emitting layer; or
forming a barrier layer containing a triplet-regulating compound, and forming a light emitting layer containing a first organic compound and a second organic compound of a delayed fluorescent material so as to be in contact with the barrier layer, wherein:
the first organic compound, the second organic compound and the triplet-regulating compound satisfy the following requirements (a) and (b).
$${E}_{S 1} ( 1 ) > {E}_{S 1} ( Q ) > {E}_{S 1} ( 2 ) \qquad Requirement ( a )$$
$${E}_{T 1} ( 1 ) > {E}_{T 1} ( 2 ) > {E}_{T 1} ( Q ) \qquad Requirement ( b )$$
wherein:
E_{S1}(1) represents the lowest excited singlet energy of the first organic compound,
E_{S1}(2) represents the lowest excited singlet energy of the second organic compound,
E_{S1}(Q) represents the lowest excited singlet energy of the triplet-regulating compound,
E_{T1}(1) represents the lowest excited triplet energy at 77K of the first organic compound,
E_{T1}(2) represents the lowest excited triplet energy at 77K of the second organic compound,
E_{T1}(Q) represents the lowest excited triplet energy at 77K of the triplet-regulating compound.

14. The method for producing an organic light emitting device according to claim 13, wherein the light emitting layer further contains a third organic compound, satisfying the following requirements (a1) and (b1):
$${E}_{S 1} ( 1 ) > {E}_{S 1} ( Q ) > {E}_{S 1} ( 2 ) > {E}_{S 1} ( 3 ) \qquad Requirement ( a1 )$$
$${E}_{T 1} ( 1 ) > {E}_{T 1} ( 2 ) > {E}_{T 1} ( 3 ) > {E}_{T 1} ( Q ) \qquad Requirement ( b1 )$$
wherein:
E_{S1}(1) represents the lowest excited singlet energy of the first organic compound,
E_{S1}(2) represents the lowest excited singlet energy of the second organic compound,
E_{S1}(3) represents the lowest excited singlet energy of the third organic compound,
E_{S1}(Q) represents the lowest excited singlet energy of the triplet-regulating compound,
E_{T1}(1) represents the lowest excited triplet energy at 77K of the first organic compound,
E_{T1}(2) represents the lowest excited triplet energy at 77K of the second organic compound,
E_{T1}(3) represents the lowest excited triplet energy at 77K of the third organic compound.
E_{T1}(Q) represents the lowest excited triplet energy at 77K of the triplet-regulating compound.
